(19) United States
(12) Patent Application Publication
(10) Pub. No.: US 2026/0164640 A1
(43) Pub. Date: Jun. 11, 2026

(54) SEMICONDUCTOR DEVICE INCLUDING ACTIVE PATTERN AND GATE ELECTRODE

(71) Applicant: Samsung Electronics Co., Ltd., Suwon-si (KR)

(72) Inventors: Taejin Park, Suwon-si (KR); Junsoo Kim, Suwon-si (KR); Sungsoo Yim, Suwon-si (KR)

(21) Appl. No.: 19/251,599

(22) Filed: Jun. 26, 2025

(30) Foreign Application Priority Data
Dec. 5, 2024 (KR) 10-2024-0179777

(51) Int. Cl. H10B 12/00; H01L 23/00; H10D 1/68; H10D 30/60; H10D 30/69; H10D 62/10

(52) U.S. Cl. CPC H10B 12/315; H10B 12/20; H10B 12/482; H10D 30/611; H10D 30/711; H10D 62/102; H10B 12/05; H10D 1/716; H10W 90/792

(57) ABSTRACT

A semiconductor device includes a first cell active pattern and a second cell active pattern adjacent to each other, a first gate electrode and a second gate electrode disposed between the first and second cell active patterns and spaced apart from each other, a first gate dielectric layer between the first gate electrode and the first cell active pattern, a second gate dielectric layer between the second gate electrode and the second cell active pattern, and a first conductive pattern disposed between the first and second cell active patterns, at least a portion of which is disposed at a different level from the first and second gate electrodes, and spaced apart from the first and second gate electrodes.

### CROSS-REFERENCE TO RELATED APPLICATION

This application claims benefit of priority to Korean Patent Application No. 10-2024-0179777 filed on Dec. 5, 2024, in the Korean Intellectual Property Office, the disclosure of which is incorporated by reference herein in its entirety.

### BACKGROUND

The present disclosure relates to a semiconductor device including an active pattern and a gate electrode.

The minimum feature size in semiconductor devices is gradually reduced to enhance productivity and improve performance. For example, the minimum feature size in a DRAM is continuously decreased to attain high-density integration and optimize its performance through advanced process technology. However, as the minimum feature size is reduced, the dispersion properties of semiconductor devices are deteriorated.

### SUMMARY

The present disclosure provides a semiconductor device having improved performance, an operating method for the semiconductor device, and a method for forming the semiconductor.

According to example embodiments, the semiconductor device includes a first cell active pattern and a second cell active pattern that are adjacent to each other, a first gate electrode and a second gate electrode disposed between the first and second cell active patterns and spaced apart from each other, a first gate dielectric layer between the first gate electrode and the first cell active pattern, a second gate dielectric layer between the second gate electrode and the second cell active pattern, and a first conductive pattern disposed between the first and second cell active patterns and spaced apart from the first and second gate electrodes, at least a portion of the first conductive pattern being disposed at a different level from the first and second gate electrodes.

According to example embodiments, the semiconductor device includes, a memory cell array region and an interface region adjacent to each other in a first horizontal direction, active patterns including cell active patterns disposed within the memory cell array region and dummy active patterns disposed within the interface region, gate electrodes traversing the memory cell array region and extending into the interface region, and conductive patterns traversing the memory cell array region and extending into the interface region, wherein at least a portion of each of the conductive patterns is disposed at a different level from the gate electrodes, wherein the cell active patterns include a first cell active pattern and a second cell active pattern adjacent to each other in a second horizontal direction perpendicular to the first horizontal direction, wherein the gate electrodes include a first gate electrode and a second gate electrode passing between the first and second cell active patterns and spaced apart from each other, and wherein the conductive patterns include a first conductive pattern passing between the first cell active pattern and the second cell active pattern.

According to example embodiments, the semiconductor device includes a memory cell array region and an interface region adjacent to each other in a first horizontal direction, active patterns including cell active patterns disposed in the memory cell array region and dummy active patterns disposed in the interface region, gate electrodes traversing the memory cell array region and extending into the interface region, first conductive patterns traversing the memory cell array region and extending into the interface region, bit lines extending in a second horizontal direction perpendicular to the first horizontal direction, connected to the cell active patterns, and disposed below the cell active patterns, data storage structures on the cell active patterns, and a contact structure between the cell active patterns and the data storage structure, wherein at least a portion of each of the first conductive patterns is at a different level from the gate electrodes, wherein the cell active patterns include a first cell active pattern and a second cell active pattern adjacent to each other in a second horizontal direction perpendicular to the first horizontal direction, wherein the gate electrodes include a first gate electrode and a second gate electrode passing between the first and second cell active patterns and spaced apart from each other, and wherein one of the first conductive patterns passes between the first cell active pattern and the second cell active pattern.

According to example embodiments, the semiconductor device includes a bit line, a data storage structure disposed at a different level from the bit line, an active pattern between the bit line and the data storage structure, a gate electrode facing a side surface of the active pattern, and a gate dielectric layer between the gate electrode and the active pattern. The gate electrode includes a lower surface, an upper surface opposite to the lower surface, a first side surface facing the side surface of the active pattern, and a first rounded edge between the first side surface and the upper surface.

The gate electrode may further include a second rounded edge between the first side surface and the lower surface.

The semiconductor device may further include a conductive pattern spaced apart from the gate electrode and facing the active pattern.

The conductive pattern may include a first conductive portion facing the active pattern and disposed at a different level from the gate electrode and a second conductive portion which extends from the first conductive portion and in which at least a portion thereof is disposed at a same level as at least a portion of the gate electrode.

The at least a portion of the gate electrode may be disposed between the active pattern and the second conductive portion.

The semiconductor device may further include a buffer dielectric layer disposed between the conductive pattern and the gate electrode and extending between the conductive pattern and the active pattern.

According to example embodiments, the semiconductor device includes a bit line, a data storage structure disposed at a different level from the bit line, an active pattern between the bit line and the data storage structure, a gate electrode facing a side surface of the active pattern, a gate dielectric layer between the gate electrode and the active pattern, and an upper buffer dielectric layer covering an upper surface of the gate electrode and extending between the gate electrode and the active pattern.

The upper buffer dielectric layer may include a high-κ dielectric having a dielectric constant higher than a dielectric constant of a material of the gate dielectric layer.

The gate dielectric layer may include a first dielectric portion disposed between the active pattern and the gate electrode and having a first thickness, and a second dielectric portion disposed between the active pattern and the upper buffer dielectric layer and having a second thickness, smaller than the first thickness.

The semiconductor device may further include a lower buffer dielectric layer covering a lower surface of the gate electrode and extending between the gate electrode and the gate dielectric layer.

The semiconductor device may further include a conductive pattern spaced apart from the gate electrode and facing the active pattern.

The conductive pattern may include a first conductive portion facing the active pattern and disposed at a different level from the gate electrode, and a second conductive portion which extends from the first conductive portion and in which at least a portion thereof is disposed at a same level as at least a portion of the gate electrode.

The at least a portion of the gate electrode may be disposed between the active pattern and the second conductive portion.

The upper buffer dielectric layer may extend from a portion disposed between the upper surface of the gate electrode and the first conductive portion to a space between the gate electrode and the active pattern.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1A, 1B, 2, and 3 are conceptual diagrams illustrating a semiconductor device according to an example embodiment of the present disclosure;

FIG. 4 is a conceptual perspective view illustrating an example of a semiconductor device according to an example embodiment of the present disclosure;

FIGS. 5A, 5B, 5C, 6A, 6B, 6C, and 7 are views illustrating examples of a semiconductor device according to an example embodiment of the present disclosure;

FIGS. 8A and 8B are views illustrating an example of a semiconductor device according to an example embodiment of the present disclosure;

FIG. 9 is a cross-sectional view illustrating an example of a semiconductor device according to an example embodiment of the present disclosure;

FIG. 10 is a cross-sectional view illustrating an example of a semiconductor device according to an example embodiment of the present disclosure;

FIG. 11 is a cross-sectional view illustrating an example of a semiconductor device according to an example embodiment of the present disclosure;

FIGS. 12A, 12B, and 12C are views illustrating an example of a semiconductor device according to an example embodiment of the present disclosure;

FIGS. 13, 14, 15A, 15B and 16 are views illustrating an example of a semiconductor device according to an example embodiment of the present disclosure;

FIGS. 17A and 17B are views illustrating an example of a semiconductor device according to an example embodiment of the present disclosure;

FIGS. 18, 19, 20A, 20B and 21 are views illustrating examples of a semiconductor device according to an example embodiment of the present disclosure;

FIGS. 22A and 22B are views illustrating an example of a semiconductor device according to an example embodiment of the present disclosure;

FIGS. 23A and 23B are views illustrating an example of a semiconductor device according to an example embodiment of the present disclosure;

FIGS. 24A and 24B are views illustrating an example of a semiconductor device according to an example embodiment of the present disclosure;

FIGS. 25, 26 and 27 are views illustrating an example of a semiconductor device according to an example embodiment of the present disclosure;

FIG. 28 is a partially enlarged cross-sectional view illustrating an example of a semiconductor device according to an example embodiment of the present disclosure;

FIG. 29 is a partially enlarged cross-sectional view illustrating an example of a semiconductor device according to an example embodiment of the present disclosure;

FIGS. 30, 31A, 31B, and 31C are views illustrating examples of semiconductor devices according to an example embodiment of the present disclosure;

FIG. 32 is a partially enlarged cross-sectional view illustrating an example of a semiconductor device according to an example embodiment of the present disclosure;

FIGS. 33A, 33B and 33C are views illustrating an example of a semiconductor device according to an example embodiment of the present disclosure;

FIG. 34 is a partially enlarged cross-sectional view illustrating an example of a semiconductor device according to an example embodiment of the present disclosure;

FIGS. 35A, 35B, 36A, 36B, 37A, 37B, 38A, 38B, 39A, 39B, 40A, 40B, 41A, 41B, 42A and 42B are cross-sectional views illustrating an example of a method of forming a semiconductor device according to an example embodiment of the present disclosure; and

FIGS. 43A, 43B, 44A, 44B, 45A, 45B, 46A and 46B are cross-sectional views illustrating an example of a method of forming a semiconductor device according to an example embodiment of the present disclosure.

### DETAILED DESCRIPTION

Hereinafter, example embodiments of the present disclosure will be described with reference to the accompanying drawings.

Spatially relative terms, such as “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly. It will be understood that, although the terms first, second, and third may be used herein to describe various elements, components, regions, layers and/or sections, these elements, components, regions, layers, and/or sections should not be limited by these terms. Unless the context indicates otherwise, these terms are only used to distinguish one element, component, region, layer or section from another element, component, region, layer, or section, for example as a naming convention. Thus, a first element, component, region, layer, or section discussed below in one section of the specification could be termed a second element, component, region, layer, or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

A semiconductor device and an operating method thereof according to an example embodiment of the present disclosure will be described. The operating method according to an example embodiment of the present disclosure may be a semiconductor device operating method including a memory cell operating method.

The operating method will be described with reference to the elements of the semiconductor device used for the operation and the semiconductor device according to an example embodiment of the present disclosure.

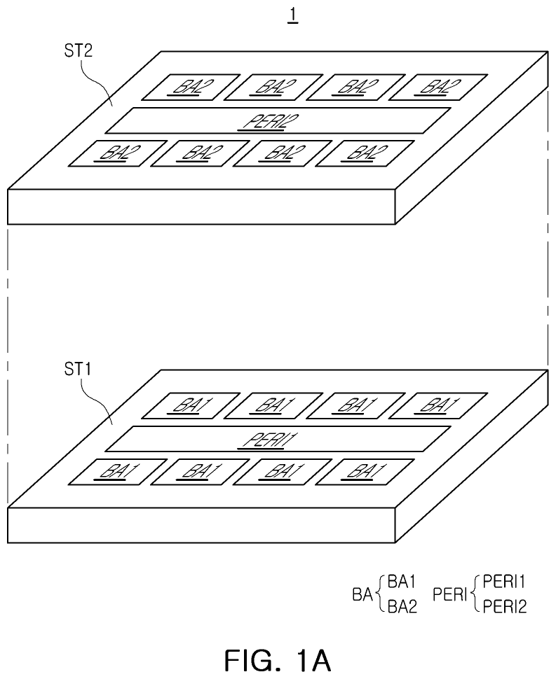

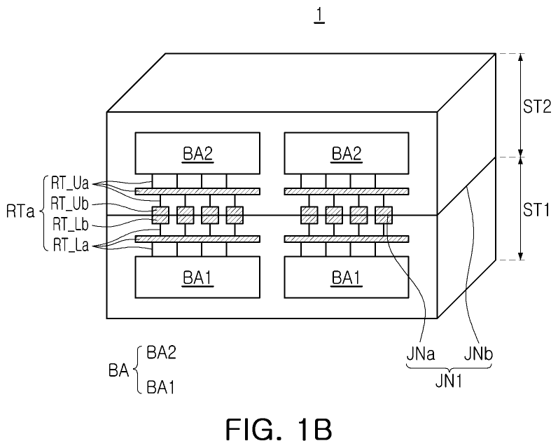

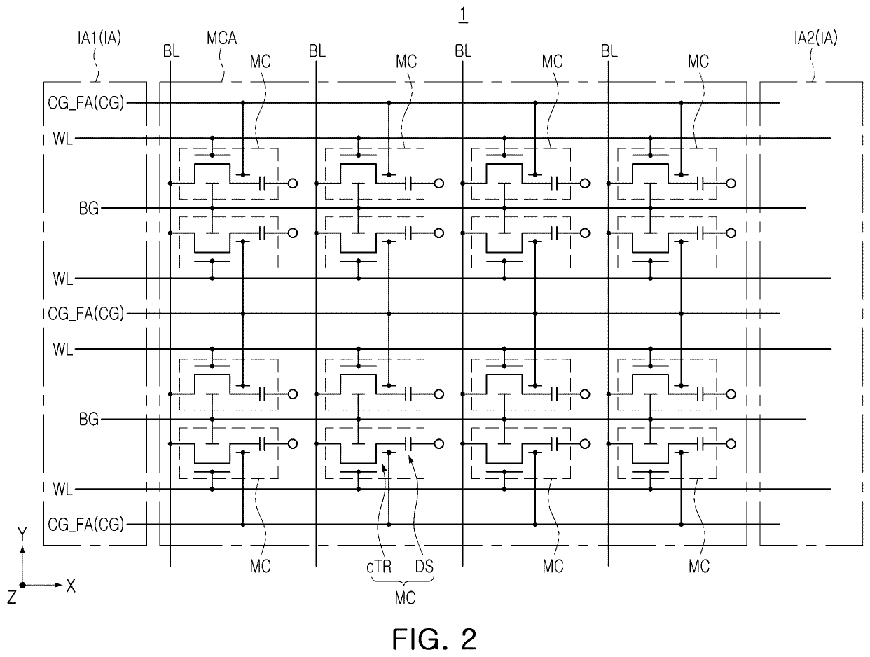

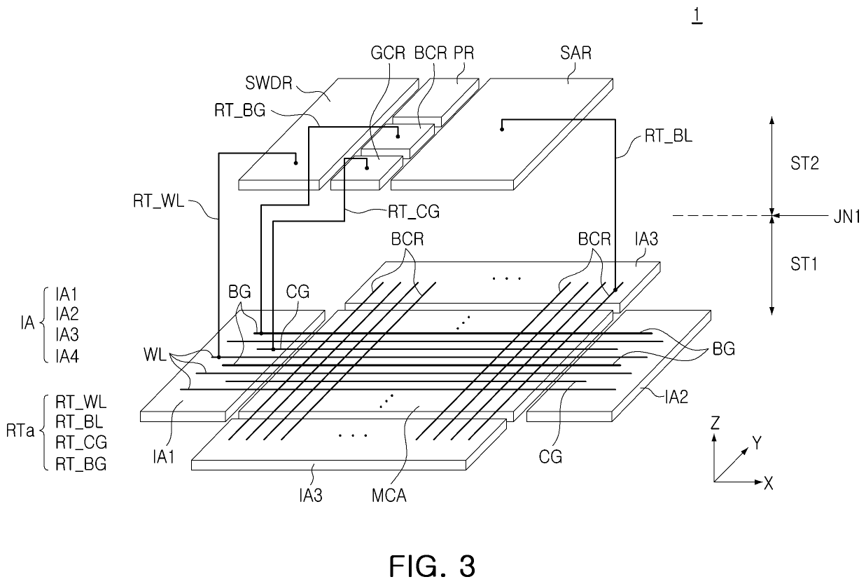

A semiconductor device and an operating method according to an example embodiment of the present disclosure will be described with reference to FIGS. 1A, 1B, 2 and 3. FIG. 1A, FIG. 1B, FIG. 2, and FIG. 3 are views illustrating a semiconductor device 1 according to an example embodiment of the present disclosure. FIG. 1A is a perspective view conceptually illustrating a semiconductor device 1 according to an example embodiment of the present disclosure. FIG. 1B is a perspective view conceptually illustrating an electrical connection relationship between first and second structures ST1 and ST2 of FIG. 1. FIG. 2 is a circuit diagram illustrating a circuit of a partial region of the first structure ST1 of FIG. 1A and FIG. 1B. FIG. 3 is a perspective view conceptually illustrating a memory cell array region MCA and interface regions IA disposed in the first structure ST1 and a sub word line driver region SWDR disposed in the second structure ST2, a sense amplifier region SAR, a conductive pattern control circuit region GCR, a back gate control circuit region BCR, and a peripheral circuit region PR. Additionally, FIG. 3 may illustrate word lines WL, conductive patterns CG, back gate electrodes BG, and bit lines BL.

Referring to FIGS. 1A, 1B, 2 and 3, a semiconductor device 1 according to an example embodiment may include a first structure ST1 and a second structure ST2 vertically overlapping the first structure ST1. The second structure ST2 may be disposed on the first structure ST1. Alternatively, the second structure ST2 may be disposed below the first structure ST1.

According to an example embodiment, the first structure ST1 may be a first chip structure including memory cells MC (see FIG. 2), and the second structure ST2 may be a second chip structure including a peripheral circuit used for the operation of the memory cells MC.

The first structure ST1 and the second structure ST2 may be bonded together by a bonding process such as a wafer bonding process. In some examples, the first structure ST1 may be electrically connected to the second structure ST2 through bonding of bonding pads formed on each bonding surface of the first structure ST1 and the second structure ST2.

The semiconductor device 1 may include a plurality of banks BA and an peripheral region PERI.

The peripheral region PERI may include a first peripheral region PERI1 within the first structure ST1 and a second peripheral region PERI2 within the second structure ST2. The peripheral region PERI may be a peripheral region in which peripheral circuits for input/output of data or commands, or input of power/ground are disposed.

The first structure ST1 may include a first bank region BA1 and the second structure ST2 may include a second bank region BA2.

The first and second structures ST1 and ST2 may further include a routing interconnection structure RTa electrically connecting the first bank region BA1 and the second bank region BA2. For example, the routing interconnection structure RTa may include first routing interconnection structures RT_La and RT_Lb disposed within the first structure ST1 and second routing interconnection structures RT_Ua and RT_Ub disposed within the second structure ST2.

The first routing interconnection structures RT_La and RT_Lb may include a first interconnection structure RT_La electrically connected to the first bank region BA1 and first bonding pads RT_Lb electrically connected to the first interconnection structure RT_La. The second routing interconnection structures RT_Ua and RT_Ub may include a second interconnection structure RT_Ua electrically connected to the second bank region BA2 and second bonding pads RT_Ub electrically connected to the second interconnection structure RT_Ua.

The first bonding pads RT_Lb and the second bonding pads RT_Ub may be in contact with and bonded to each other. For example, the first bonding pads RT_Lb and the second bonding pads RT_Ub may include copper and may be bonded to each other by a metal-to-metal bonding process. Accordingly, a bonding surface JN1 between the first structure ST1 and the second structure ST2 may include metal-to-metal bonding regions JNa in which the first bonding pads RT_Lb of the first structure ST1 and the second bonding pads RT_Ub of the second structure ST2 are bonded to each other and merge with each other, and dielectric-to-dielectric bonding regions JNb in which dielectric surfaces of the first structure ST1 and the second structure ST2 are bonded to each other and merge with each other.

The first bank region BA1 within the first structure ST1 may include a memory cell array region MCA and interface regions IA adjacent to the memory cell array region MCA as shown in FIGS. 2 and 3. For example, the interface regions IA may include a first interface region IA1 and a second interface region IA2 disposed on both sides of the memory cell array region MCA in a first horizontal direction (X-direction), and a third interface region IA3 and a fourth interface region IA4 disposed on both sides of the memory cell array region MCA in a second horizontal direction (Y-direction), perpendicular to the first horizontal direction (X-direction).

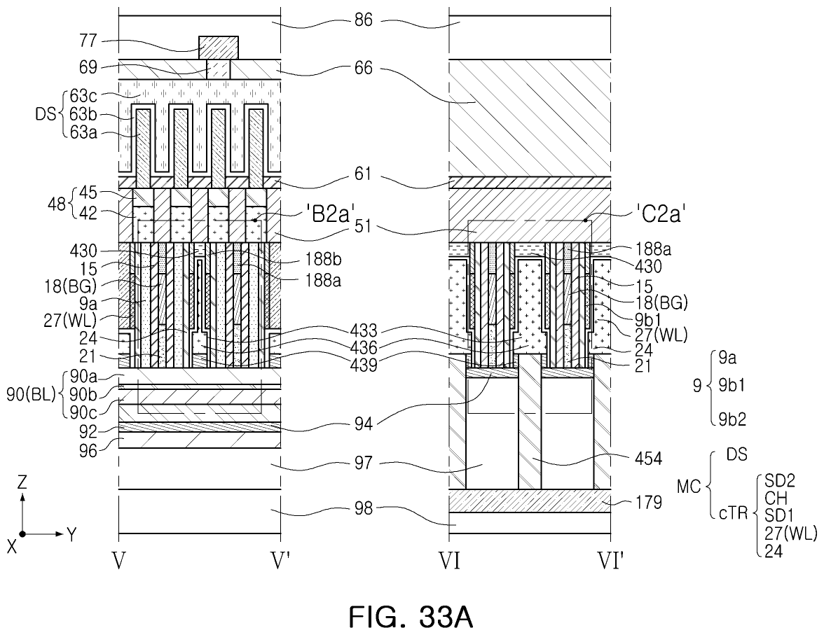

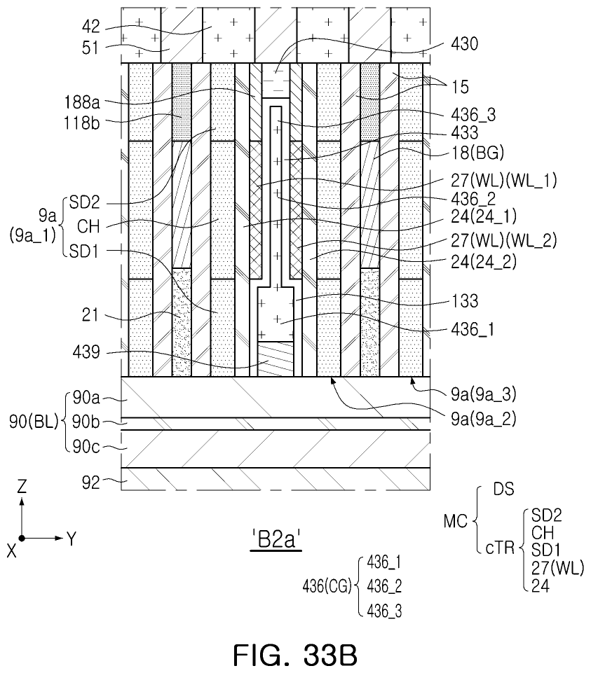

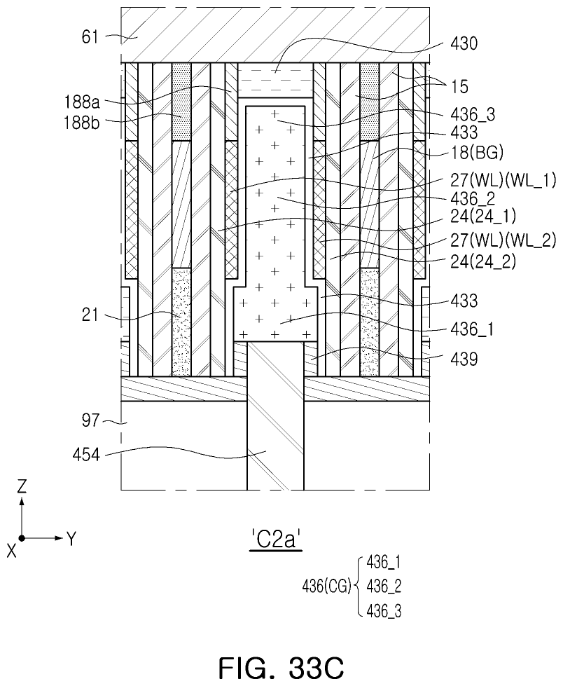

The first bank region BA1 in the first structure ST1 may include memory cells MC (see FIG. 2), word lines WL (see FIG. 2 and FIG. 33), bit lines BL (see FIG. 2 and FIG. 3), back gate electrodes BG (see FIG. 2 and FIG. 3), and conductive patterns CG.

The memory cells MC may be disposed in the memory cell array region MCA. Each of the memory cells MC may include a data storage structure DS that is configured to store data information, and electrically connected to a cell transistor cTR. In a DRAM, the data storage structure DS may be a cell capacitor configured to store data information.

The word lines WL may traverse the memory cell array region MCA and may be electrically connected to the memory cells MC, and may extend into the first and second interface regions IA1 and IA2 adjacent to the memory cell array region MCA. The word lines WL may extend into the first and second interface regions IA1 and IA2 the first horizontal direction.

The bit lines BL may traverse the memory cell array region MCA and may be electrically connected to the memory cells MC, and may extend into the third and fourth interface regions IA1 and IA2 adjacent to the memory cell array region MCA. Each of the bit lines BL may extend into the first and second interface regions IA1 and IA2 in the second horizontal direction.

The back gate electrodes BG may traverse the memory cell array region MCA and may be electrically connected to the memory cells MC, and may extend into the first and second interface regions IA1 and IA2. Each of the back gate electrodes BG may extend into the first and second interface regions IA1 and IA2 in the first horizontal direction.

The conductive patterns CG may traverse the memory cell array region MCA and may pass between the cell transistors cTR, and may extend into the first and second interface regions IA1 and IA2. In FIG. 3, the conductive patterns CG may be a first shield conductive patterns CG_FA that may reduce parasitic capacitance between the cell transistors cTR. The first shield conductive patterns CG_FA may be positioned vertically above the word lines WL. A conductive pattern, positioned between adjacent active patterns and partially disposed at a different level from a word line to reduce parasitic capacitance between adjacent cell transistors may be referenced as a “shield conductive pattern” and may improve the performance of cell transistors.

The second bank region BA2 in the second structure ST2 may include circuit regions in which circuits used for an operation of the memory cells MC are disposed. For example, the second bank region BA2 may include a sense amplifier region SAR, a sub word line driver region SWDR, a back gate circuit region BCR, a control circuit region GCR, and a peripheral circuit region PR.

Each of the sense amplifiers in the sense amplifier region SAR may be electrically connected to the bit lines BL by a bit line routing interconnection structure RT_BL and the sense amplifiers may read data information of the memory cells MC.

Each of the sub word line drivers in the sub word line driver region SWDR may be electrically connected to the word lines WL by a word line routing interconnection structure RT_WL and the sub word line driver is configured to activate or deactivate the memory cells MC. For example, the sub word line driver in the sub word line driver region SWDR may transmit a word line signal to each of the memory cells MC through the word line routing interconnection structure RT_WL and the word lines WL, and may activate or deactivate the memory cells MC.

Each of the back gate circuits of the back gate circuit region BCR may be electrically connected to the back gate electrodes BG by a back gate routing interconnection structure RT_BG and the back gate circuit may apply a back gate voltage to the back gate electrodes BG of the memory cells MC.

Each of the control circuits in the control circuit region GCR may be electrically connected to the conductive patterns CG by a control routing interconnection structure RT_CG and the control circuit may apply a control voltage or a shield voltage to the conductive patterns CG.

A peripheral circuit in the peripheral circuit region PR may control the circuits of the sense amplifier region SAR, the sub word line driver region SWDR, the back gate circuit region BCR and the control circuit region GCR.

According to an example, when the memory cells MC are activated, for reducing leakage current generated in the cell transistors cTR by the GIDL, a control voltage may be applied to the conductive patterns CG, in which the control voltage is generated by a control circuit of the control circuit region GCR. A voltage level of the control voltage may be lower than the voltage level applied to a selected word line among the word lines WL. The voltage level applied to the selected word lines among the word lines WL may correspond to a voltage level for activating the memory cells MC.

Alternatively, when the memory cells MC are activated, for reducing the parasitic capacitance between adjacent cell transistors cTR among the cell transistors cTR, a shield voltage may be applied to the conductive patterns CG. For example, the shield voltage may be a ground voltage. For example, 0V may be applied to the conductive patterns CG.

The routing interconnection structure RTa of FIG. 1B may be a signal path including the bit line routing interconnection structure RT_BL, the word line routing interconnection structure RT_WL, the back gate routing interconnection structure RT_BG, and the control routing interconnection structure RT_CG.

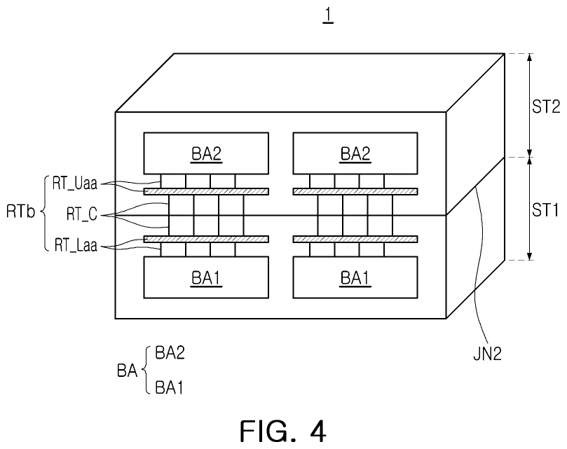

An example of the routing interconnection structure RTa and the bonding surface JN1 will be described with reference to FIG. 4. FIG. 4 is a conceptual perspective view illustrating an example of the routing interconnection structure RTa and the bonding surface JN1 of FIG. 1B.

Referring to FIG. 4, the routing interconnection structure RTa may be replaced with a routing interconnection structure RTb. The routing interconnection structure may not include the first bonding pads RT_Lb and the second bonding pads RT_Ub. The bonding surface JN1 in FIG. 1B may be replaced with a bonding surface JN2. The bonding surface JN2 may not include the intermetallic bonding regions JNa.

The routing interconnection structure RTb may include a first interconnection structure RT_Laa included in the first structure ST1 and electrically connected to the first bank region BA1, a second interconnection structure RT_Uaa included in the second structure ST2 and electrically connected to the second bank region BA2, and a connection structure RT_C extending from the first structure ST1 to the second structure ST2 and electrically connecting the first and second interconnection structures RT_Laa and RT_Uaa. The bonding surface JN2 between the first structure ST1 and the second structure ST2 may be formed through a dielectric-to-dielectric surface bonding in which a dielectric surface of the first structure ST1 and a dielectric surface of the second structure ST2 are bonded to each other. The connection structure RT_C may include a through-via or a through-connection plug that may pass through the bonding surface JN2.

Hereinafter, with reference to FIGS. 1A, 1B, 2 and 3, examples of the first structure ST1 of the semiconductor device 1 will be described. The routing interconnection structure RTa and the bonding surface JN1 described in FIG. 1B may be replaced with the routing interconnection structure RTb and the bonding surface JN2 described in FIG. 4. Additionally, the following example embodiment may be combined to form a different embodiment.

In addition, the elements disposed in the first interface region IA1, the memory cell array region MCA and the second interface region IA2, may be sequentially arranged in the first horizontal direction.

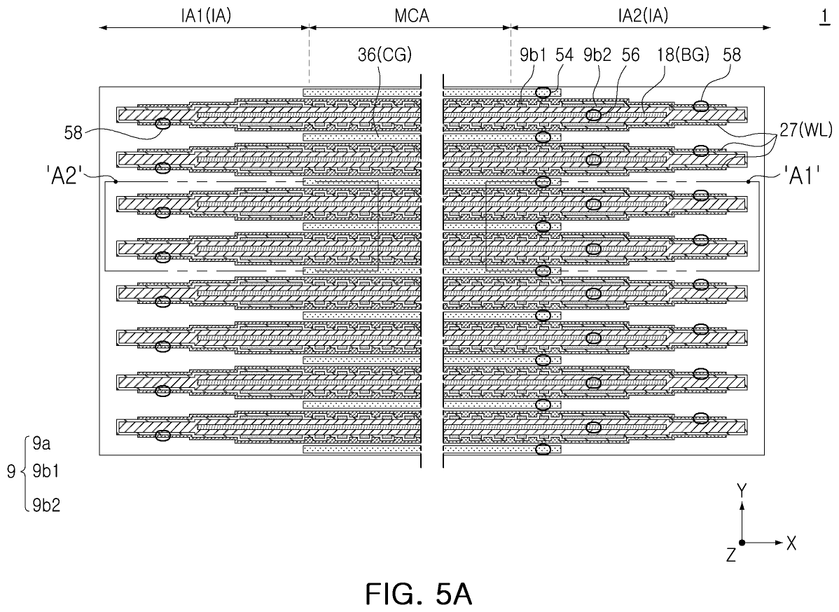

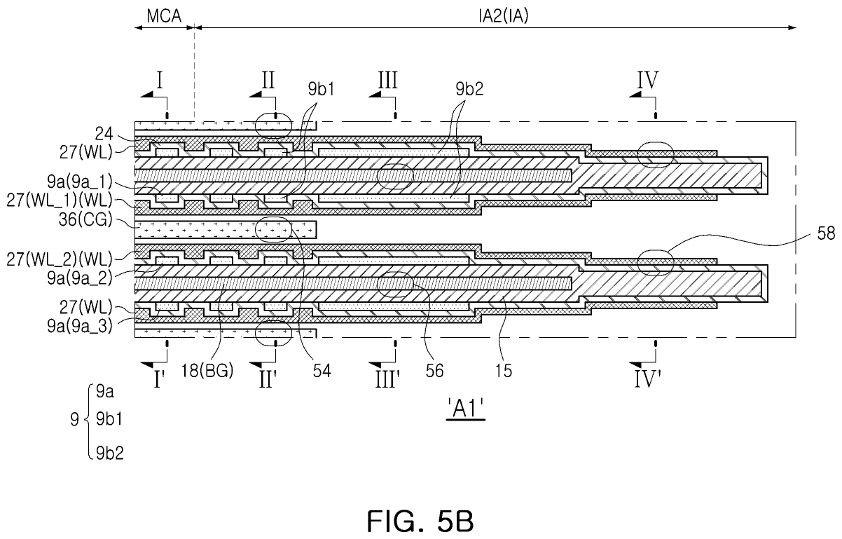

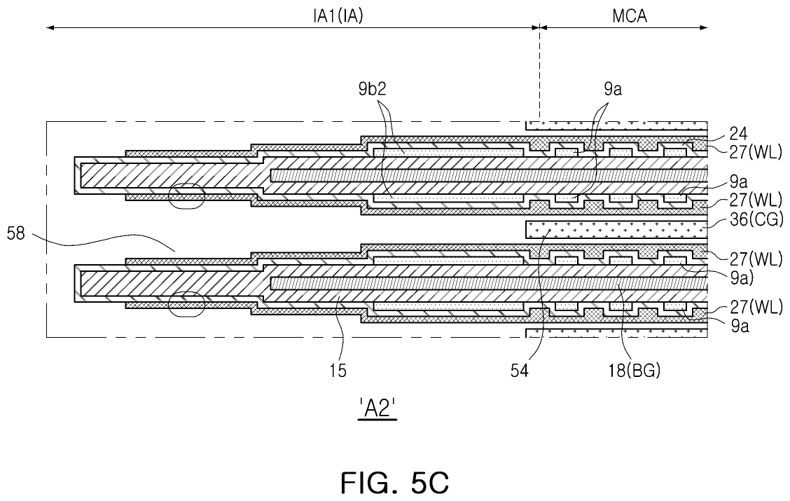

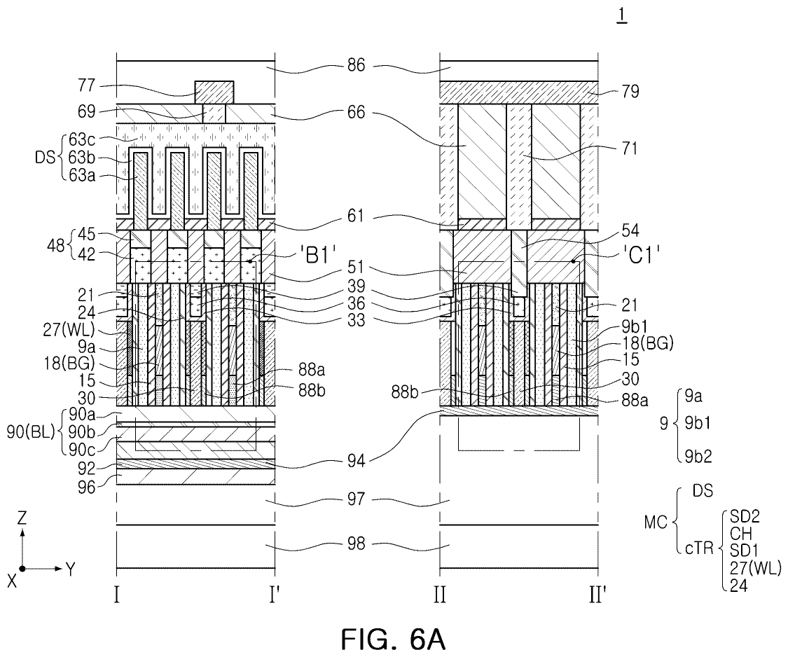

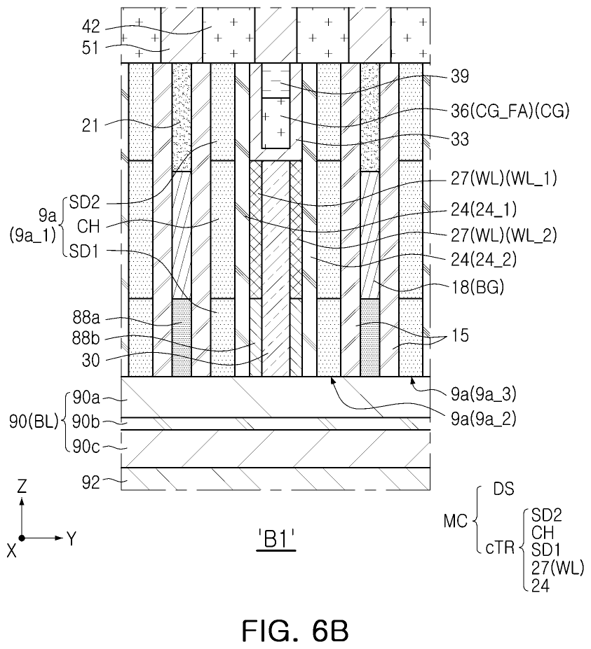

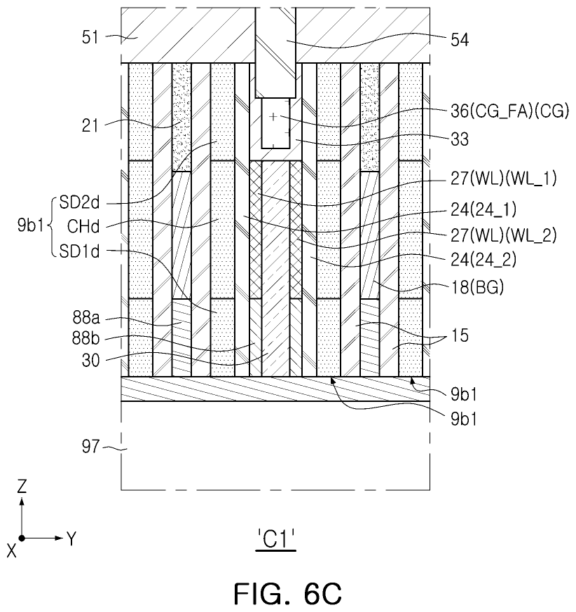

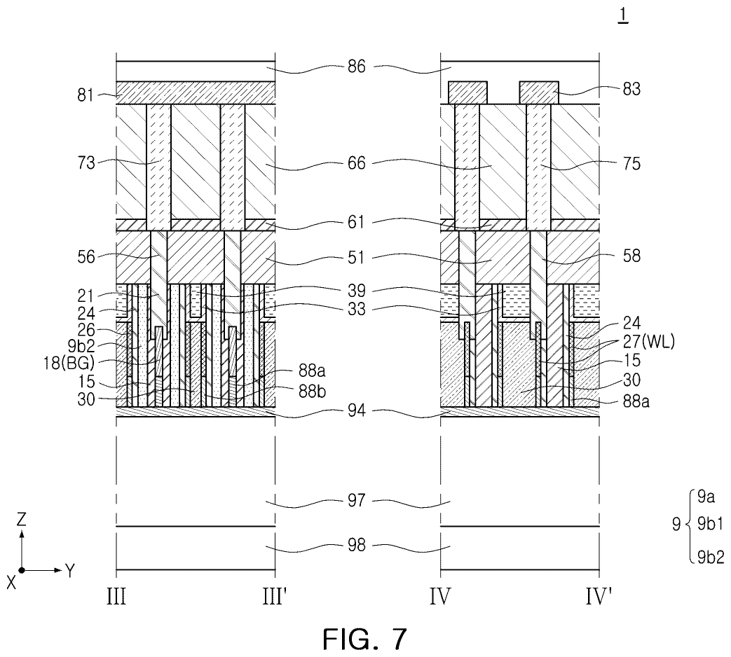

With reference to FIGS. 1A, 1B, 2 and 3, and FIGS. 5A, 5B, 5C, 6A, 6B, 6C and 7, an example of the semiconductor device 1 will be described. FIG. 5A is a plan view illustrating an example of a semiconductor device according to an example embodiment of the present disclosure, FIG. 5B is a partially enlarged view illustrating a region indicated by ‘A1’ in FIG. 5A, FIG. 5C is a partially enlarged view illustrating a region indicated by ‘A2’ in FIG. 5A, FIG. 6A is a cross-sectional view illustrating areas taken along lines I-I′ and II-II′ in FIG. 5B, FIG. 6B is a partially enlarged view illustrating a region indicated by ‘B1’ in FIG. 6A, FIG. 6C is a partially enlarged view illustrating a region indicated by ‘C1’ in FIG. 6A, and FIG. 7 is a cross-sectional view illustrating areas taken along lines III-III′ and IV-IV′ in FIG. 5A.

Referring to FIGS. 5A, 5B, 5C, 6A, 6B, 6C and 7 along with FIGS. 1A, 1B, 2 and 3, the semiconductor device 1 may include the memory cell array region MCA and the first and second interface regions IA1 and IA2, each of the first and second interface regions IA1 and IA2 is adjacent to the memory cell array region MCA in the first horizontal direction. The memory cell array region MCA may be disposed between the first and second interface regions IA1 and IA2.

The semiconductor device 1 may further include active patterns 9, the cell gate dielectric layers 24, gate electrodes 27, back gate electrodes 18, and back gate dielectric layers 15.

The active patterns 9 may include a semiconductor material that may be used as a channel region of a transistor. For example, the active patterns 9 may include a semiconductor material such as single crystal silicon. The active patterns 9 within the memory cell array region MCA may be disposed vertically at the same level.

The active patterns 9 may include cell active patterns 9a disposed within the memory cell array region MCA, and dummy active patterns 9b1 and 9b2 disposed within the first and second interface regions IA1 and IA2. Each of the active patterns 9 may be an elongated bar shape, an oval shape, or a bar shape close to an oval shape in the first horizontal direction.

The cell active patterns 9a may be spaced apart from each other and arranged along the first horizontal direction and the second horizontal direction within the memory cell array region MCA. Cell active patterns disclosed herein may be electrically connected to a bit line and a data storage structure.

The dummy active patterns 9b1 and 9b2 may include first dummy active patterns 9b1 having the same size as the cell active patterns 9a and second dummy active patterns 9b2 having a greater size than the first dummy active patterns 9b1. The dummy active patterns disclosed herein may be active patterns that are not electrically connected to a bit line and/or a data storage structure.

The first dummy active patterns 9b1 may be disposed between the cell active patterns 9a and the second dummy active patterns 9b2. A length of each of the second dummy active patterns 9b2 may be greater than a length of each of the cell active patterns 9a and the first dummy active patterns 9b1 when measured in the first horizontal direction. A width of each of the second dummy active patterns 9b2 may be substantially same as a width of each of the cell active patterns 9a and the first dummy active patterns 9b1 when measured in the second horizontal direction.

Each of the cell active patterns 9a may include a first source/drain region SD1, a second source/drain region SD2 disposed vertically at a different level from the first source/drain region SD1, and a channel region CH between the first and second source/drain regions SD1 and SD2. Each of the first source/drain region SD1 and the second source/drain region SD2 may be a drain region or a source region depending on a drive voltage applied between the first source/drain region SD1 and the second source/drain region SD2. The second source/drain region SD2 may be disposed vertically at higher level than the first source/drain region SD1. Each of the first and second dummy active patterns 9b1 and 9b2 may include a first dummy source/drain region SD1d disposed at the same level (same height or vertical level) as the first source/drain region SD1, a second dummy source/drain region SD2d disposed at the same level as the second source/drain region SD2, and a dummy channel region CHd disposed at the same level as the channel region CH.

The cell active patterns 9a may include a first cell active pattern 9a_1, a second cell active pattern 9a_2, and a third cell active pattern 9a_3, which are arranged sequentially along the second horizontal direction.

The back gate electrodes 18 may extend into the first and second interface regions IA1 and IA2 across the memory cell array region MCA. Each of the back gate electrodes 18 may have a line shape extending in the first horizontal direction. Each of the back gate electrodes 18 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or combinations thereof, but the invention is not limited thereto. Each of the back gate electrodes 18 may include a single layer or multiple layers of the above-described conductive materials.

The back gate electrodes 18 may include a first back gate electrode 18 passing between the second cell active pattern 9a_2 and the third cell active pattern 9a_3 and extending in the first horizontal direction. The first back gate among the back gate electrodes 18 may pass between the second dummy active patterns 9b2 away from the memory cell array region MCA.

The back gate dielectric layers 15 may cover side surfaces of the active patterns 9 adjacent to the back gate electrodes 18 and may extend in the first horizontal direction. The back gate dielectric layers 15 may also cover side surfaces of end portions of the back gate electrodes 18 within the first and second interface regions IA1 and IA2. The back gate dielectric layers 15 may pass between the back gate electrodes 18 and the active patterns 9 and may extend in the first horizontal direction. For example, a first back gate dielectric layer among the back gate dielectric layers 15 may be disposed between the second cell active pattern 9a_2 and the back gate electrode 18, and between the third cell active pattern 9a_3 and the back gate electrode 18.

The channel regions CH of the cell transistors cTR may be a floating body, and the back gate electrodes 18 adjacent to the channel regions CH may suppress a floating body effect at the channel regions CH, thereby minimizing the effect to the performance of the cell transistors cTR.

The gate electrodes 27 may be the word lines WL described above. Each of the gate electrodes 27 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or combinations thereof, but the invention is not limited thereto. Each of the gate electrodes 27 may include a single layer or multiple layers of the above-described conductive materials.

The gate electrodes 27 may include a first gate electrode WL_1 and a second gate electrode WL_2 passing between the first cell active pattern 9a_1 and the second cell active pattern 9a_2 and extending into the first and second interface regions IA1 and IA2.

The first gate electrode WL_1 may be adjacent to the first cell active pattern 9a_1, and the second gate electrode WL_2 may be adjacent to the second cell active pattern 9a_2. The first gate electrode WL_1 may have a side surface facing a side surface of the first cell active pattern 9a_1. The second gate electrode WL_2 may have a side surface facing a side surface of the second cell active pattern 9a_2.

At least a portion of each of the back gate electrodes 18 may be positioned vertically at the same level as the gate electrodes 27.

The gate dielectric layers 24 may surround side surfaces of the back gate dielectric layers 15, and the active patterns 9 may be disposed between the gate dielectric layers 24 and the back gate dielectric layers 15. The gate dielectric layers 24 may cover side surfaces of the back gate dielectric layers 15. Each of the active patterns 9 may have side surfaces facing each other in the first horizontal direction (X-direction) and side surfaces facing each other in the second horizontal direction (Y-direction). The side surfaces of the active patterns 9 facing each other in the first horizontal direction (X-direction) may be covered with the gate dielectric layers 24. Among the side surfaces of the active patterns 9 facing each other in the second horizontal direction (Y-direction), side surfaces facing the back gate electrodes 18 may be covered with the back gate dielectric layers 15, and side surfaces facing the gate electrodes 27 may be covered with the gate dielectric layers 24. Each of the active patterns 9 may have first and second side surfaces facing each other in the second horizontal direction. The first side surfaces of the active patterns 9 facing the gate electrodes 27 in the second horizontal direction (Y-direction) may be covered with the gate dielectric layers 24. The second side surfaces of the active patterns 9 facing the back gate electrodes 18 may be covered with the back gate dielectric layers 15. The gate dielectric layers 24 may be disposed between the gate electrodes 27 and the active patterns 9.

The gate dielectric layers 24 may include a first gate dielectric layer 24_1 between the first gate electrode WL_1 and the first cell active pattern 9a_1, and a second gate dielectric layer 24_2 between the second gate electrode WL_2 and the second cell active pattern 9a_2.

Each of the cell transistors cTR may include the first source/drain region SD1, the second source/drain region SD2, the channel region CH, and a gate electrode 27. The first source/drain region SD1, the second source/drain region SD2 and the channel region CH are disposed in a corresponding cell active pattern among the cell active patterns 9a, and a gate dielectric layer 24 is disposed between the channel region CH and the gate electrode 27. The gate electrode 27 may have a side surface facing the side surface of the channel region CH.

According to embodiments, depending on operations performed on the memory cells MC, such as read and write, each of the first and second source/drain regions SD1 and SD2 may be determined as a source region or a drain region. For example, during a write operation, the first source/drain region SD1 may be a source region of the cell transistor cTR, and the second source/drain region SD2 may be a drain region of the cell transistor cTR. During a read operation, the first source/drain region SD1 may be a drain region of the cell transistor cTR, and the second source/drain region SD2 may be a source region of the cell transistor cTR. The semiconductor device 1 may further include bit line structures 90 and 92. The bit lines 90 may be the bit lines BL described above.

Each of the bit line structures 90 and 92 may include a bit line 90 and a bit line capping pattern 92 below the bit line 90. The bit line capping pattern 92 may be formed of an insulating material. Each of the bit lines 90 may include a first material layer 90a, a second material layer 90b under the first material layer 90a, and a third material layer 90c on the second material layer 90b. The first material layer 90a may include at least one of doped silicon, doped germanium, and doped silicon-germanium. The second material layer 90b may include at least one of a metal-semiconductor compound layer and a metal nitride. The third material layer 90c may include at least one of a metal and a metal nitride.

The semiconductor device 1 may further include an insulating liner 94 covering lower surfaces and side surfaces of bit line structures 90 and 92 and extending to cover lower surfaces of the dummy active patterns 9b1 and 9b2.

The semiconductor device 1 may further include a bit line shield pattern 96 disposed at sides of the bit line structures 90 and 92. More specifically, the bit line shield pattern 96 may be formed between lower surface of the insulating liner 94 and lower surfaces of the bit line structures 90 and 92. The bit line shield pattern 96 may be formed of a conductive material. The bit line shield pattern 96 may reduce parasitic capacitance between the bit lines 90, thereby reducing crosstalk between bit lines 90 while transmitting a signal, thereby improving a signal transmission speed of the bit lines 90.

The semiconductor device 1 may further include a first lower insulating layer 97 disposed below the bit line shield pattern 96 and the insulating liner 94, and a second lower insulating layer 98 disposed below the first lower insulating layer 97.

The semiconductor device 1 may further include first back gate capping patterns 21 on the back gate electrodes 18 and second back gate capping patterns 88a at bottom of the back gate electrodes 18, in which both the first back gate capping patterns 21 and the second back gate capping patterns 88a may have insulating properties.

The semiconductor device 1 may further include gate capping patterns 88b disposed below the gate electrodes 27, in which gate capping patterns 88b may have insulating properties.

The semiconductor device 1 may further include an insulating layer 30 disposed between the adjacent gate electrodes 27 and between the gate capping patterns 88b.

According to an embodiment, the semiconductor device 1 may include first conductive patterns 36, first insulating capping patterns 39 on the first conductive patterns 36, and buffer dielectric layers 33 covering lower surfaces of the first conductive patterns 36 and covering side surfaces of the first conductive patterns 36 and the first insulating capping patterns 39.

The first conductive patterns 36 may be disposed between the active patterns 9. The first conductive patterns 36 may be in a line shape extending in the first horizontal direction. The first conductive patterns 36 may pass between the active patterns 9 within the memory cell array region MCA and may extend in the first horizontal direction, and may extend into the first and second interface regions IA1 and IA2. The first conductive patterns 36 may be spaced apart from each other in the second horizontal direction. The first conductive patterns 36 may be spaced apart from the gate electrodes 27. At least a portion of each of the first conductive patterns 36 may be positioned vertically at a different level from the gate electrodes 27. For example, the first conductive patterns 36 may be positioned vertically at a higher level than the gate electrodes 27. For example, A first conductive pattern among the first conductive patterns 36 may be disposed between the first and second cell active patterns 9a_1 and 9a_2 and may be spaced apart from each other, and at least a portion of the first conductive pattern may be positioned vertically at a different level from the first and second gate electrodes WL_1 and WL_2, and the first conductive pattern may be spaced apart from the first and second gate electrodes WL_1 and WL_2. The first conductive patterns 36 may not be disposed between the second and third active patterns 9a_2 and 9a_3. The first conductive patterns 36 may not vertically overlap the back gate electrodes 18. Because the first conductive pattern is shared by the first and second word lines WL_1 and WL_2, the width of the first conductive pattern may be wider than each width of the first and second gate electrodes WL_1 and WL_2.

A width of each of the first conductive patterns 36 in the second horizontal direction may be greater than a width of each of the gate electrodes 27 in the second horizontal direction. Therefore, from a process perspective, the first conductive patterns 36 may be implemented in the memory cells with additional processing steps.

A first distance between the first conductive pattern 36 and the first cell active pattern 9a_1 may be greater than a second distance between the first gate electrode WL_1 and the first cell active pattern 9a_1. A third distance between the first conductive pattern 36 and the second cell active pattern 9a_2 may be greater than a fourth distance between the second gate electrode WL_2 and the second cell active pattern 9a_2. The side and lower surfaces of the first conductive pattern 36 may be covered by first buffer dielectric layer 33.

The first gate dielectric layer 24_1 and the first buffer dielectric layer 33 may be disposed between the first cell active pattern 9a_1 and the first conductive pattern 36. The second gate dielectric layer 24_2 and the first buffer dielectric layer 33 may be disposed between the second cell active pattern 9a_2 and the first conductive pattern 36.

A width of the first conductive pattern 36 in the second horizontal direction may be greater than a width of each of the first and second gate electrodes WL_1 and WL_2 in the second horizontal direction.

The first conductive patterns 36 may be positioned vertically over the gate electrodes 27 and the insulating layers 30. Upper surfaces of the first conductive patterns 36 may be vertically lower than upper surfaces of the active patterns 9.

At least a portion of each of the first conductive patterns 36 may be disposed between the second source/drain regions. For example, among the first conductive patterns 36, at least a portion of the first conductive pattern 36 passing between the first and second cell active patterns 9a_1 and 9a_2 and extending in the first horizontal direction may be disposed between the second source/drain region SD2 of the first cell active pattern 9a_1 and the second source/drain region SD2 of the second cell active pattern 9a_2.

The first conductive patterns 36 may be disposed between the second source/drain regions SD2 adjacent to each other in the second horizontal direction. The first conductive patterns 36 may be disposed at a higher level than the channel regions CH.

Each of the first conductive patterns 36 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or combinations thereof, but the invention is not limited thereto. Each of the first conductive patterns 36 may include a single layer or multiple layers of the aforementioned conductive materials. The first conductive patterns 36 may include a different material from the gate electrodes 27. For example, the gate electrodes 27 may include a metallic material such as a metal or a metal nitride, and the first conductive patterns 36 may include a material different from the material of the gate electrodes 27, for example, doped polysilicon.

The gate electrodes 27 may extend from the memory cell array region MCA into the first and second interface regions IA1 and IA2 by a first length. The back gate electrodes 18 extend from the memory cell array region MCA into the first and second interface regions IA1 and IA2 by a second length, in which the first length is greater than the second length. The first conductive patterns 36 may extend from the memory cell array region MCA into the first and second interface regions IA1 and IA2 by a third length, in which the first length is greater than the third length. The second length may be greater than the third length. A first insulating capping patterns 39 may be disposed on the first conductive patterns 36.

Upper surfaces of the first insulating capping patterns 39 may be substantially same level as the upper surfaces of the active patterns 9. The upper surfaces of the buffer dielectric layers 33 may be coplanar with the upper surfaces of the first insulating capping patterns 39. The buffer dielectric layers 33 may be disposed between the lower surfaces of the first conductive patterns 36 and the insulating layers 30, and between the side surfaces of the first conductive patterns 36 and the side surfaces of the active patterns 9. The buffer dielectric layer 33 may be disposed between the first cell active pattern 9a_1 and the first conductive pattern 36, and between the second cell active pattern 9a_2 and the first conductive pattern 36, and may be disposed between the first conductive pattern 36 and the first and second gate electrodes WL_1 and WL_2.

The first conductive patterns 36 may be spaced apart from the gate electrodes 27 by the buffer dielectric layers 33.

The first gate dielectric layer 24_1 may extend from a portion disposed at the same level as the first gate electrode WL_1 to a space between the buffer dielectric layer 33 and the first cell active pattern 9a_1, and the second gate dielectric layer 24_2 may extend from a portion disposed at the same level as the second gate electrode WL_2 to a space between the buffer dielectric layer 33 and the second cell active pattern 9a_2.

The semiconductor device 1 may further include contact structures 48 and insulating structures 51. The contact structures 48 may be disposed on the cell active patterns 9a. The contact structures 48 may be connected to the cell active patterns 9a. For example, the contact structures 48 may be electrically connected to the second source/drain regions SD2.

Each of the contact structures 48 may include a first material layer 42 and a second material layer 45 on the first material layer 42. The first material layer 42 may include a material such as doped silicon. The second material layer 45 may include at least one of a metal, a metal nitride, and a metal-semiconductor compound. The insulating structure 51 may surround side surfaces of the contact structures 48.

The semiconductor device 1 may further include gate contact plugs 58, back gate contact plugs 56, and first conductive contact plugs 54, disposed within the first and second interface regions IA1 and IA2.

The gate contact plugs 58 may penetrate through the insulating structure 51 and may be connected to the gate electrodes 27. Each of the gate contact plugs 58 may be in contact with an upper surface and partially with side surfaces of an upper region of corresponding gate electrode among the gate electrodes 27.

The back gate contact plugs 56 may penetrate the insulating structure 51 and may be connected to the back gate electrodes 18.

Each of the back gate contact plugs 56 may be in contact with an upper surface and partially with side surfaces of an upper region of corresponding back gate electrode among the back gate electrodes 18.

The first conductive contact plugs 54 may penetrate the insulating structure 51 and may be connected to the first conductive patterns 36. More specifically, the first conductive contact plugs 54 may penetrate through the insulating structure 51 and the first insulating capping patterns 39, and may be connected to upper surfaces of the first conductive patterns 36.

According to an example, the gate contact plugs 58 may be electrically connected to the gate electrodes 27 within the first and second interface regions IA1 and IA2.

The back gate contact plugs 56 may be electrically connected to the back gate electrodes 18 within the second interface region IA2, and may not be disposed within the first interface region IA1.

The first conductive contact plugs 54 may be electrically connected to the first conductive patterns 36 within the second interface region IA2, and may not be disposed within the first interface region IA1.

The first dummy active patterns 9b1 may not be disposed within the second interface region IA2, but may be disposed within the first interface region IA1.

The second dummy active patterns 9b2 may be disposed within the first and second interface regions IA1 and IA2.

The first conductive contact plugs 54 may pass between the first dummy active patterns 9b1 adjacent to each other in the second horizontal direction within the second interface region IA2, and may be electrically connected to the first conductive patterns 36.

The back gate contact plugs 56 may pass between the second dummy active patterns 9b2 adjacent to each other in the second horizontal direction within the second interface region IA2, and may be electrically connected to the back gate electrodes 18.

The gate contact plugs 58 may be electrically connected to the gate electrodes 27 in a region that is farther from the memory cell array region MCA than the second dummy active patterns 9b2.

The semiconductor device 1 may include the contact structures 48, the gate contact plugs 58, the back gate contact plugs 56, the first conductive contact plugs 54, and an insulating etch stop layer 61 disposed on the insulating structure 51.

The information storage structure DS may include first electrodes 63a penetrating through the insulating etch stop layer 61 and connected to the contact structures 48 and extending upwardly, a dielectric layer 63b covering the first electrodes 63a and the etch stop layer 61, and a second electrode 63c covering the dielectric layer 63b. The data storage structure DS may be cell capacitors configured to store data information in a memory such as a DRAM.

Each of the memory cells MC may include the data storage structure DS and the cell transistor cTR.

The contact structures 48 may be disposed between the data storage structure DS and the cell transistors cTR. The data storage structure DS may be electrically connected to the cell transistors cTR by the contact structures 48.

The semiconductor device 1 may further include a first upper insulating layer 66 on the data storage structure DS and the insulating etch stop layer 61, and upper contact plugs 69, 71, 73 and 75 penetrating through the first upper insulating layer 66.

The upper contact plugs 69, 71, 73 and 75 may include a first upper contact plug 69 electrically connected to the second electrode 63c, second upper contact plugs 71 electrically connected to the first conductive contact plugs 54, third upper contact plugs 73 electrically connected to the back gate contact plugs 56, and fourth upper contact plugs 75 electrically connected to the gate contact plugs 58.

The semiconductor device 1 may further include upper interconnections 77, 79, 81 and 83 and a second upper insulating layer 86.

The upper interconnections 77, 79, 81 and 83 may be disposed on the first upper insulating layer 66 and the upper contact plugs 69, 71, 73 and 75. The second upper insulating layer 86 may be disposed on the first upper insulating layer 66 and the upper interconnections 77, 79, 81 and 83. The upper interconnections 77, 79, 81 and 83 may include a first upper interconnection 77 electrically connected to the first upper contact plug 69, a second upper interconnection 79 electrically connected to the second upper contact plugs 71, a third upper interconnection 81 electrically connected to the third upper contact plugs 73, and a fourth upper interconnection 83 electrically connected to the fourth upper contact plugs 75, respectively. The same back gate voltage may be applied to the back gate electrodes 18 disposed in the memory cell array region MCA by the third upper interconnection 81.

According to embodiments, operations of the memory cells MC may include activating the memory cells MC and performing operations such as reading or writing data. For example, the operations of the memory cells MC may denote storing data in the memory cells MC or reading data stored in the memory cells MC.

The first conductive patterns 36 may reduce parasitic capacitance between the second source/drain regions SD2 adjacent to each other in the second horizontal direction (Y-direction), and may improve the performance of the cell transistors cTR.

According to an example, the first conductive patterns 36 may be first shield conductive patterns CG_FA that may reduce parasitic capacitance between the cell transistors cTR.

During operation of the memory cells MC such as reading or writing data, a shield voltage may be applied to the first conductive patterns 36 by the control circuit of the control circuit region GCR, and the first conductive patterns 36 to which the shield voltage is applied may suppress or reduce parasitic capacitance between the second source/drain regions SD2 of the cell transistors cTR adjacent to each other in the second horizontal direction. The shield voltage applied to the first conductive patterns 36 may be a ground voltage. The ground voltage applied to the first conductive patterns 36 may be 0V.

When the memory cells MC are activated, an operation of applying the shield voltage to the first conductive patterns 36 using the control circuit of the control circuit region GCR may be performed to suppress or reduce the parasitic capacitance between the second source/drain regions SD2 of the cell transistors cTR adjacent to each other in the second horizontal direction. Accordingly, the first conductive patterns 36 may improve the performance of the semiconductor device 1.

According to an example embodiment, while the memory cells MC are activated to perform operations such as reading or writing data, the shield voltage may be applied to the first conductive patterns 36 by the control circuit of the control circuit region GCR, thereby suppressing or reducing the parasitic capacitance between the second source/drain regions SD2 of the cell transistors cTR adjacent to each other in the second horizontal direction.

Hereinafter, example embodiments of the operating method of the semiconductor device 1 will be described. The various example embodiments described below may be combined to form a different embodiment. The elements described above may be directly cited without a separate detailed description, or descriptions thereof may be omitted. Additionally, the elements that may be modified or replaced are described with reference to the drawings below, but the elements that may be modified, replaced, or added may be combined with each other or with the elements to form a different embodiment of the present disclosure. Additionally, the elements described may be either plural or singular.

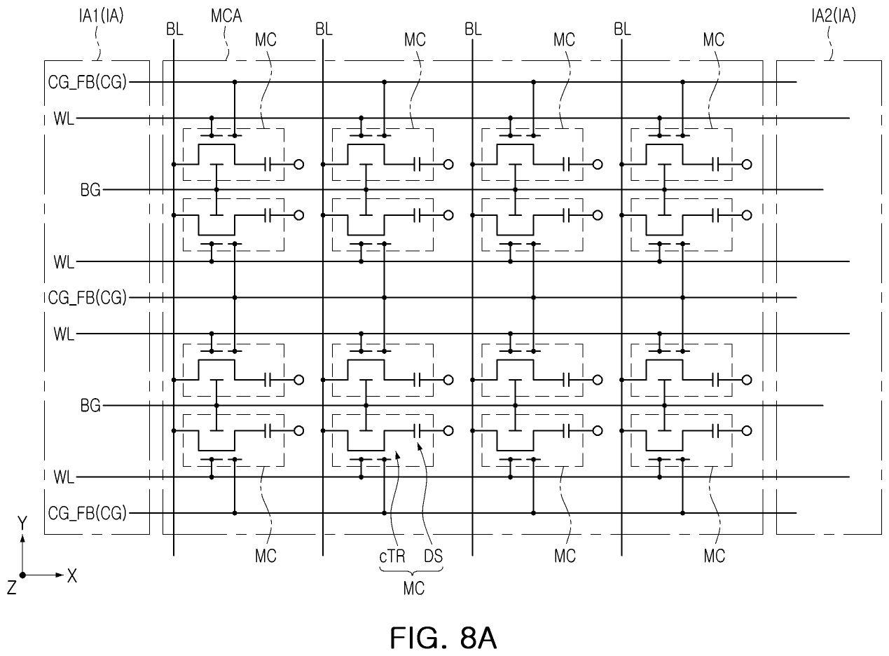

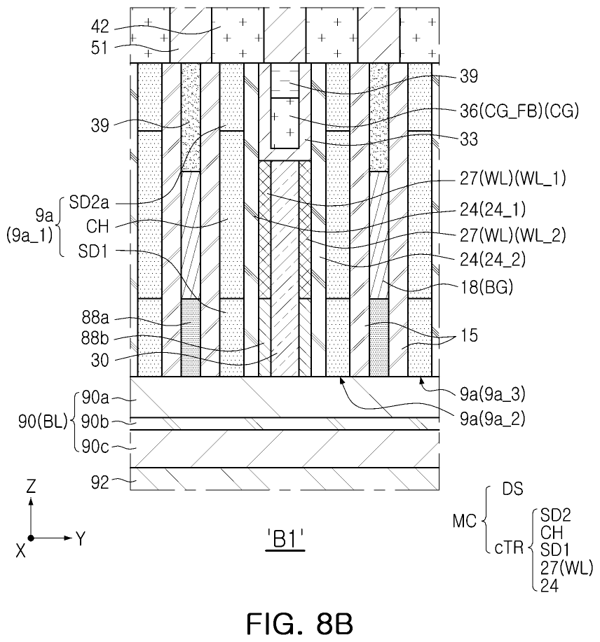

Referring to FIGS. 8A and 8B, an example embodiment of the semiconductor device 1 and the operating method of the semiconductor device 1 will be described. FIG. 8A is a circuit diagram corresponding to the circuit diagram of FIG. 2, and FIG. 8B is a partially enlarged view corresponding to FIG. 6B.

Referring to FIGS. 8A and 8B, the second source/drain region SD2 shown in FIG. 6B may be replaced with a second source/drain region SD2a positioned vertically at a higher level than a lower surface of the first conductive pattern 36. At least a portion of the first conductive pattern 36 may be positioned vertically at the same level as the channel region CH. The first conductive pattern 36 may include a portion disposed at the same level as the channel region CH and a portion disposed at a same level as a lower region of the second source/drain region SD2a. Among the first conductive patterns 36, the first conductive pattern 36 disposed between the first cell active pattern 9a_1 and the second cell active pattern 9a_2 may include a portion disposed between the channel region CH of the first cell active pattern 9a_1 and the channel region CH of the second cell active pattern 9a_2. As a portion of the first conductive pattern 36 is disposed between the channel region CH of the first cell active pattern 9a_1 and the channel region CH of the second cell active pattern 9a_2, the distance between the top point of the first gate electrode WL_1 and the bottom point of the second source/drain region SD2a increases. Because of the increased distance, electric field formed between the first gate electrode WL_1 and the second source/drain region SD2a may be reduced, thereby reducing the GIDL.

The first conductive patterns 36 may reduce leakage current generated by the GIDL in the cell transistors cTR adjacent to the first conductive patterns 36, thereby improving the performance of the cell transistors cTR.

The first conductive patterns 36 may be first control gate electrodes CG_FB that may reduce leakage current generated in the cell transistors cTR by the GIDL. A control gate electrode that reduces leakage current of cell transistors due to Gate-Induced-Drain Leakage (GIDL) may be referenced as “shield gate electrode” and may reduce the parasitic capacitance between adjacent cell transistors and reduce leakage current of cell transistors (e.g., reduce GIDL).

When the memory cells MC are activated, a control voltage may be applied to the first conductive patterns 36 by the control circuit of the control circuit region GCR, and the first conductive patterns 36 to which the control voltage is applied may reduce the leakage current generated by the GIDL in the cell transistors cTR.

When the memory cells MC are activated, for reducing the leakage current generated by the GIDL in the cell transistors cTR, a lower voltage than the voltage applied to the selected word lines among the word lines WL may be applied to the first conductive pattern 36 by the control circuit of the control circuit region GCR. The voltage applied to the selected word lines among the word lines WL may be a voltage for activating the memory cells MC. Accordingly, by adding the first conductive patterns 36 in the cell transistors cTR, which may be the first control gate electrodes CG_FB, the performance of the semiconductor device 1 may be improved.

According to an example embodiment, while the memory cells MC are activated to perform operations such as reading or writing data, the leakage current generated in the cell transistors cTR by the GIDL may be reduced by applying a control voltage to the first conductive patterns 36 by the control circuit of the control circuit region GCR.

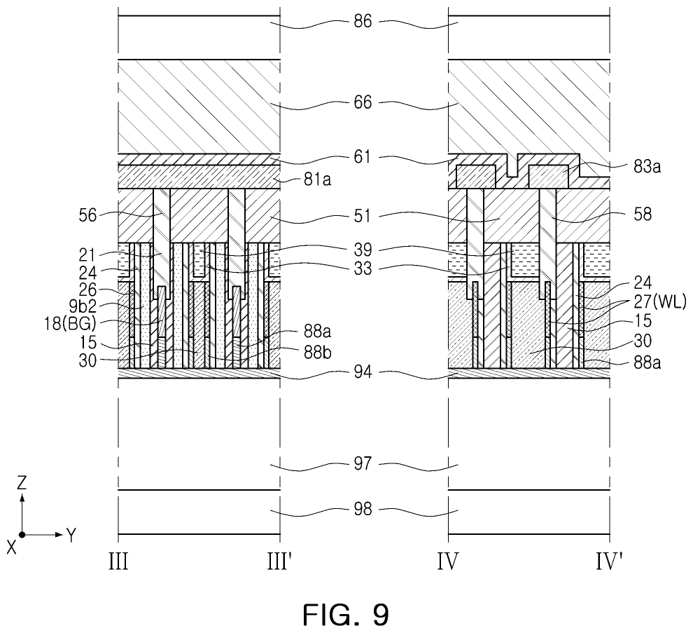

An example embodiment of the semiconductor device 1 will be described with reference to FIG. 9. FIG. 9 is a cross-sectional view corresponding to FIG. 7.

Referring to FIG. 9, the third upper interconnection 81 shown in FIG. 7 and the fourth upper interconnections 83 may be replaced with a third upper interconnection 81a and fourth upper interconnections 83a as shown in FIG. 9, and the third upper contact plugs 73 and the fourth upper contact plugs 75 shown in FIG. 7 may be omitted. The insulating etch stop layer 61 may cover the third upper interconnection 81a and the fourth upper interconnections 83a.

The third upper interconnection 81a may be electrically connected to the back gate contact plugs 56, and the fourth upper interconnections 83a may be electrically connected to the gate contact plugs 58.

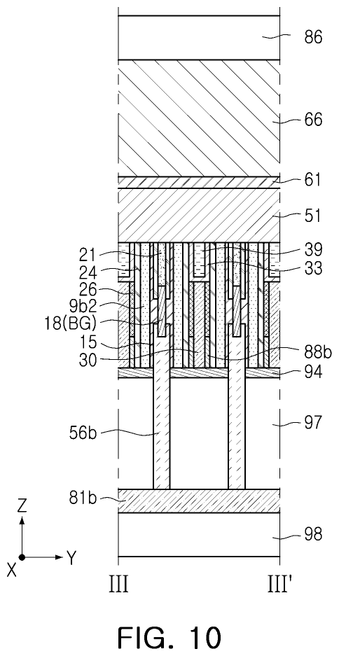

Referring to FIG. 10, an example embodiment of the semiconductor device 1 will be described. FIG. 10 is a cross-sectional view corresponding to a cross-sectional area of line III-III′ of FIG. 7.

The back gate contact plugs 56 may be replaced with back gate contact plugs 56b extending upwardly by penetrating through the first back insulating layer 97 and contacting lower surfaces and side surfaces of lower regions of each of the back gate electrodes 18, and the third upper contact plugs 73 and the third upper interconnection 81 may be replaced with a rear interconnection 81a connected to the back gate contact plugs 56b below the first back insulating layer 97.

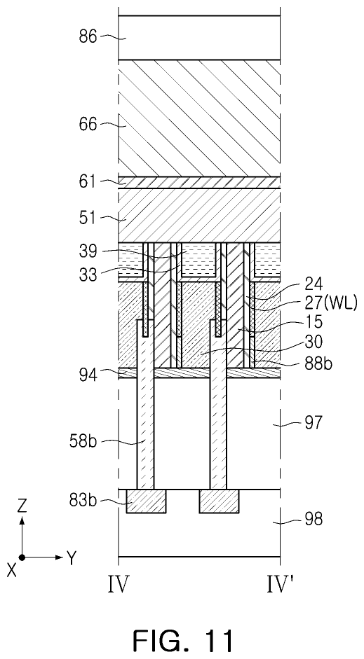

Referring to FIG. 11, an example embodiment of the semiconductor device 1 will be described. FIG. 10 is a cross-sectional view corresponding to a cross-sectional region of line IV-IV′ of FIG. 7.

Referring to FIG. 11, the gate contact plugs 58 shown in FIG. 7 may be replaced with gate contact plugs 58b extending upwardly by penetrating through the first rear insulating layer 97 and contacting lower surfaces and side surfaces of lower regions of each of the gate electrodes 27, and the fourth upper contact plugs 75 and the fourth upper interconnections 83 may be replaced with rear interconnections 83b connected to the gate contact plugs 58b below the first rear insulating layer 97.

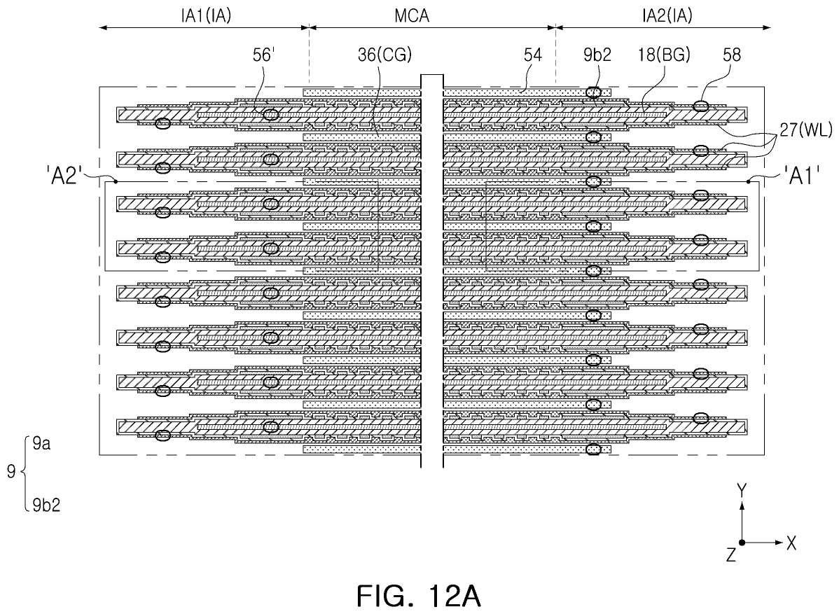

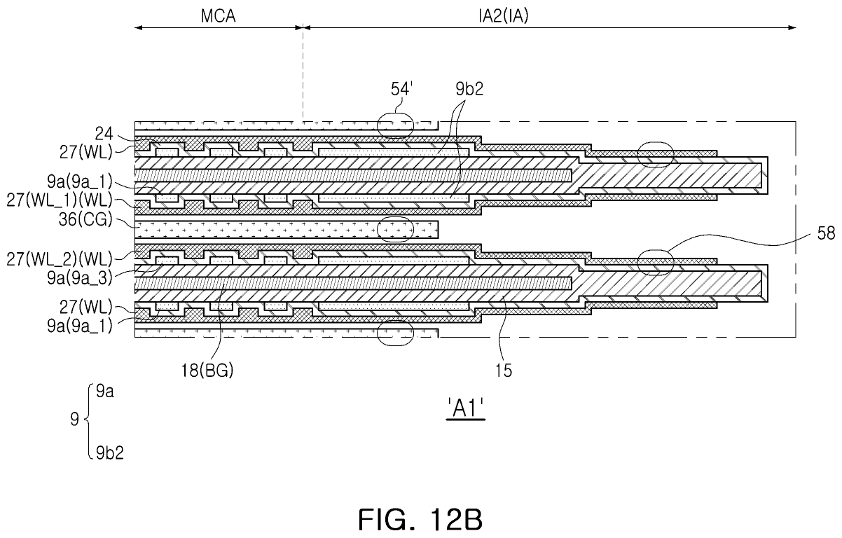

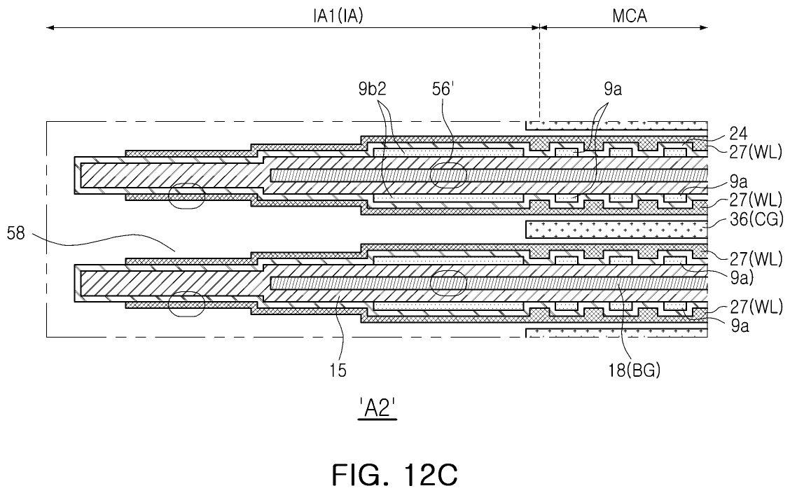

Referring to FIGS. 12A, 12B and 12C, an example embodiment of the semiconductor device 1 will be described. FIG. 12A is a plan view corresponding to FIG. 5A, FIG. 12B is a partially enlarged view of a region indicated as ‘A1’ in FIG. 12A, FIG. 12C is a partially enlarged view of a region indicated as ‘A2’ in FIG. 12A.

Referring to FIGS. 12A, 12B and 12C, the first conductive patterns 36 may extend to a space between the second dummy active patterns 9b2 within the second interface region IA2. The back gate contact plugs 56 shown in FIG. 5A may be replaced with back gate contact plugs 56′ disposed in the first interface region IA1. The back gate contact plugs 56′ may be connected to the back gate electrodes 18 disposed between the second dummy active patterns 9b2 within the first interface region IA1.

The first conductive contact plugs 54 may be replaced with first conductive contact plugs 54′ connected to the first conductive patterns 36 disposed between the second dummy active patterns 9b2 within the second interface region IA2.

The first dummy active patterns 9b1 (see FIG. 5A and FIG. 5B) may be omitted, thereby reducing a total area of the interface regions IA.

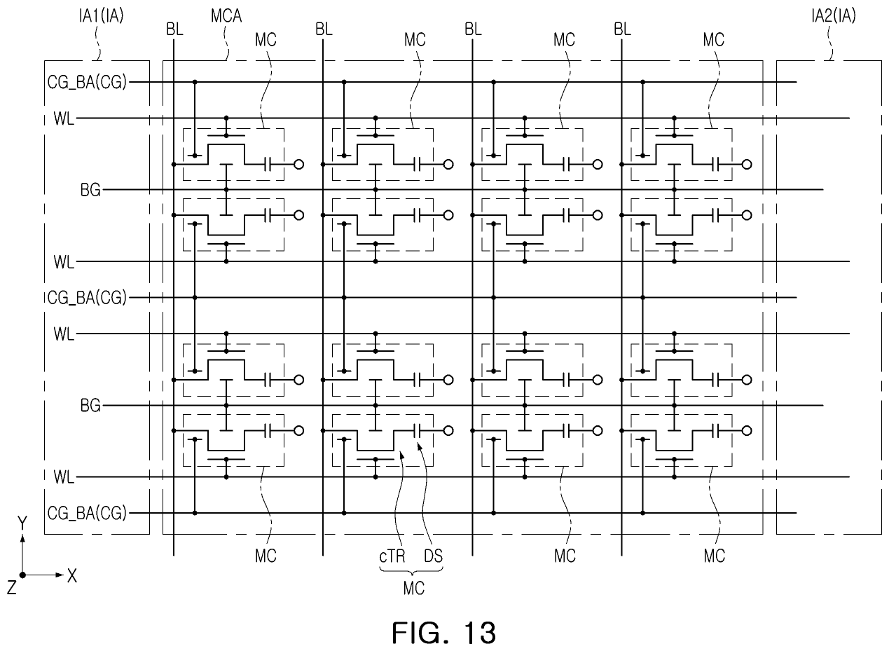

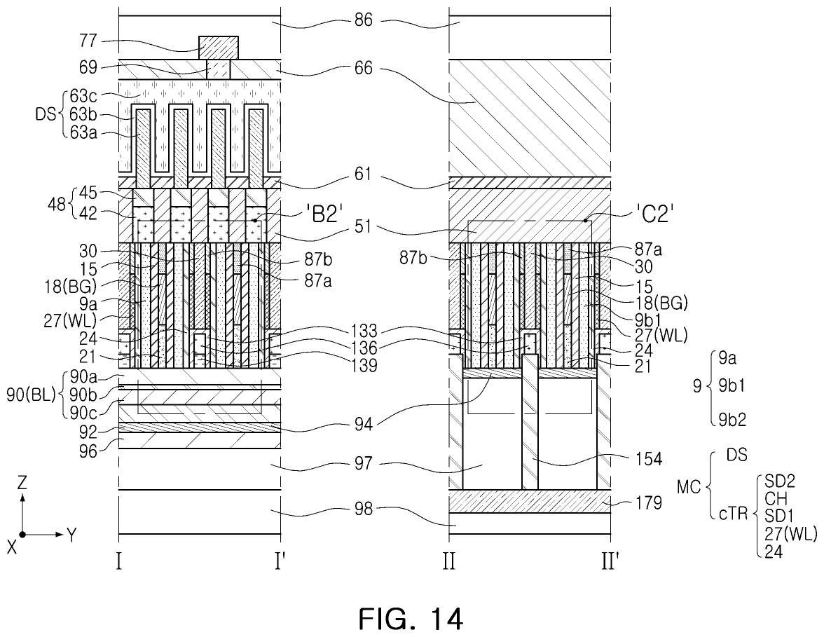

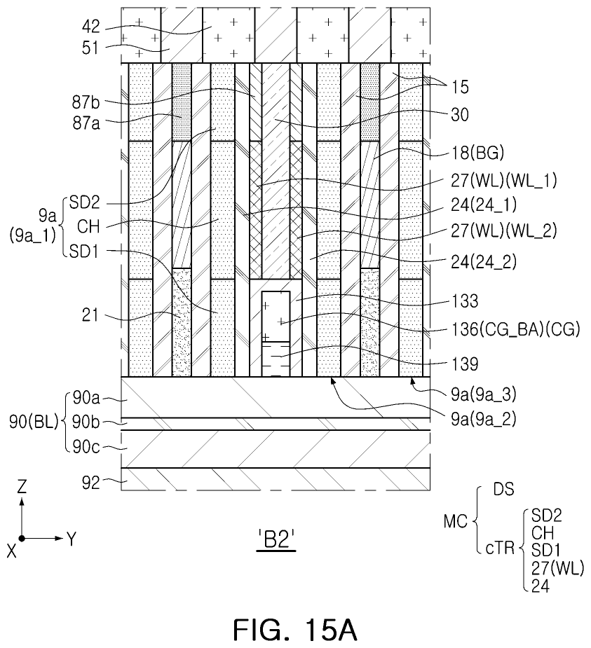

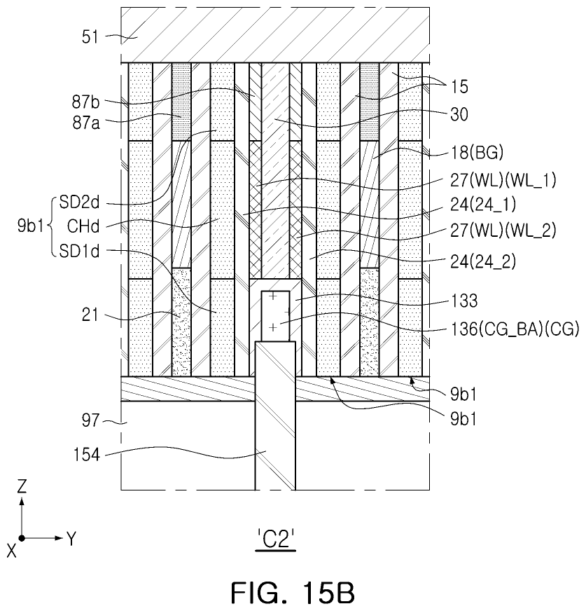

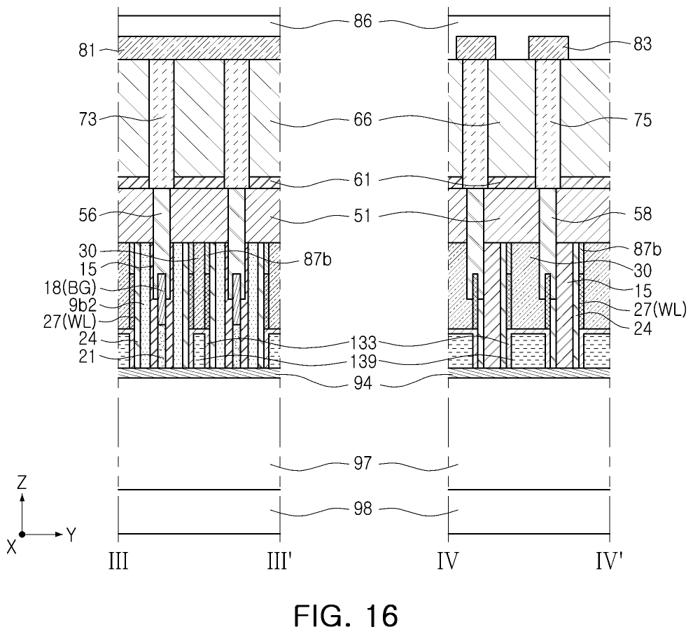

Referring to FIGS. 13, 14, 15A, 15B and 16, examples of the semiconductor device 1 and the operating method of the semiconductor device 1 will be described. FIG. 13 is a circuit diagram corresponding to the circuit diagram of FIG. 2, FIG. 14 is a cross-sectional view corresponding to FIG. 6A, FIG. 15A is a partially enlarged view of a region indicated by ‘B2’ in FIG. 14, FIG. 15B is a partially enlarged view of a region indicated by ‘C2’ in FIG. 14, and FIG. 16 is a cross-sectional view corresponding to FIG. 7.

Referring to FIGS. 13, 14, 15A, 15B and 16, the first conductive patterns 36 (see FIGS. 6A, 6B and 6C) may be replaced with second conductive patterns 136 disposed on a level lower than that of the gate electrodes 27 and higher than that of the bit lines 90, the first insulating capping patterns 39 may be replaced with second insulating capping patterns 139 disposed below the second conductive patterns 136, and the first buffer dielectric layers 33 may be replaced with second buffer dielectric layers 133 covering upper surfaces of the second conductive patterns 136, side surfaces of the second conductive patterns 136, and side surfaces of the second insulating capping patterns 139. The second conductive patterns 136 may be spaced apart from the gate electrodes 27 by the second buffer dielectric layers 133.

A width of each of the second conductive patterns 136 in the second horizontal direction may be greater than a width of each of the gate electrodes 27 in the second horizontal direction.

With reference to FIGS. 6A, 6B, 6C and 7, the insulating layer 30 may replace the first conductive patterns 36, the first insulating capping patterns 39, and the first buffer dielectric layers 33, and the gate capping patterns 87b disposed on the gate electrodes 27 may replace the gate capping patterns 88b.

The second back gate capping patterns 88a may be replaced with second back gate capping patterns 87a disposed on the back gate electrodes 18, and the first back gate capping patterns 21 may be disposed below the back gate electrodes 18.

The first conductive contact plugs 54 may be replaced with first conductive contact plugs 154 extending upwardly by penetrating through the first lower insulating layer 97 and connected to lower surfaces of the second conductive patterns 136.

The contact plugs 71 may be replaced with a lower interconnection 179 connected to the first conductive contact plugs 154. The first conductive contact plugs 154 may be connected to the first lower insulating layer 97.

At least a portion of the second conductive pattern 136 may be disposed between the first source/drain regions SD1 adjacent to each other in the second horizontal direction. The second conductive pattern 136 may be disposed between the first source/drain regions SD1 adjacent to each other in the second horizontal direction. The second conductive pattern 136 may be spaced apart from the bit line 90 by the second insulating capping pattern 139.

The second conductive pattern 136 may be spaced apart from the first and second gate electrodes WL_1 and WL_2 by the second buffer dielectric layer 133.

The first gate dielectric layer 24_1 and the second buffer dielectric layer 133 may be disposed between the first cell active pattern 9a_1 and the second conductive pattern 136, and the second gate dielectric layer 24_2 and the second buffer dielectric layer 133 may be disposed between the second cell active pattern 9a_2 and the second conductive pattern 136.

A width of the second conductive pattern 136 in the second horizontal direction may be greater than a width of each of the first and second gate electrodes WL_1 and WL_2 in the second horizontal direction.

The second conductive patterns 136 may reduce the parasitic capacitance that may occur between the first source/drain regions SD1 adjacent to each other in the second horizontal direction, thereby improving the performance of the cell transistors cTR.

The second conductive patterns 136 may be second shield conductive patterns CG_BA that may reduce parasitic capacitance between the cell transistors cTR.

During operation of the memory cells MC activated to perform operations such as reading or writing data, a shield voltage may be applied to the second conductive patterns 136 by the control circuit of the control circuit region GCR, the second conductive patterns 136 to which the shield voltage is applied may suppress or reduce the parasitic capacitance between the first source/drain regions SD1 of the cell transistors cTR adjacent to each other in the second horizontal direction. The shield voltage applied to the second conductive patterns 136 may be a ground voltage. The ground voltage applied to the second conductive patterns 136 may be 0V.

When the memory cells MC are activated, an a shield voltage may be applied to the second conductive patterns 136 by the control circuit of the control circuit region GCR, thereby suppressing or reducing the parasitic capacitance between the first source/drain regions SD1 of the cell transistors cTR adjacent to each other in the second horizontal direction. Accordingly, the second conductive patterns 136 may improve the performance of the semiconductor device 1.

According to an example embodiment, while the memory cells MC are activated to perform operations such as reading or writing data, the shield voltage may be applied to the second conductive patterns 136 by the control circuit of the control circuit region GCR, thereby suppressing or reducing the parasitic capacitance between the first source/drain regions SD1 of the cell transistors cTR adjacent to each other in the second horizontal direction.

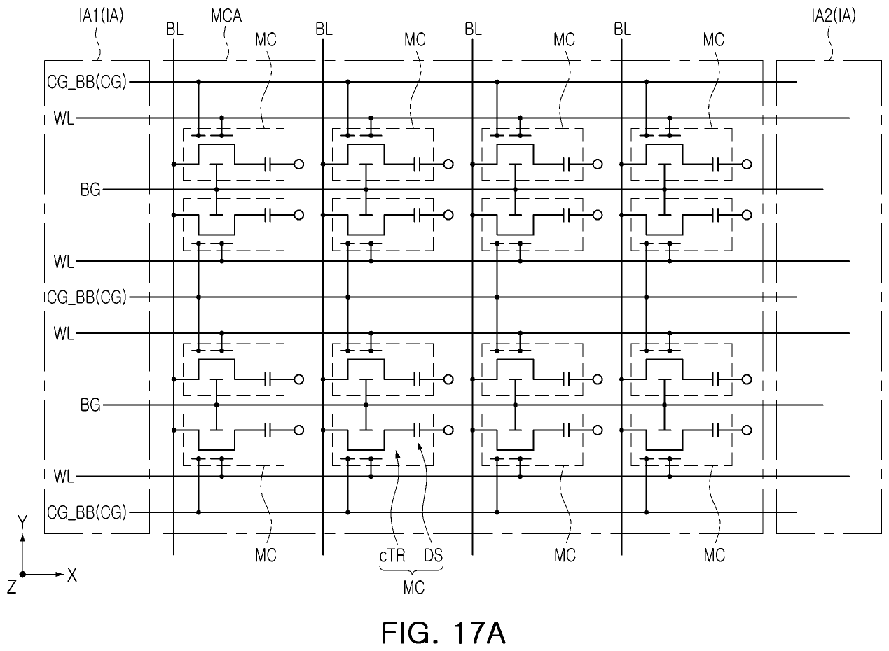

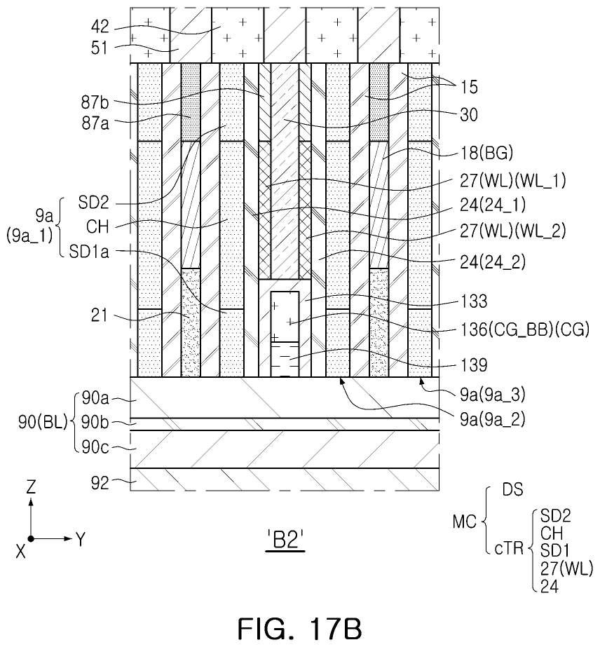

With reference to FIGS. 17A and 17B, an example embodiment of the semiconductor device 1 and the operating method of the semiconductor device 1 will be described. FIG. 17A is a circuit diagram corresponding to the circuit diagram of FIG. 13, and FIG. 17B is a partially enlarged view corresponding to FIG. 15A.

According to an example embodiment, referring to FIGS. 17A and 17B, the first source/drain region SD1 shown in FIG. 15A may be replaced with a first source/drain region SD1a positioned vertically at a lower level than an upper surface of the second conductive pattern 136. At least a portion of a second conductive pattern 136 may be disposed at the same level as the channel region CH. The second conductive pattern 136 may include a portion disposed at the same level as the channel region CH and a portion disposed at the same level as an upper region of the first source/drain region SD1a. As a portion of the second conductive pattern 136 is disposed at the same level as the channel region CH and at the same level as an upper region of the first source/drain region SD1a, the distance between the bottom point of the first gate electrode WL_1 and the top point of the second source/drain region SD1a increases. Because of the increased distance, electric field formed between the first gate electrode WL_1 and the second source/drain region SD1a may be reduced, thereby reducing the GIDL.

The second conductive patterns 136 may reduce leakage current generated by the GIDL in the cell transistors cTR adjacent to the second conductive patterns 136, thereby improving the performance of the cell transistors cTR.

The second conductive patterns 136 may be second control gate electrodes CG_BB that may reduce leakage current generated in the cell transistors cTR by the GIDL.

When the memory cells MC are activated, a control voltage may be applied to the second conductive patterns 136 by the control circuit of the control circuit region GCR, and the second conductive patterns 136 to which the control voltage is applied may reduce the leakage current generated in the cell transistors cTR by the GIDL.

When the memory cells MC are activated, for reducing the leakage current generated in the cell transistors cTR by the GIDL, the control circuit of the control circuit region GCR may apply a control voltage to the second conductive pattern 136, in which the control voltage is lower than the voltage applied to the selected word lines WL among the word lines. The voltage applied to the selected word lines WL among the word lines may be a voltage for activating the memory cells MC. Accordingly, the second conductive patterns 136, which may be the second control gate electrodes CG_BB, may improve the performance of the semiconductor device 1.

According to an example embodiment, while the memory cells MC are activated to perform operations such as reading or writing data, a control voltage may be applied to the second conductive patterns 136 by the control circuit of the control circuit region GCR, thereby reducing the leakage current generated in the cell transistors cTR by the GIDL.

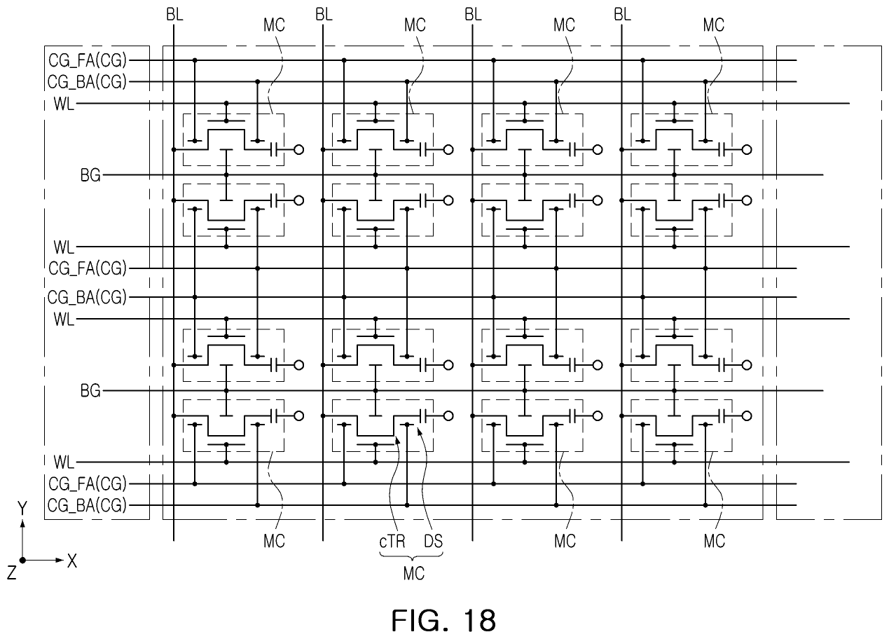

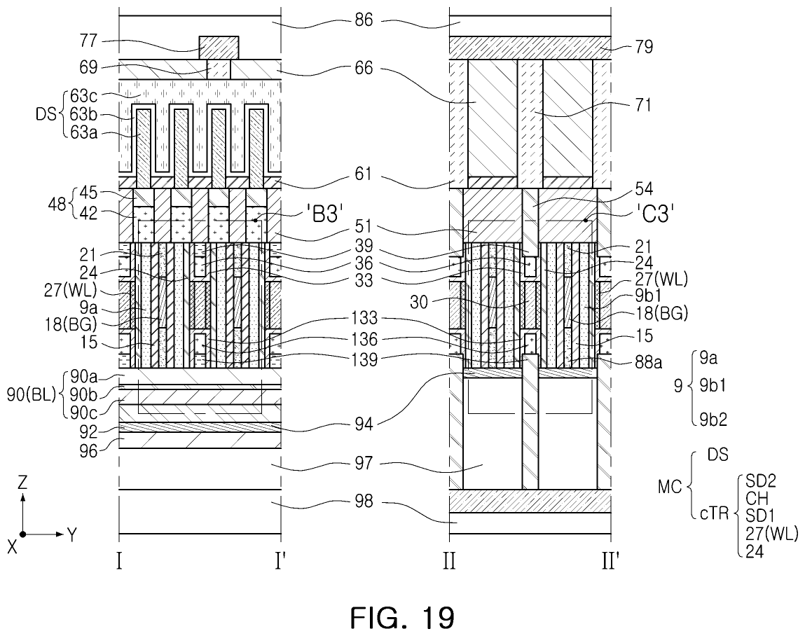

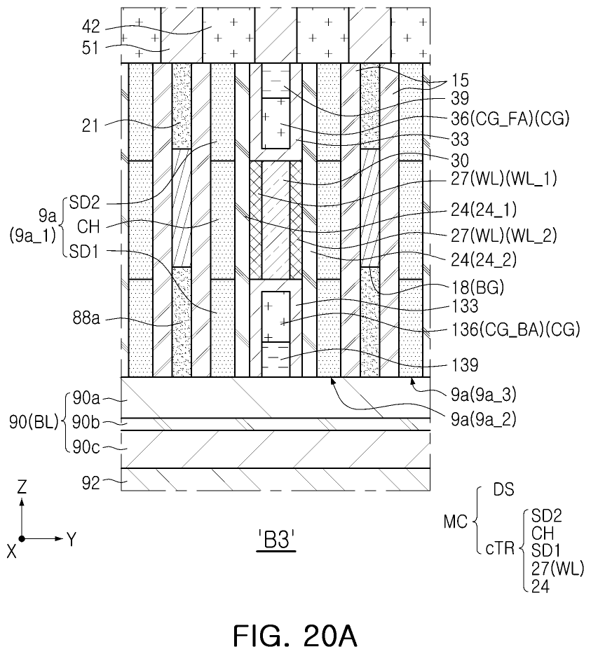

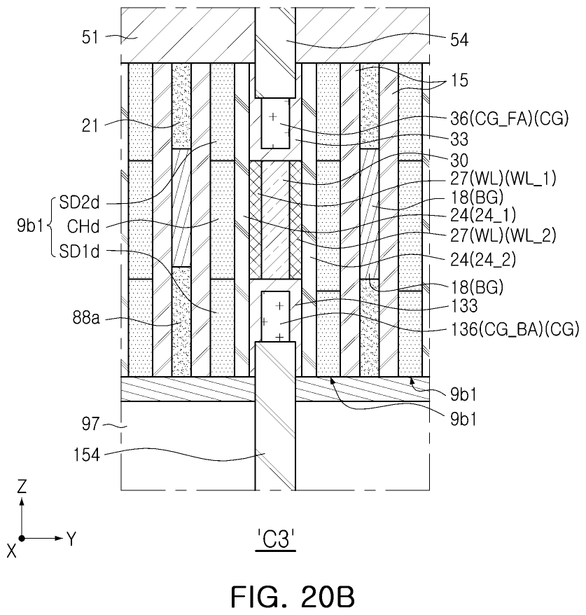

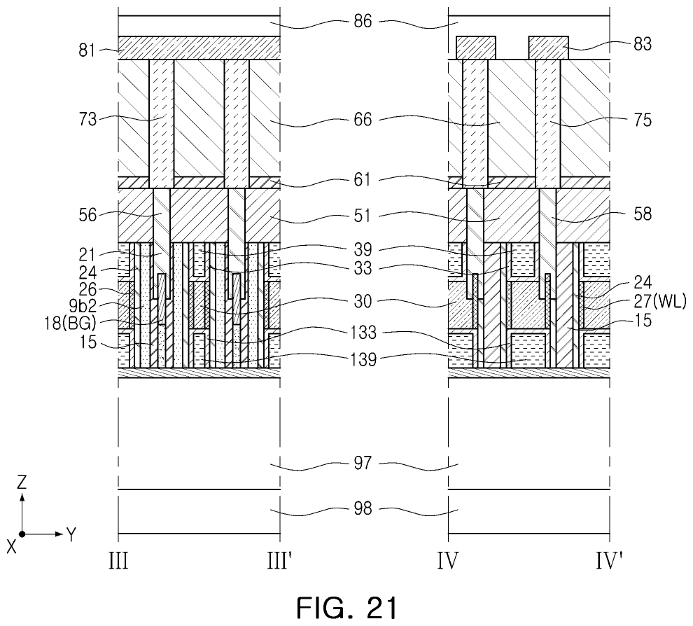

Referring to FIGS. 18, 19, 20A, 20B and 21, example embodiments of the semiconductor device 1 and the operating method of the semiconductor device 1 will be described. FIG. 18 is a circuit diagram corresponding to the circuit diagram of FIG. 2, FIG. 19 is a cross-sectional view corresponding to FIG. 6A, FIG. 20A is a partially enlarged view of a region indicated by ‘B3’ in FIG. 19, FIG. 20B is a partially enlarged view of a region indicated by ‘C3’ in FIG. 19, and FIG. 21 is a cross-sectional view corresponding to FIG. 7.

Referring to FIGS. 18, 19, 20A, 20B and 21, the semiconductor device 1 may include an electrical connection configuration including the second conductive patterns 136, the second buffer dielectric layers 133 and the second insulating capping patterns 139 described in FIGS. 14, 15A, 15B and 16, along with an electrical connection configuration including the first conductive patterns 36, the first buffer dielectric layers 33, and the first insulating capping patterns 39 described in FIGS. 6A, 6B, 6C and 7.

According to an example embodiment, the first conductive patterns 36 may reduce the parasitic capacitance between the second source/drain regions SD2 adjacent to each other in the second horizontal direction as described with reference to FIGS. 6A, 6B, 6C and 7, and the second conductive patterns 136 may reduce the parasitic capacitance between the second source/drain regions SD1 adjacent to each other in the second horizontal direction as described with reference to FIGS. 15A, 15B and 16.

The semiconductor device 1 may include the first conductive patterns 36, which may be the first shield conductive patterns CG_FA that may reduce the parasitic capacitance between the second source/drain regions SD2 of the cell transistors cTR, among the conductive patterns CG, and second conductive patterns 136, which may be the second shield conductive patterns CG_BA that may reduce the parasitic capacitance between the first source/drain regions SD1 of the cell transistors cTR.

When the memory cells MC are activated to perform operations such as reading or writing data, a shield voltage may be applied to the first conductive patterns 36 and the second conductive patterns 136 by the control circuit of the control circuit region GCR, thereby suppressing or reducing the parasitic capacitance between the first source/drain regions SD1 of the cell transistors cTR adjacent to each other in the second horizontal direction, and suppressing or reducing the parasitic capacitance between the second source/drain regions SD2 of the cell transistors cTR adjacent to each other in the second horizontal direction.

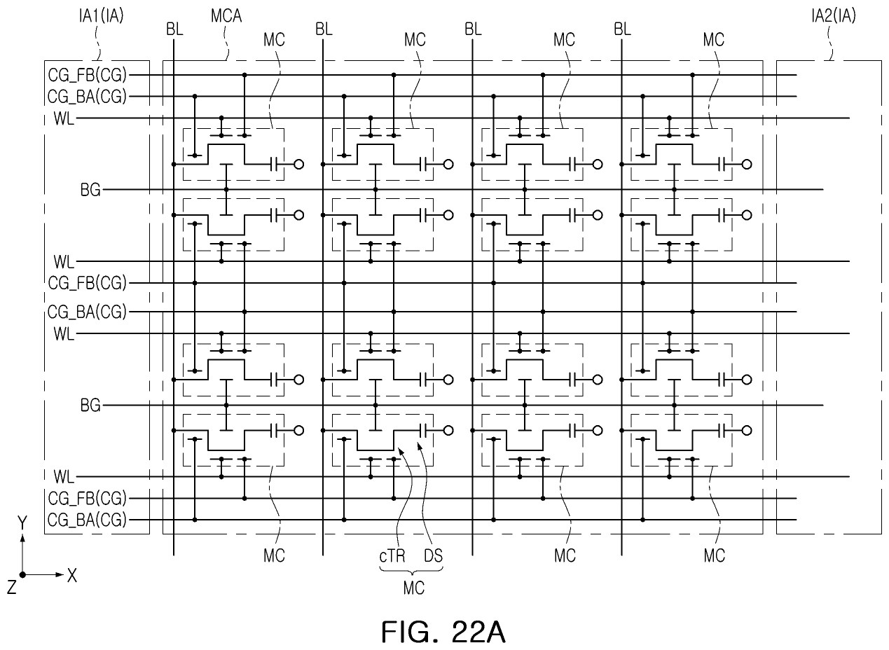

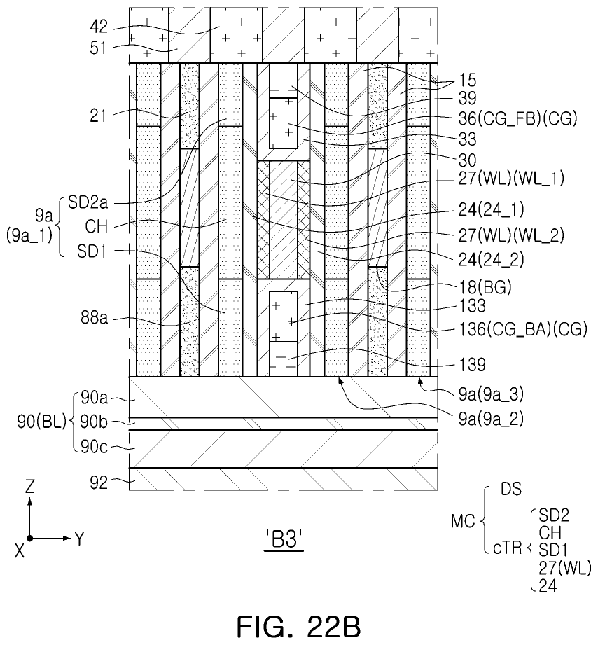

Referring to FIGS. 22A and 22B, an example embodiment of the semiconductor device 1 and the operating method of the semiconductor device 1 will be described. FIG. 22A is a circuit diagram corresponding to the circuit diagram of FIG. 18, and FIG. 22B is a cross-sectional view corresponding to FIG. 22A.

Referring to FIG. 22A and FIG. 22B, the second source/drain regions SD2 described with reference to FIGS. 19, 20A, 20B and 21 may be replaced with the second source/drain regions SD2a described with reference to FIG. 8B. Accordingly, the first conductive patterns 36 may reduce the leakage current generated by the GIDL in the cell transistors cTR adjacent to the first conductive patterns 36, thereby improving the performance of the cell transistors cTR.

According to an example embodiment, When the memory cells MC are activated to perform operations such as reading or writing data, the control circuit of the control circuit region GCR may apply the control voltage to the first conductive patterns 36 to reduce the leakage current generated in the cell transistors cTR by the GIDL, and the shield voltage may be applied to the second conductive patterns 136 by the control circuit of the control circuit region GCR, thereby suppressing or reducing the parasitic capacitance between the first source/drain regions SD1 of the cell transistors cTR adjacent to each other in the second horizontal direction.

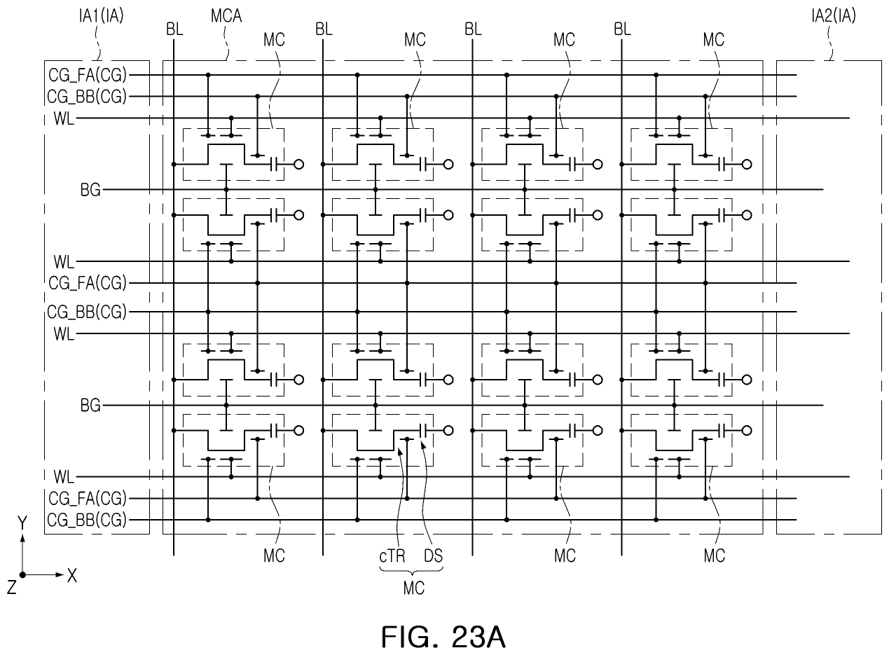

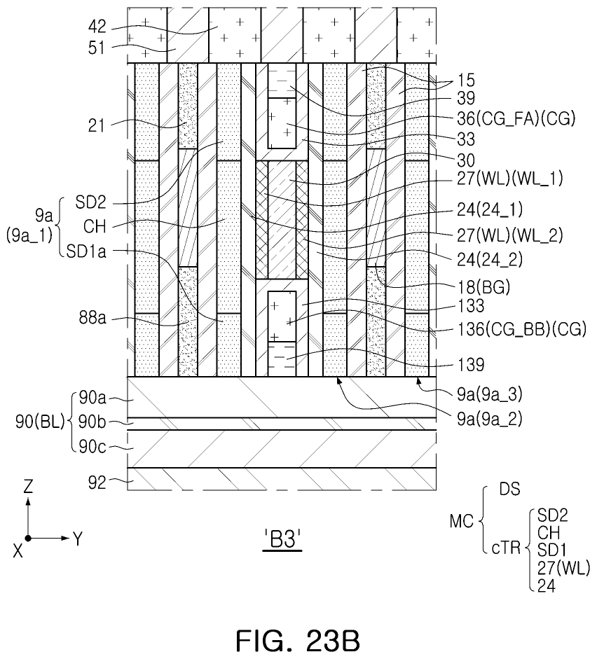

With reference to FIGS. 23A and 23B, an example embodiment of the semiconductor device 1 and the operating method of the semiconductor device 1 will be described. FIG. 23A is a circuit diagram corresponding to the circuit diagram of FIG. 18, and FIG. 23B is a cross-sectional view corresponding to FIG. 23A.

Referring to FIGS. 23A and 23B, the first source/drain regions SD1 described with reference to FIGS. 19, 20A, 20B and 21 may be replaced with the first source/drain regions SD1a (see FIG. 17B) described with reference to FIG. 17B. Accordingly, the second conductive patterns 136 may reduce the leakage current generated by the GIDL in the cell transistors cTR adjacent to the second conductive patterns 136, thereby improving the performance of the cell transistors cTR.

According to an example embodiment, while the memory cells MC are activated to perform operations such as reading or writing data, the control voltage may be applied to the second conductive patterns 136 by the control circuit of the control circuit region GCR to reduce the leakage current generated in the cell transistors cTR by the GIDL, and the shield voltage may be applied to the first conductive patterns 36 by the control circuit of the control circuit region GCR, thereby suppressing or reducing the parasitic capacitance between the second source/drain regions SD2 of the cell transistors cTR adjacent to each other in the second horizontal direction.

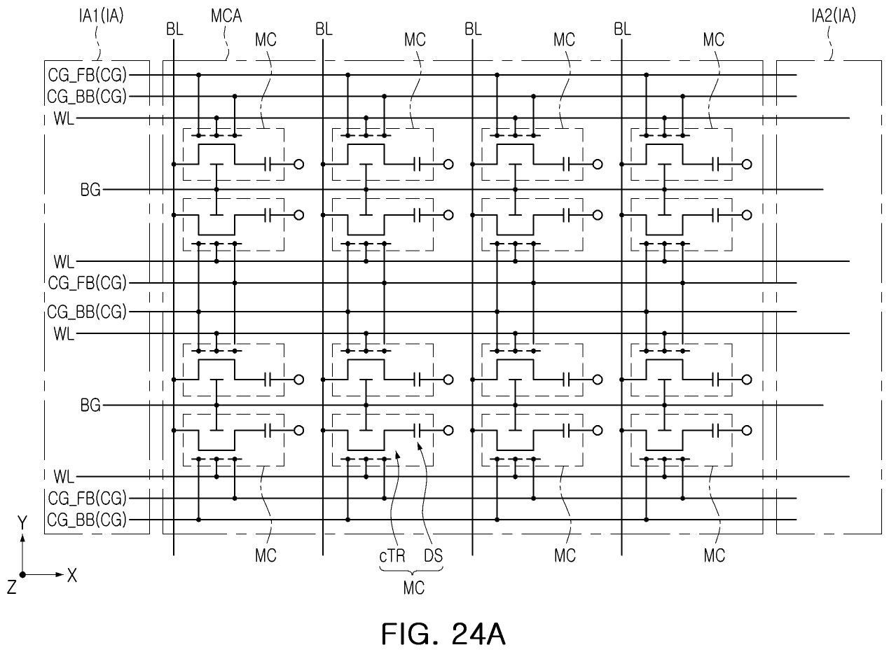

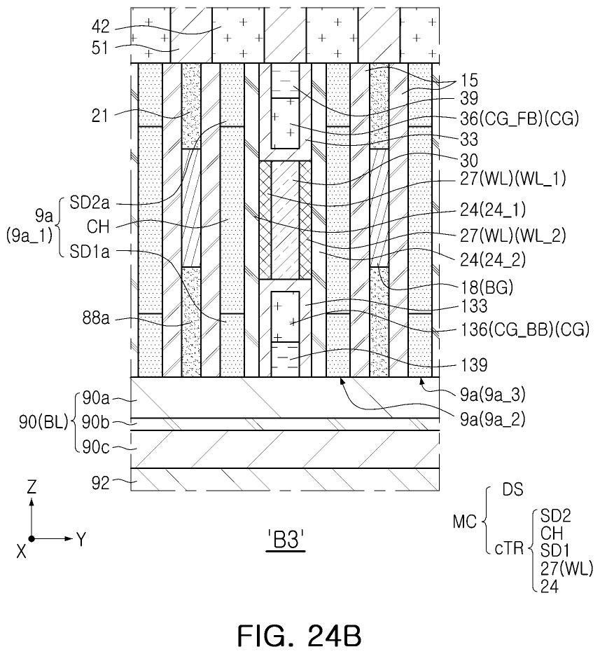

Referring to FIGS. 24A and 24B, an example embodiment of the semiconductor device 1 and the operating method of the semiconductor device 1 will be described. FIG. 24A is a circuit diagram corresponding to the circuit diagram of FIG. 18, and FIG. 24B is a cross-sectional view corresponding to FIG. 20A.

According to an example embodiment, referring to FIGS. 24A and 24B, the second source/drain regions SD2 described with reference to FIGS. 19, 20A, 20B and 21 may be replaced with the second source/drain regions SD2a (see FIG. 8B) described with reference to FIG. 8B. Accordingly, the first conductive patterns 36 may reduce the leakage current generated by the GIDL in the cell transistors cTR adjacent to the first conductive patterns 36, thereby improving the performance of the cell transistors cTR.

The first source/drain regions SD1 described with reference to FIGS. 19, 20A, 20B and 21 may be replaced with the first source/drain regions SD1a (see FIG. 17B) described in FIG. 17B. Accordingly, the second conductive patterns 136 may reduce the leakage current caused by the GIDL in the cell transistors cTR adjacent to the second conductive patterns 136, thereby improving the performance of the cell transistors cTR. Accordingly, the second conductive patterns 136 may reduce the leakage current generated by the GIDL in the cell transistors cTR adjacent to the second conductive patterns 136, thereby improving the performance of the cell transistors cTR.

According to an example embodiment, while the memory cells MC are activated to perform operations such as reading or writing data, the control voltage may be applied to the first conductive patterns 36 by the control circuit of the control circuit region GCR to reduce the leakage current generated in the cell transistors cTR by the GIDL, and the control voltage may be applied to the second conductive patterns 136 by the control circuit of the control circuit region GCR, thereby reducing the leakage current generated in the cell transistors cTR by the GIDL.

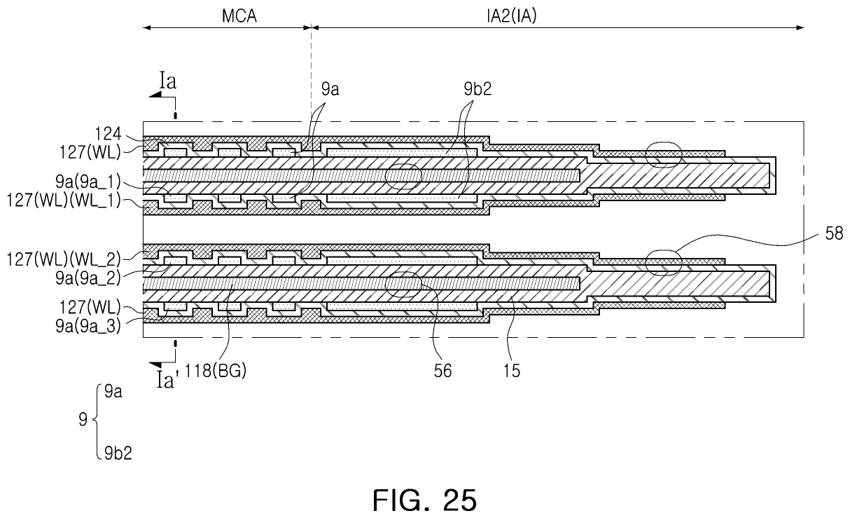

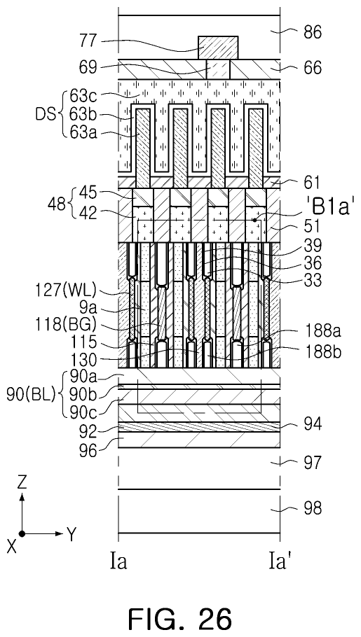

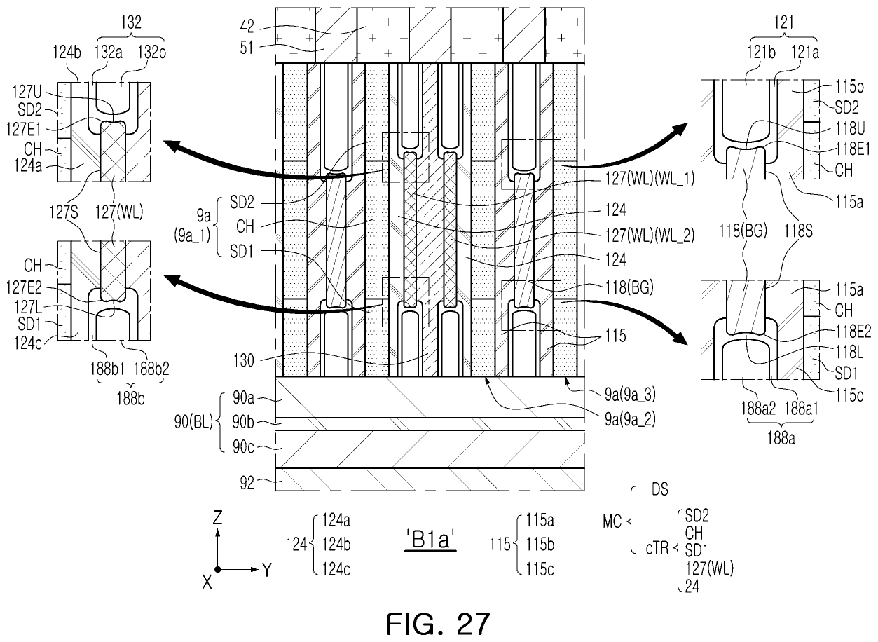

Referring to FIGS. 25, 26 and 27, an example embodiment of the semiconductor device 1 (see FIGS. 1A and 1B) will be described. FIG. 25 is a partially enlarged plan view. The first conductive patterns 36 of FIGS. 5B and 12B, which are shown in the partially enlarged plan view of FIG. 5B or a partially enlarged plan view of FIG. 12B, are omitted. FIG. 26 is a cross-sectional view illustrating a region taken along line Ia-Ia′ of FIG. 25, and FIG. 27 is a partially enlarged view illustrating a region indicated by ‘B1a’ of FIG. 26.

According to an example embodiment, referring to FIGS. 25, 26 and 27, the first conductive patterns 36 of FIGS. 5B and 12B, along with the first dummy active patterns 9b1 of FIGS. 5A and 5B, may be omitted, thereby reducing the total area of the interface regions IA.

The insulating layer 30 of FIG. 6B may be replaced with an insulating layer 130 having an upper surface extending upwardly and forming a coplanar surface with upper surfaces of the cell active patterns 9a. The insulating layer 130 may have a lower surface forming a coplanar surface with lower surfaces of the cell active patterns 9a.

Each of the gate electrodes 27 of FIGS. 5A to 24B, which may be the word lines WL, may be replaced with a gate electrode 127 having at least one rounded edge. For example, each of the gate electrodes 127 may include an upper surface 127U, a lower surface 127L, a first side surface 127S facing an adjacent cell active pattern 9a among the cell active patterns 9a, an upper edge 127E1 between the upper surface 127U and the first side surface 127S, and a lower edge 127E2 between the lower surface 127L and the first side surface 127S.

Hereinafter, a single cell active pattern 9a and a single gate electrode 127 adjacent to each other, among the cell active patterns 9a and the gate electrodes 127, will be described.

In the gate electrode 127, at least one of the upper edges 127E1 and the lower edge 127E2 may be a rounded edge. The upper edge 127E1 may be an upper rounded edge 127E1 that may be formed by extending to the first side surface 127S and the upper surface 127U, and the lower edge 127E2 may be a lower rounded edge 127E2 that may be formed by extending to the first side surface 127S and the lower surface 127L.

The upper surface 127U of the gate electrode 127 may have a concave shape at its center, oriented toward the center of the upper surface 127U of the gate electrode 127.

The lower surface 127L of the gate electrode 127 may have a concave shape at its center, oriented toward the center of the lower surface 127L of the gate electrode 127.

The upper rounded edge 127E1 of the gate electrode 127 may alleviate the electric field concentration between the second source/drain region SD2 of the cell active pattern 9a and the gate electrode 127 to reduce the leakage current of the cell transistor cTR due to the GIDL, thereby improving the performance of the cell transistor cTR.

The lower rounded edge 127E2 of the gate electrode 127 may alleviate the electric field concentration between the first source/drain region SD1 of the cell active pattern 9a and the gate electrode 127 to reduce the leakage current of the cell transistor cTR due to GIDL, thereby improving the performance of the cell transistor cTR.

A first upper buffer dielectric pattern 132 may be disposed on the gate electrode 127. The first upper buffer dielectric pattern 132 may cover an upper surface 127U and an upper rounded edge 127E1 of the gate electrode 127. An upper surface of the first upper buffer dielectric pattern 132 may be coplanar with an upper surface of the cell active pattern 9a. The first upper buffer dielectric pattern 132 may include a first upper buffer dielectric layer 132a and a second upper buffer dielectric layer 132b. The first upper buffer dielectric layer 132a may cover a lower surface and a side surface of the second upper buffer dielectric layer 132b. The first upper buffer dielectric layer 132a may cover the upper surface 127U of the gate electrode 127 and may extend between the gate electrode 127 and the cell active pattern 9a. The first upper buffer dielectric layer 132a may cover a portion of the first side surface 127S of the gate electrode 127, the upper surface 127U, and the upper rounded edge 127E1. The first upper buffer dielectric layer 132a may extend upwardly from a space between the gate electrode 127 and the cell active pattern 9a, thus covering the side surface of the second upper buffer dielectric layer 132b.

A first lower buffer dielectric pattern 188b may be disposed below the gate electrode 127. The first lower buffer dielectric pattern 188b may cover the lower surface 127L and the lower rounded edge 127E2 of the gate electrode 127. A lower surface of the first lower buffer dielectric pattern 188b may be coplanar with a lower surface of the cell active pattern 9a. The first lower buffer dielectric pattern 188b may include a first lower buffer dielectric layer 188b1 and a second lower buffer dielectric layer 188b2. The first lower buffer dielectric layer 188b1 may cover an upper surface and a side surface of the second lower buffer dielectric layer 188b2. The first lower buffer dielectric layer 188b1 may cover the lower surface 127L of the gate electrode 127 and may extend between the gate electrode 127 and the cell active pattern 9a. The first lower buffer dielectric layer 188b1 may cover a portion of the first side surface 127S of the gate electrode 127, the lower surface 127L, and the lower rounded edge 127E2. The first lower buffer dielectric layer 188b1 may extend downwardly from a space between the gate electrode 127 and the cell active pattern 9a, thus covering a side surface of the second lower buffer dielectric layer 188b2.

The cell gate dielectric layer 24 described above may be replaced with a cell gate dielectric layer 124 including a portion of dielectric layer having different thicknesses.

The cell gate dielectric layer 124 may include a first dielectric layer portion 124a having a first thickness and a second dielectric layer portion 124b extending from the first dielectric layer portion 124a and having a second thickness, smaller than the first thickness. The first dielectric layer portion 124a may be disposed between the cell active pattern 9a and the gate electrode 127. The second dielectric layer portion 124b may extend upwardly from the first dielectric layer portion 124a and may be disposed between the first upper buffer dielectric layer 132a and the cell active pattern 9a.

The cell gate dielectric layer 124 may further include a third dielectric layer portion 124c extending downwardly from the first dielectric layer portion 124a and having a third thickness smaller than the first thickness. The third dielectric layer portion 124c may extend downwardly from the first dielectric layer portion 124a and may be disposed between the first lower buffer dielectric layer 188b1 and the cell active pattern 9a.

The first upper buffer dielectric layer 132a may include a material having a higher dielectric constant than a material of the cell gate dielectric layer 124. For example, the cell gate dielectric layer 124 may include at least one of silicon oxide, silicon oxide doped with impurities or metal oxide, and the first upper buffer dielectric layer 132a may include a high-κ dielectric (e.g., HfO, ZrO, HfAlO, AlO, TiO, or LaO) having a higher dielectric constant than a material of the cell gate dielectric layer 124.

Since the dielectric constant of the first upper buffer dielectric layer 132a is higher than a dielectric constant of the cell gate dielectric layer 124, an equivalent oxide thickness (EOT) between the upper rounded edge 127E1 of the gate electrode 127 and the cell active pattern 9a may increase. For example, in the cell transistor cTR, the cell gate dielectric layer 124 may be disposed between the channel region CH and the gate electrode 127, and the second dielectric layer portion 124b of the cell gate dielectric layer 124 and the first upper buffer dielectric layer 132a may be disposed between the second source/drain region SD2 and the gate electrode 127, so that an equivalent oxide thickness between the second source/drain region SD2 and the gate electrode 127 may be greater than an equivalent oxide thickness between the channel region CH and the gate electrode 127. Accordingly, since the equivalent oxide thickness between the second source/drain region SD2 and the gate electrode 127 is greater than an equivalent oxide thickness between the channel region CH and the gate electrode 127, electric field formed between the second source/drain region SD2 and the gate electrode 127 may be reduced, thereby reducing the leakage current of the cell transistor cTR due to the GIDL. Because the thickness of the cell gate dielectric layer 124 facing the channel region CH is not changed, the performance of the cell transistor cTR such as current-voltage characteristics, may be maintained.

The second upper buffer dielectric layer 132b may include a dielectric layer having a lower dielectric constant than the first upper buffer dielectric layer 132a. For example, the first upper buffer dielectric layer 132a may include a high-κ dielectric, and the second upper buffer dielectric layer 132b may include at least one of silicon oxide and a low-κ dielectric. The second upper buffer dielectric layer 132b may reduce the parasitic capacitance between the second source/drain regions SD2 adjacent to each other in the second horizontal direction.

The low-κ dielectric may be a dielectric having a lower dielectric constant than that of silicon oxide, and the high-κ dielectric may be a dielectric having a higher dielectric constant than that of silicon oxide.

The first lower buffer dielectric layer 188b1 may include a material having a higher dielectric constant than that of the cell gate dielectric layer 124. For example, the first lower buffer dielectric layer 188b1 may include a high-κ dielectric (e.g., HfO, ZrO, HfAlO, AlO, TiO, or LaO) having a higher dielectric constant than the material of the cell gate dielectric layer 124.

Because the third dielectric layer portion 124c of the cell gate dielectric layer 124 and the first lower buffer dielectric layer 188b1 are disposed between the first source/drain region SD1 and the gate electrode 127, the equivalent oxide thickness between the first source/drain region SD1 and the gate electrode 127 may be greater than the equivalent oxide thickness between the channel region CH and the gate electrode 127. Accordingly, due to the first lower buffer dielectric layer 188b1, the equivalent oxide thickness between the first source/drain region SD1 and the gate electrode 127 may be greater than the equivalent oxide thickness between the channel region CH and the gate electrode 127, and electric field formed between the first source/drain region SD1 and the gate electrode 127 may be reduced, thereby reducing leakage current of the cell transistor cTR due to GIDL. Because the thickness of the cell gate dielectric layer 124 facing the channel region CH is not changed, the performance of the cell transistor cTR such as current-voltage characteristics, may be maintained.

According to an example embodiment, the second lower buffer dielectric layer 188b2 may include a dielectric having a lower dielectric constant than that of the first lower buffer dielectric layer 188b1. For example, the first lower buffer dielectric layer 188b1 may include a high-κ dielectric, and the second lower buffer dielectric layer 188b2 may include at least one of silicon oxide and a low-κ dielectric. The second lower buffer dielectric layer 188b2 may reduce parasitic capacitance between the first source/drain regions SD1 adjacent to each other in the second horizontal direction (Y-direction).

Each of the back gate electrodes 18 described with reference to FIGS. 5A to 24B may be replaced with a back gate electrode 118 having at least one rounded edge. For example, each of the back gate electrodes 118 may include an upper surface 118U, a lower surface 118L, a first side surface 118S facing an adjacent cell active pattern 9a among the cell active patterns 9a, an upper edge 118E1 between the upper surface 118U and the first side surface 118S, and a lower edge 118E2 between the lower surface 118L and the first side surface 118S.

Hereinafter, a single cell active pattern 9a and a single back gate electrode 118 that are adjacent to each other, among the cell active patterns 9a and the back gate electrodes 118, will be described.

In the back gate electrode 118, at least one of the upper edges 118E1 and the lower edge 118E2 may be a rounded edge. The upper edge 118E1 may be an upper rounded edge 118E1 that may be formed by extending to the first side surface 118S and the upper surface 118U, and the lower edge 118E2 may be a lower rounded edge 118E2 that may be formed by extending to the first side surface 118S and the lower surface 118L.

The upper surface 118U of the back gate electrode 118 may have a shape in which a center thereof is concave in a direction oriented toward a center of the back gate electrode 118.

The lower surface 118L of the back gate electrode 118 may have a shape in which a center thereof is concave in a direction oriented toward the center of the back gate electrode 118.

The upper rounded edge 118E1 and the lower rounded edge 118E2 of the back gate electrode 118 may alleviate the electric field concentration at an edge of the back gate electrode 118, thereby suppressing the leakage current of the cell transistor cTR adjacent to the back gate electrode 118. The back gate electrode 118 may prevent the performance degradation of the cell transistor cTR due to the floating body effect.

A second upper buffer dielectric pattern 121 may be disposed on the back gate electrode 118. The second upper buffer dielectric pattern 121 may cover the upper surface 118U and the upper rounded edge 118E1 of the back gate electrode 118. An upper surface of the second upper buffer dielectric pattern 121 may be coplanar with the upper surface of the cell active pattern 9a. The second upper buffer dielectric pattern 121 may include a third upper buffer dielectric layer 121a and a fourth upper buffer dielectric layer 121b. The third upper buffer dielectric layer 121a may cover a lower surface and a side surface of the fourth upper buffer dielectric layer 121b. The third upper buffer dielectric layer 121a may cover the upper surface 118U of the back gate electrode 118 and may extend between the back gate electrode 118 and the cell active pattern 9a. The third upper buffer dielectric layer 121a may cover a portion of the first side surface 118S of the back gate electrode 118, the upper surface 118U, and the upper rounded edge 118E1. The third upper buffer dielectric layer 121a may extend upwardly from a space between the back gate electrode 118 and the cell active pattern 9a, thus covering the side surface of the second upper buffer dielectric layer 132a.

A second lower buffer dielectric pattern 188a may be disposed below the back gate electrode 118. The second lower buffer dielectric pattern 188a may cover the lower surface 118L and the lower rounded edge 118E2 of the back gate electrode 118. A lower surface of the second lower buffer dielectric pattern 188a may be coplanar with the lower surface of the cell active pattern 9a. The second lower buffer dielectric pattern 188a may include a third lower buffer dielectric layer 188a1 and a fourth lower buffer dielectric layer 188a2. The third lower buffer dielectric layer 188a1 may cover an upper surface and a side surface of the second lower buffer dielectric layer 188b2. The third lower buffer dielectric layer 188a1 may cover the lower surface 118L of the back gate electrode 118 and may extend between the back gate electrode 118 and the cell active pattern 9a. The third lower buffer dielectric layer 188a1 may cover a portion of the first side surface 118S of the back gate electrode 118, the lower surface 118L, and the lower rounded edge 118E2. The third lower buffer dielectric layer 188a1 may extend downwardly from a space between the back gate electrode 118 and the cell active pattern 9a, thus covering a side surface of the fourth lower buffer dielectric layer 188a2.

The back gate dielectric layer 15 described above may be replaced with a back gate dielectric layer 115 including dielectric layer portions having different thicknesses.

The back gate dielectric layer 115 may include a first dielectric layer portion 115a having a first thickness and a second dielectric layer portion 115b extending from the first dielectric layer portion 115a and having a second thickness, smaller than the first thickness. The first dielectric layer portion 115a may be disposed between the cell active pattern 9a and the back gate electrode 118. The second dielectric layer portion 115b may extend upwardly from the first dielectric layer portion 115a and may be disposed between the third upper buffer dielectric layer 121a and the cell active pattern 9a.

The back gate dielectric layer 115 may further include a third dielectric layer portion 115c extending downwardly from the first dielectric layer portion 115a and having a third thickness smaller than the first thickness. The third dielectric layer portion 115c may extend downwardly from the first dielectric layer portion 115a and may be disposed between the third lower buffer dielectric layer 188a1 and the cell active pattern 9a.

The third upper buffer dielectric layer 121a may include a material having a higher dielectric constant than a material of the back gate dielectric layer 115. For example, the back gate dielectric layer 115 may include at least one of silicon oxide, silicon oxide doped with impurities, and metal oxide, and the third upper buffer dielectric layer 121a may include a high-κ dielectric (e.g., HfO, ZrO, HfAlO, AlO, TiO, or LaO) having a higher dielectric constant than the material of the back gate dielectric layer 115. The fourth upper buffer dielectric layer 121b may include a dielectric material having a lower dielectric constant than the third upper buffer dielectric layer 121a. For example, the third upper buffer dielectric layer 121a may include a high-κ dielectric, and the fourth upper buffer dielectric layer 121b may include at least one of silicon oxide and a low-κ dielectric. The fourth upper buffer dielectric layer 121b may reduce the parasitic capacitance between the second source/drain regions SD2 adjacent to each other in the second horizontal direction.

According to an example embodiment, the third lower buffer dielectric layer 188a1 may include a material having a higher dielectric constant than the material of the back gate dielectric layer 115. For example, the third lower buffer dielectric layer 188a1 may include a high-κ dielectric (e.g., HfO, ZrO, HfAlO, AlO, TiO, or LaO) having a higher dielectric constant than the material of the back gate dielectric layer 115. The fourth lower buffer dielectric layer 188a2 may include a dielectric having a lower dielectric constant than the third lower buffer dielectric layer 188a1. For example, the third lower buffer dielectric layer 188a1 may include a high-κ dielectric, and the fourth lower buffer dielectric layer 188a2 may include at least one of silicon oxide or a low-κ dielectric. The fourth lower buffer dielectric layer 188a2 may reduce the parasitic capacitance between the first source/drain regions SD1 adjacent to each other in the second horizontal direction.

Since the third upper buffer dielectric layer 121a and the third lower buffer dielectric layer 188a1 increase the equivalent oxide thickness between the edges 118E1 and 118E2 of the back gate electrode 118 and the cell active pattern 9a, the third upper buffer dielectric layer 121 a and the third lower buffer dielectric layer 188a1 may reduce the leakage current of the cell transistor cTR generated by the back gate electrode 118.

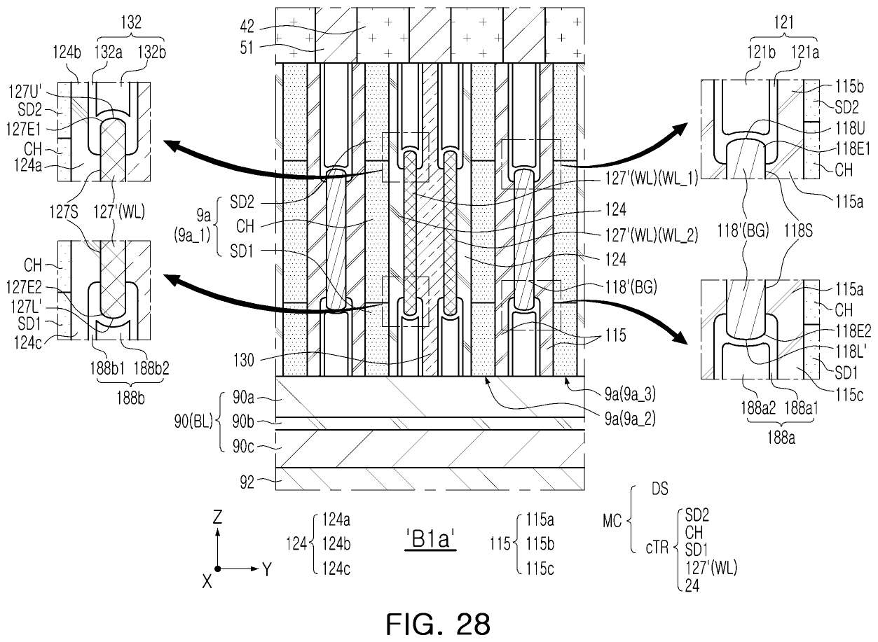

FIG. 28 is a partially enlarged cross-sectional view illustrating an example of a semiconductor device according to an example embodiment of the present disclosure, and may illustrate a modified element in the cross-sectional view of FIG. 27.

Referring to FIGS. 27 and 28, the gate electrode 127 having the concave downward upper surface 127U and the concave upward lower surface 127L may be replaced with a gate electrode 127′ having a convex upward upper surface 127U′ and a convex downward lower surface 127L′. The gate electrode 127′ may have the upper and lower rounded edges 127E1 and 127E2 as shown in FIG. 28.

The back gate electrode 118 having the concave downward upper surface 118U and the concave upward lower surface 118L may be replaced with a back gate electrode 118′ having a convex upward upper surface 118U′ and a convex downward lower surface 118L′. The back gate electrode 118′ may have the upper and lower rounded edges 118E1 and 118E 2 as shown in FIG. 28.

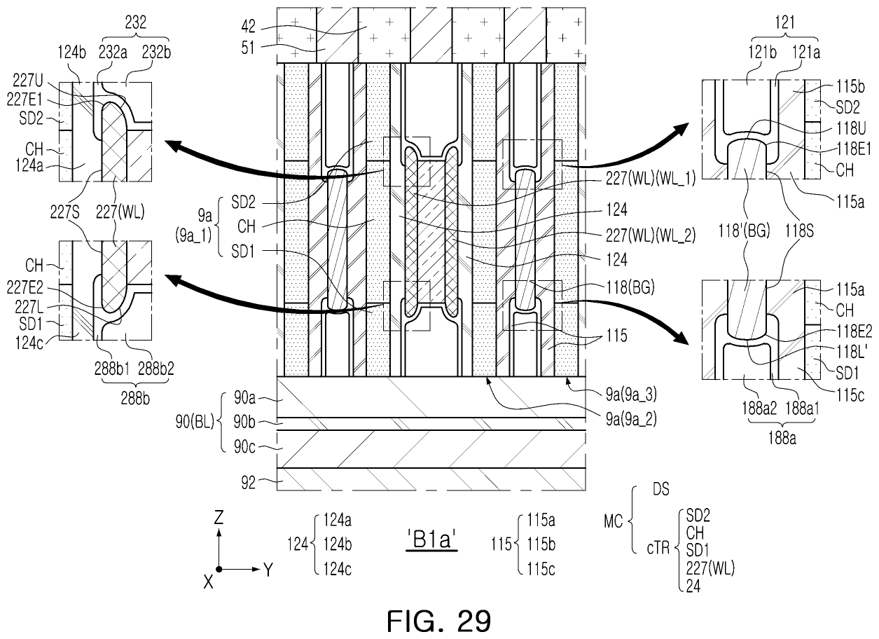

FIG. 29 is a partially enlarged cross-sectional view illustrating an example of a semiconductor device according to an example embodiment of the present disclosure, and may illustrate a modified element from the cross-sectional structure of FIG. 27 or the cross-sectional structure of FIG. 28.

Referring to FIGS. 27, 28 and 29, the gate electrode 127 or the gate electrode 127′ may be replaced with a gate electrode 227 as shown in FIG. 29, the insulating layer 130 may be replaced with an insulating layer 230, the first upper buffer dielectric pattern 132 may be replaced with a first upper buffer dielectric pattern 232, and the first lower buffer dielectric pattern 188b may be replaced with a first lower buffer dielectric pattern 288b as shown in FIG. 29. The cell gate dielectric layer 124 may be disposed between the cell active pattern 9a and the gate electrode 227, between the cell active pattern 9a and the first upper buffer dielectric pattern 232, and between the cell active pattern 9a and the first lower buffer dielectric pattern 288b, in a substantially identical shape. The cell gate dielectric layer 124 may include the first, second, and third dielectric layer portions 124a, 124b and 124c.

Each of the gate electrodes 227, which may be the word lines WL, may have at least one rounded edge. For example, each of the gate electrodes 227 may include an upper surface 227U, a lower surface 227L, a first side surface 227S facing an adjacent cell active pattern among the cell active patterns 9a, an upper edge 227E1 between the upper surface 227U and the first side surface 227S, and a lower edge 227E2 between the lower surface 227L and the first side surface 227S.

Hereinafter, a single cell active pattern 9a and a single gate electrode 227 among the cell active patterns 9a and the gate electrodes 227 that are adjacent to each other will be described.

In the gate electrode 227, at least one of the upper edges 227E1 or the lower edge 227E2 may be a rounded edge. The upper edge 227E1 may be an upper rounded edge 227E1 that may be formed to extend to the first side surface 227S and the upper surface 227U, and the lower edge 227E2 may be a lower rounded edge 227E2 that may be formed to extend to the first side surface 227S and the lower surface 227L.

The upper rounded edge 227E1 and the lower rounded edge 227E2 of the gate electrode 227 may improve the performance of the cell transistor cTR for the same reason as described in FIG. 27.

According to an example, the upper surface 227U of the first word line WL_1) may have a sloped shape that gradually descends in a direction toward the second word line WL_2). The first word line WL_1 and the second word line WL_2 may be the gate electrode 227.

The lower surface 227L of the first word line WL_1 may have a sloped shape that gradually ascends in a direction toward the second word line WL_2 adjacent to the first word line WL_1.

The insulating layer 230 may have an upper surface disposed at a lower level than the upper rounded edge 227E1 and a lower surface disposed at a higher level than the lower rounded edge 227E2.

The first upper buffer dielectric pattern 232 may cover upper surfaces 227U of the first word line WL_1, the second word line WL_2, and an upper surface of the insulating layer 230. The first upper buffer dielectric pattern 232 may have an upper surface that is coplanar with the upper surface of the cell active pattern 9a. The first word line WL_1 and the second word line WL_2 may be the gate electrode 227.

The first upper buffer dielectric pattern 232 may cover the upper rounded edges 227E1 of the first word line WL_1 and the second word line WL_2.

The first upper buffer dielectric pattern 232 may include a first upper buffer dielectric layer 232a and a second upper buffer dielectric layer 232b. The first upper buffer dielectric layer 232a may cover a lower surface and a side surface of the second upper buffer dielectric layer 232b. The first upper buffer dielectric layer 232a may extend between the first word line WL_1 and the first cell active pattern 9a_1, and may extend between the second word line WL_2 and the second cell active pattern 9a_2. The first word line WL_1 and the second word line WL_2 may be the gate electrode 227.

The first lower buffer dielectric pattern 288b may cover lower surfaces 227L of the first word line WL_1 and the second word line WL_2, and a lower surface of the insulating layer 230. The first lower buffer dielectric pattern 288b may have a lower surface that is coplanar with the lower surface of the cell active pattern 9a.

The first lower buffer dielectric pattern 288b may cover the lower rounded edges 227E2 of the first word line WL_1 and the second word line WL_2.

The first lower buffer dielectric pattern 288b may include a first lower buffer dielectric layer 288b1 and a second lower buffer dielectric layer 288b2. The first lower buffer dielectric layer 288b1 may cover an upper surface and a side surface of the second lower buffer dielectric layer 288b2. The first lower buffer dielectric layer 288b1 may extend between the first word line WL_1 and the first cell active pattern 9a_1, and may extend between the second word line WL_2 and the second cell active pattern 9a_2.

As described with reference to FIG. 27, since the first upper buffer dielectric layer 232a and the first lower buffer dielectric layer 288b1 may include a high-κ dielectric having a higher dielectric constant than the cell gate dielectric layer 124, the first upper buffer dielectric layer 232a and the first lower buffer dielectric layer 288b1 may reduce the leakage current of the cell transistor cTR due to the GIDL.

Likewise, since the second upper buffer dielectric layer 232b and the second lower buffer dielectric layer 288b2 may include a dielectric having a lower dielectric constant than the first upper buffer dielectric layer 232a and the first lower buffer dielectric layer 288b1, the second upper buffer dielectric layer 232b and the second lower buffer dielectric layer 288b2 may reduce the parasitic capacitance between the first source/drain regions SD1 adjacent to each other and the parasitic capacitance between the adjacent second source/drain regions SD2 adjacent to each other.

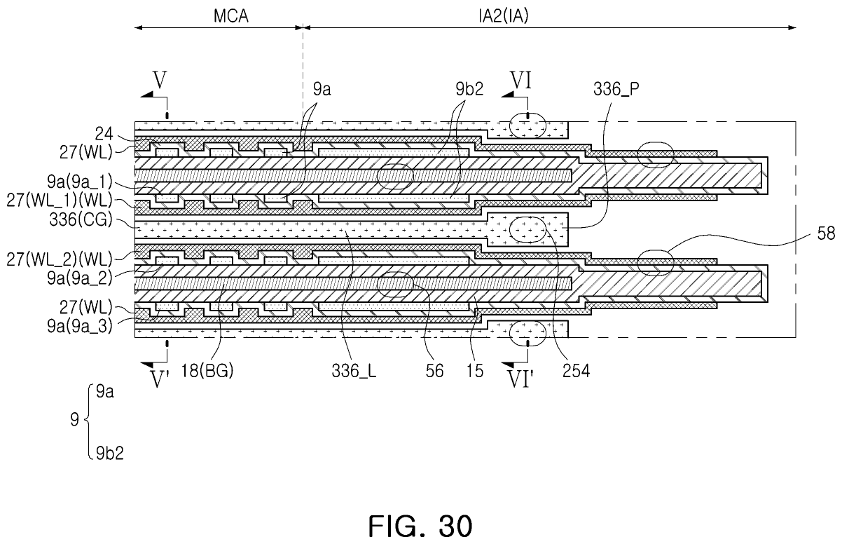

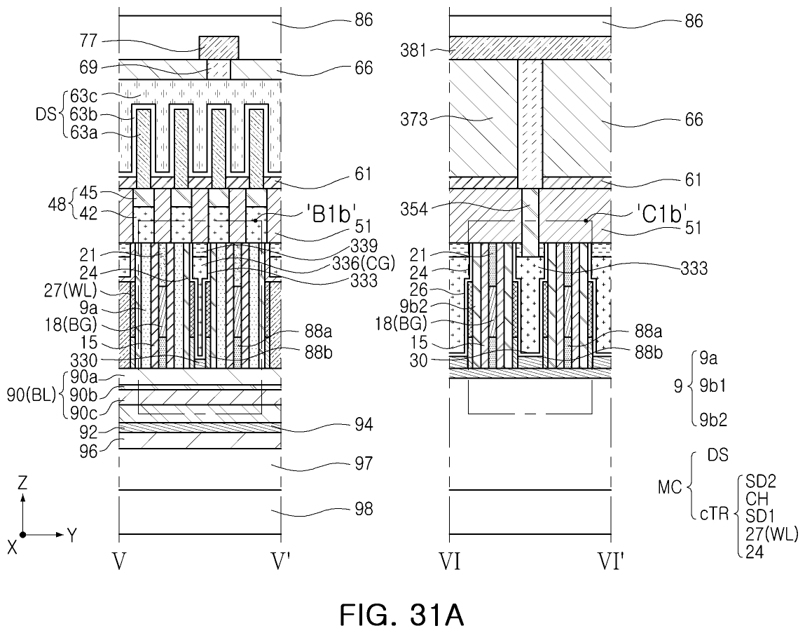

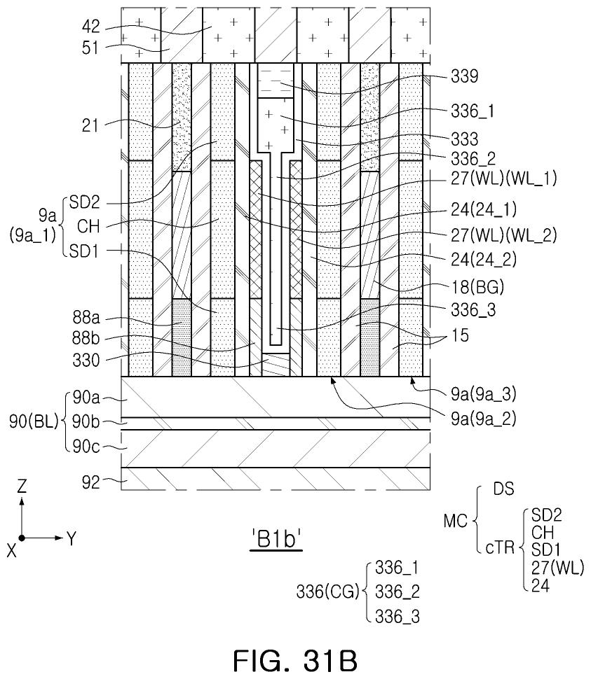

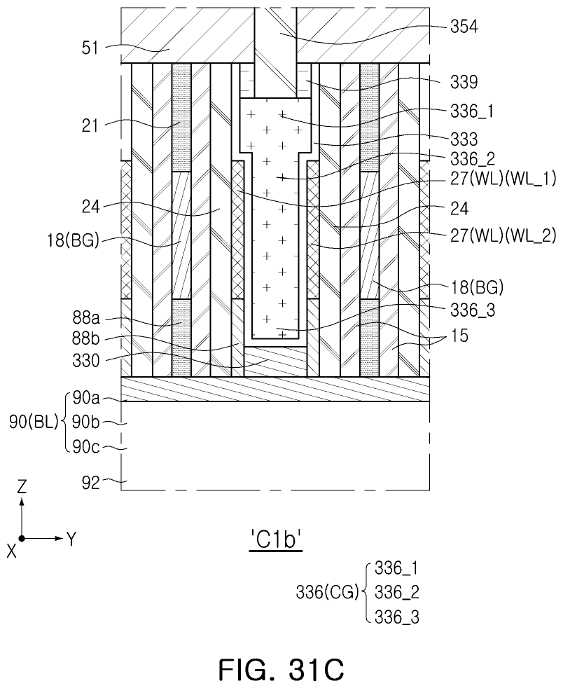

With reference to FIGS. 30, 31A, 31B and 31C, an example embodiment of the semiconductor device 1 (see FIGS. 1A and 1B) will be described. FIG. 30 is a partially enlarged plan view illustrating conductive patterns 336 that may replace the first conductive patterns 36 (see FIG. 5B and FIG. 12B), in a partially enlarged plan view of FIG. 5B or a partially enlarged plan view of FIG. 12B, FIG. 31A is a cross-sectional view illustrating areas taken along lines V-V′ and VI-VI′ of FIG. 30, FIG. 31B is a partially enlarged view illustrating a region indicated by ‘B1b’ of FIG. 31A, FIG. 31C is a partially enlarged view illustrating a region indicated by ‘C1b’ of FIG. 31A. Hereinafter, one conductive pattern 336 of the conductive patterns 336 will be described.

Referring to FIGS. 30, 31A, 31B and 31C, the first conductive pattern 36 (see FIGS. 5A, 5B, 5C, 6A, 6B, 6C, 8B, 12A, 12B and 12C) may be replaced with a first conductive pattern 336, in which a portion of the first conductive pattern 336 arranged between the first word line WL_1 and the second word line WL_2, and the other portion of the first conductive pattern 336 is disposed between the second source/drain regions SD2 at a higher level than the gate electrode 27.

The first conductive pattern 336 may extend between the first source/drain regions SD1 disposed at a lower level than the gate electrode 27 between the first word line WL_1 and the second word line WL_2. Accordingly, the first conductive pattern 336 may include an upper conductive portion 336_1 disposed between the second source/drain regions SD2 at a higher level than the gate electrode 27, an intermediate conductive portion 336_2 extending downwardly from the first conductive portion 336_1 and disposed between the first word line WL_1 and the second word line WL_2, and a lower conductive portion 336_3 that extending downwardly from the intermediate conductive portion 336_2 at a lower level than the gate electrode 27.

In the first conductive pattern 336, a width of the upper conductive portion 336_1 may be greater than widths of each of the intermediate and lower conductive portions 336_2 and 336_3.

The upper conductive portion 336_1 may play substantially the same role as the first conductive pattern 36 (see FIGS. 5A, 5B, 5C, 6A, 6B, 6C, 8B, 12A, 12B and 12C), the intermediate conductive portion 336_2 may play a role of reducing the parasitic capacitance between the adjacent word lines WL, and the lower conductive portion 336_3 may play a role of reducing the parasitic capacitance between the adjacent first source/drain regions SD1.

The first insulating capping pattern 39 (see FIGS. 5A, 5B, 5C, 6A, 6B, 6C and 8B) may be replaced with a first insulating capping pattern 339 disposed on an upper surface of the first conductive pattern 336, and the first buffer dielectric layer 333 (see FIGS. 5A, 5B, 5C, 6A, 6B, 6C and 8B) may be replaced with a first buffer dielectric layer 333 covering a side surface and a lower surface of the first conductive pattern 336 and covering a side surface of the first insulating capping pattern 339. The insulating layer 30 (see FIGS. 5A, 5B, 5C, 6A, 6B, 6C and 8B) may be replaced with an insulating layer 330 which is disposed below the first buffer dielectric layer 333.

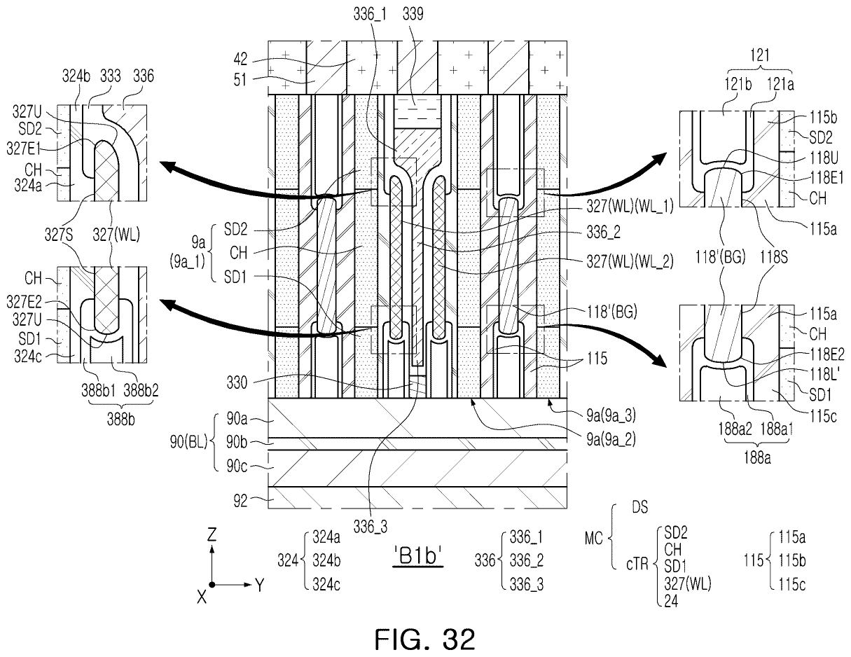

Referring to FIG. 32, an example embodiment of the semiconductor device 1 (see FIGS. 1A and 1B) will be described. FIG. 32 is a partially enlarged cross-sectional view illustrating an example of a semiconductor device according to an example embodiment of the present disclosure, and may illustrate a modified element from the cross-sectional structure of FIG. 31b.

According to an example embodiment, referring to FIG. 32, the gate electrode 27 in FIG. 31b adjacent to the first conductive pattern 336 in FIG. 31B may be replaced with a gate electrode 327 as in FIG. 32.

The gate electrode 327 may have an upper region having substantially the same shape as an upper region of the gate electrode 227 (see FIG. 29) described with reference to FIG. 29, and a lower region having substantially the same shape as a lower region of the gate electrode 127 (see FIG. 27) or the gate electrode 127′ (see FIG. 28) described with reference to FIG. 27 or FIG. 28. For example, the gate electrode 327 may have a first side surface 327S, an upper rounded edge 327E1 and an upper surface 327U corresponding to the first side surface 227S, the upper rounded edge 227E1 and the upper surface 227U of the gate electrode 227 (see FIG. 29) described in FIG. 29, respectively, and may have a lower rounded edge 327E2 and a lower surface 327L corresponding to the lower rounded edge 127E2 and the lower surface 127L of the gate electrode 127'(see FIG. 28) described in FIG. 28, respectively.

The cell gate dielectric layer 24 described above may be replaced with a cell gate dielectric layer 324 having substantially the same shape as the cell gate dielectric layer 124 (see FIGS. 27, 28 and 29) described in FIGS. 27, 28 and 29. For example, the cell gate dielectric layer 324 may include a first dielectric layer portion 324a, a second dielectric layer portion 324b and a third dielectric layer portion 324c corresponding to the first dielectric layer portion 124a (see FIGS. 27, 28 and 29), the second dielectric layer portion 124b (see FIGS. 27, 28 and 29), and the third dielectric layer portion 124c (see FIGS. 27, 28 and 29) respectively.

The first buffer dielectric layer 333 described above may extend between the cell active pattern 9 and the gate electrode 327 as in the first upper buffer dielectric layer 232a described with reference to FIG. 29, while covering a lower surface and a side surface of the first conductive pattern 336.

The first lower buffer dielectric pattern 188b (see FIG. 28) described above may be replaced with a first lower buffer dielectric pattern 388b covering the lower surface 327L and the lower rounded edge 327E2 of the gate electrode 327 and extending between the gate electrode 327 and the cell active pattern 9a, as described with reference to FIG. 28.

The first lower buffer dielectric pattern 388b may include a first lower buffer dielectric layer 388b1 and a second lower buffer dielectric layer 388b2, which correspond to the first lower buffer dielectric layer 188b1 (see FIG. 28) and the second lower buffer dielectric layer 188b2 (see FIG. 28) respectively, as described in FIG. 28.

Referring to FIGS. 33A, 33B and 33C, an example embodiment of the semiconductor device 1 (FIGS. 1A and 1B) will be described. In FIGS. 33A, 33B and 33C, FIG. 33A is a cross-sectional view illustrating regions taken along lines V-V′ and VI-VI′ of FIG. 30, FIG. 33B is a partially enlarged view illustrating a region indicated by ‘B2a’ of FIG. 33A, and FIG. 33C is a partially enlarged view illustrating a region indicated by ‘C2a’ of FIG. 33A. Hereinafter, a second conductive pattern among the second conductive patterns 436 will be described.

According to an example embodiment, referring to FIGS. 33A, 33B and 33C, the second conductive pattern 136 (see FIGS. 14, 15A, 15B and 17B) may be replaced with a second conductive pattern 436 extending from a portion disposed between the first source/drain regions SD1 at a lower level than the gate electrode 27 to a space between the first word line WL_1 and the second word line WL_2. The first word line WL_1 and the second word line WL_2 may be the gate electrode 227.

The second conductive pattern 436 may extend between the second source/drain regions SD2 disposed at a higher level than the gate electrode 27, between the first word line WL_1 and the second word line WL_2. Accordingly, the second conductive pattern 436 may include a lower conductive portion 436_1 disposed between the first source/drain regions SD1 at a lower level than the gate electrode 27, an intermediate conductive portion 436_2 extending upwardly from the first conductive portion 336_1 and disposed between the first word line WL_1 the second word line WL_2, and an upper conductive portion 436_3 extending upwardly from the intermediate conductive portion 436_2 at a higher level than the gate electrode 27.

In the second conductive pattern 436, a width of the lower conductive portion 436_1 may be greater than widths of each of the intermediate and upper conductive portions 336_2 and 336_3.

The lower conductive portion 436_1 may play substantially the same role as the second conductive pattern 136 (see FIGS. 14, 15A, 15B and 17B), the intermediate conductive portion 436_2 may play a role of reducing the parasitic capacitance between the word lines WL adjacent to each other, and the upper conductive portion 436_3 may play a role of reducing the parasitic capacitance between the second source/drain regions SD2 adjacent to each other.

The above-described second insulating capping pattern 139 (see FIGS. 14, 15A, 15B and 17B) may be replaced with a second insulating capping pattern 439 which is disposed below a lower surface of the second conductive pattern 436, and the second buffer dielectric layer 133 (see FIGS. 14, 15A, 15B and 17B) may be replaced with a first buffer dielectric layer 433 covering a side surface and an upper surface of the second conductive pattern 436 and covering a side surface of the second insulating capping pattern 439. The insulating layer 30 (see FIGS. 14, 15A, 15B and 17B) may be replaced with an insulating layer 430 which disposed on the first buffer dielectric layer 433.

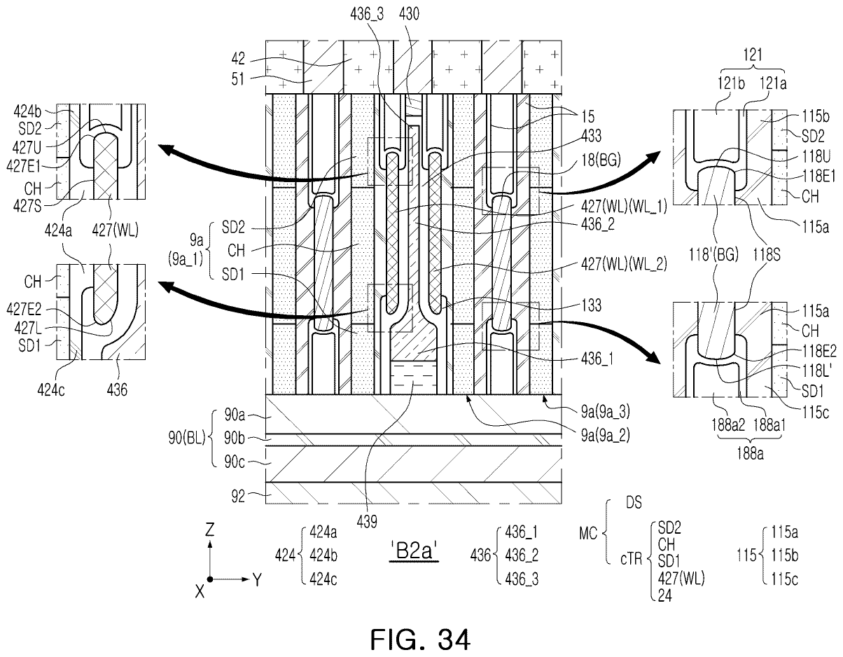

Referring to FIG. 34, an example embodiment of the semiconductor device 1 (see FIGS. 1A and 1B) will be described. FIG. 34 is a partially enlarged cross-sectional view illustrating an example of a semiconductor device according to an example embodiment of the present disclosure, and may illustrate a modified element from the cross-sectional structure of FIG. 33B.

In an example embodiment, referring to FIG. 34, the gate electrode 27 in FIG. 33B adjacent to the second conductive pattern 436 in FIG. 33B may be replaced with a gate electrode 427 as shown in FIG. 34.

The gate electrode 427 may have a lower region having a shape substantially the same as a lower region of the gate electrode 227 described with reference to FIG. 29, and an upper region having a shape substantially the same as an upper region of the gate electrode 127 or the gate electrode 127′ described with reference to FIG. 27 and FIG. 28. For example, the gate electrode 427 may have a first side surface 427S, a lower rounded edge 427E1 and a lower surface 427L corresponding to the first side surface 227S, the lower rounded edge 227E2 and the lower surface 227L of the gate electrode 227 described with reference to FIG. 29, respectively, and may have an upper rounded edge 427E1 and an upper surface 427U corresponding to the upper rounded edge 127E1 and the upper surface 127U of the gate electrode 127′ described with reference to FIG. 28, respectively.

The cell gate dielectric layer 24 may have a cell gate dielectric layer 24 corresponding to the cell gate dielectric layer 124 described with reference to FIGS. 27, 28 and 29. The cell gate dielectric layer 24 may be replaced with a cell gate dielectric layer 424 having substantially the same shape as the cell gate dielectric layer 124. For example, the cell gate dielectric layer 424 may include a first dielectric layer portion 424a, a second dielectric layer portion 424b and a third dielectric layer portion 424c corresponding to the first dielectric layer portion 124a, the second layer dielectric portion 124b and the third dielectric layer portion 124c, respectively.

The first buffer dielectric layer 433 may cover an upper surface and a side surface of the first conductive pattern 436, and may extend between the cell active pattern 9 and the gate electrode 427, as in the first lower buffer dielectric layer 288b1 (see FIG. 29) described with reference to FIG. 29.

The first upper buffer dielectric pattern 132 (see FIG. 28) may be replaced with a first upper buffer dielectric pattern 432 covering the upper surface 427U and the upper rounded edge 427E1 of the gate electrode 427 and extending between the gate electrode 427 and the cell active pattern 9a as described with reference to FIG. 28. The first upper buffer dielectric pattern 432 may include a first upper buffer dielectric layer 432a and a second upper buffer dielectric layer 432b, which correspond to the first upper buffer dielectric layer 432a of FIG. 28 and the second upper buffer dielectric layer 432b of FIG. 28, respectively, described with reference to FIG. 28.

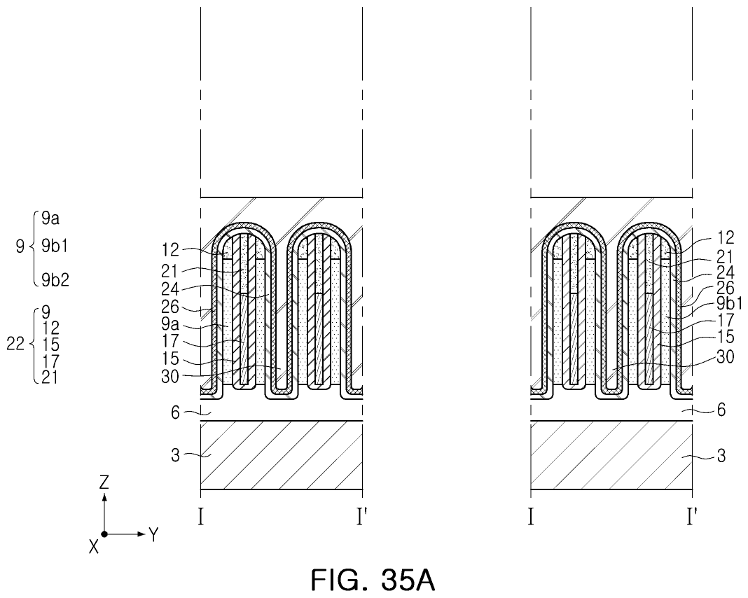

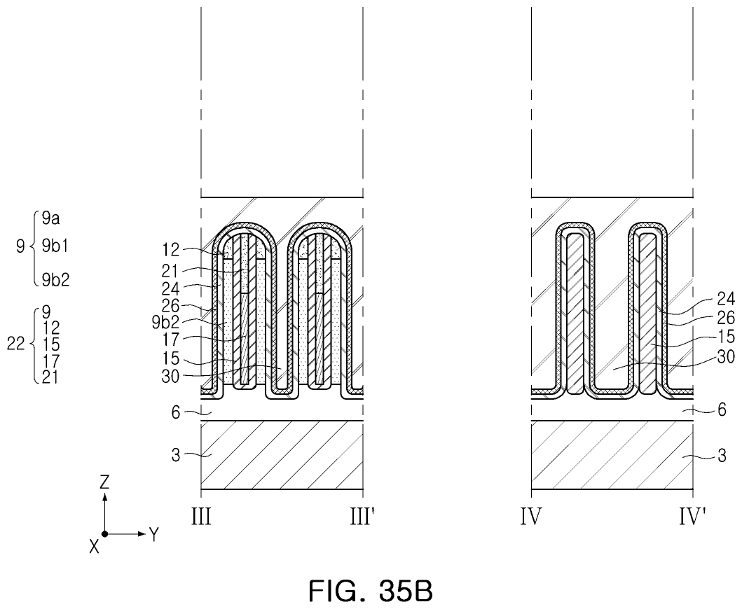

With reference to FIGS. 35A to 42B along with FIGS. 5A, 5B and 5C, an example of a method of forming a semiconductor device according to an example embodiment of the present disclosure will be described. FIGS. 35A to 42B, FIGS. 35A, 36A, 37A, 38A, 39A, 40A, 41A and 42A are cross-sectional views illustrating regions taken along lines I-I′ and II-II′ of FIG. 5B, and FIGS. 35B, 36B, 37B, 38B, 39B, 40B, 41B and 42B are cross-sectional views illustrating regions taken along lines III-III′ and IV-IV′ of FIG. 5B.

Referring to FIGS. 5A, 5B, 5C, 35A and 35B, a structure for fabricating a memory cell may include a base substrate 3 and a sacrificial insulating layer 6 on the base substrate 3. Preliminary structures 22 may be formed on the sacrificial insulating layer 6.

Each of the preliminary structures 22 may traverse the memory cell array region MCA and extend into the first interface region IA1 and the second interface region IA2 on both sides of the memory cell array region MCA. Each of the preliminary structures 22 may extend in the first horizontal direction. The preliminary structures 22 may be spaced apart from each other in the second horizontal direction, perpendicular to the first horizontal direction.

Each of the preliminary structures 22 may include active patterns 9, masks 12 on the active patterns 9, a preliminary back gate electrode 17 passing between the active patterns 9 and extending in the first horizontal direction, a first back gate capping pattern 21 on the preliminary back gate electrode 17, and a back gate dielectric layer 15 covering a side surface and a lower surface of the preliminary back gate electrode 17 and a side surface of the first back gate capping pattern 21. An upper surface of the preliminary back gate electrode 17 may be formed on a level lower than that of upper surfaces of the active patterns 9. The back gate dielectric layer 15 may extend from the memory cell array region MCA into the first and second interface regions IA1 and IA2, in which the back gate dielectric layer 15 may extend farther from the memory cell array region MCA than the preliminary back gate electrode 17.

The active patterns 9 may be formed of a semiconductor material that may be used as a channel region of a transistor. For example, the active patterns 9 may include a semiconductor material such as single crystal silicon.

In each of the preliminary structures 22, the active patterns 9 may be spaced apart from each other in the second horizontal direction and may be arranged in the first horizontal direction. The active patterns 9 may include cell active patterns 9a disposed in the memory cell array region MCA and dummy active patterns 9b1 and 9b2 disposed in the first and second interface regions IA1 and IA2.

The dummy active patterns 9b1 and 9b2 may include first dummy active patterns 9b1 adjacent to the memory cell array region MCA and second dummy active patterns 9b2 further from the memory cell array region MCA than the first dummy active patterns 9b1. The first dummy active patterns 9b1 may have the same size as that of the cell active patterns 9a. Each of the second dummy active patterns 9b2 may have a length in the first horizontal direction greater than a length of each of the cell active patterns 9a in the first horizontal direction.

A gate dielectric layer 24 conformally covering the preliminary structures 22 and a preliminary gate electrode layer 26 conformally covering the gate dielectric layer 24 may be sequentially formed on the sacrificial insulating layer 6.

On the preliminary gate electrode layer 26, an insulating layer 30 filling a space between the preliminary structures 22 may be formed.

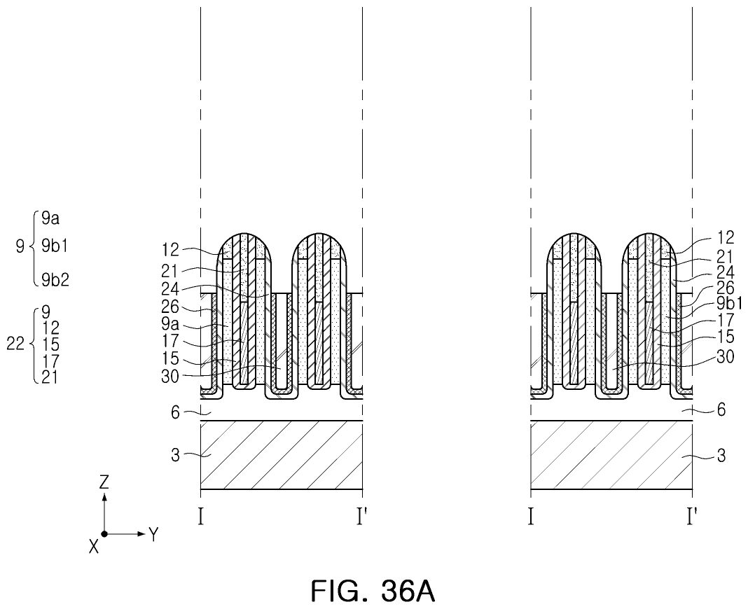

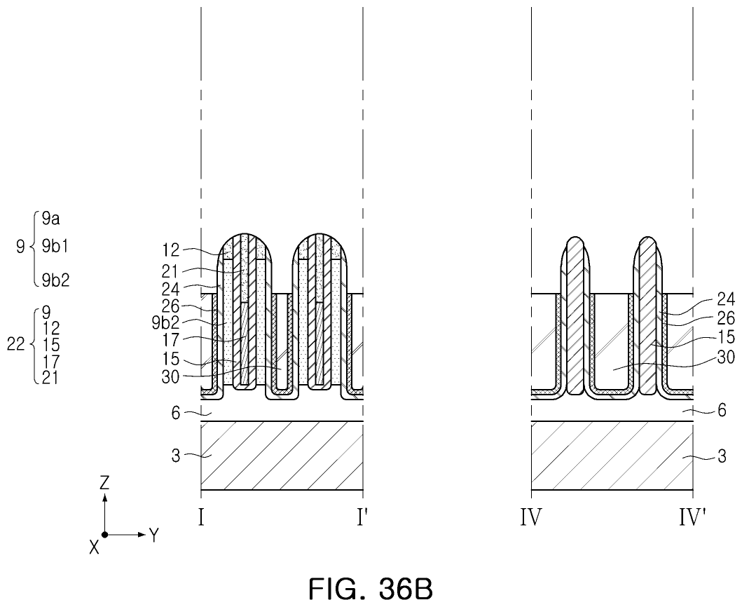

Referring to FIGS. 5A, 5B, 5C, 36A and 36B, the insulating layer 30, the preliminary gate electrode layer 26 and the gate dielectric layer 24 may be partially etched. An upper surface of the partially etched insulating layer 30 and an upper surface of the partially etched preliminary gate electrode layer 26 may be disposed on a level higher than an intermediate portion between an upper surface and a lower surface of each of the active patterns 9 and may be disposed on a level lower than upper surfaces of the active patterns 9.

While partially etching the insulating layer 30 and the preliminary gate electrode layer 26, a portion of the gate dielectric layer 24 may be etched to expose upper surfaces of the preliminary structures 22. The partially etched gate dielectric layer 24 may be formed to cover the side surfaces of the active patterns 9.

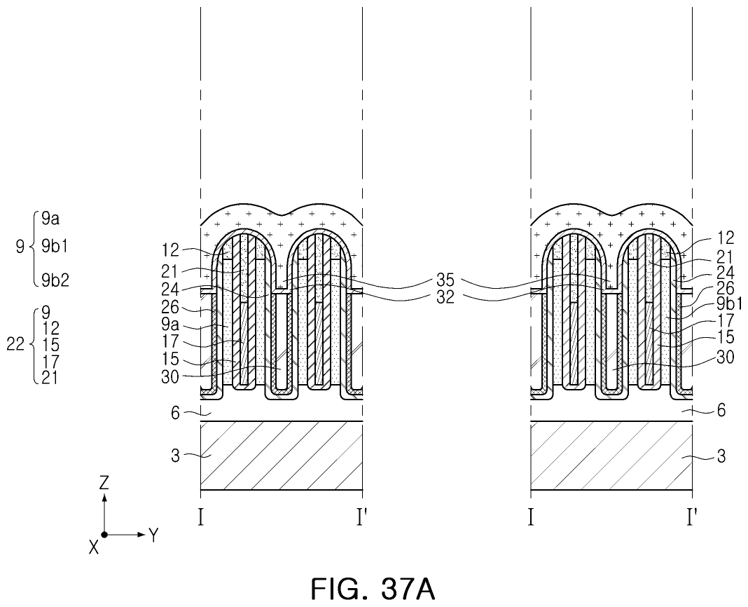

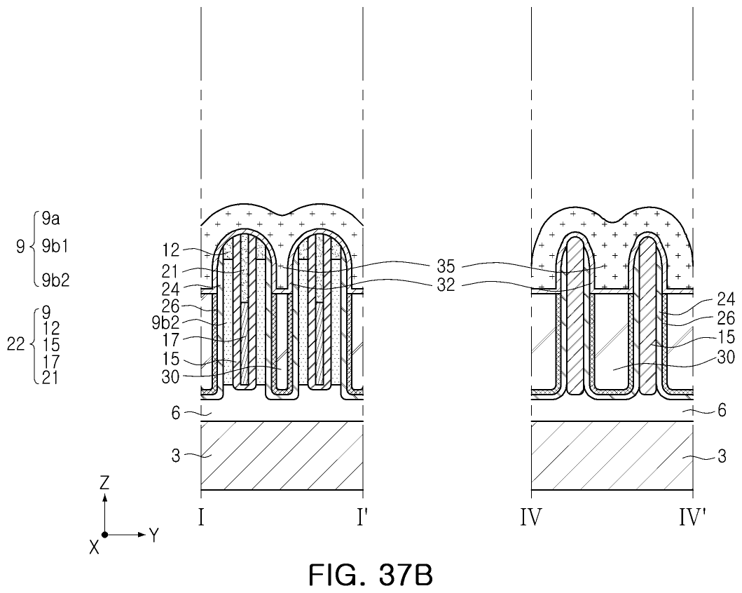

Referring to FIGS. 5A, 5B, 5C, 37A and 37B, a dielectric liner 32 conformally covering the partially etched insulating layer 30, the partially etched preliminary gate electrode layer 26, the partially etched gate dielectric layer 24 and the preliminary structures 22 may be formed. A conductive material layer 35 may be formed on the dielectric liner 32.

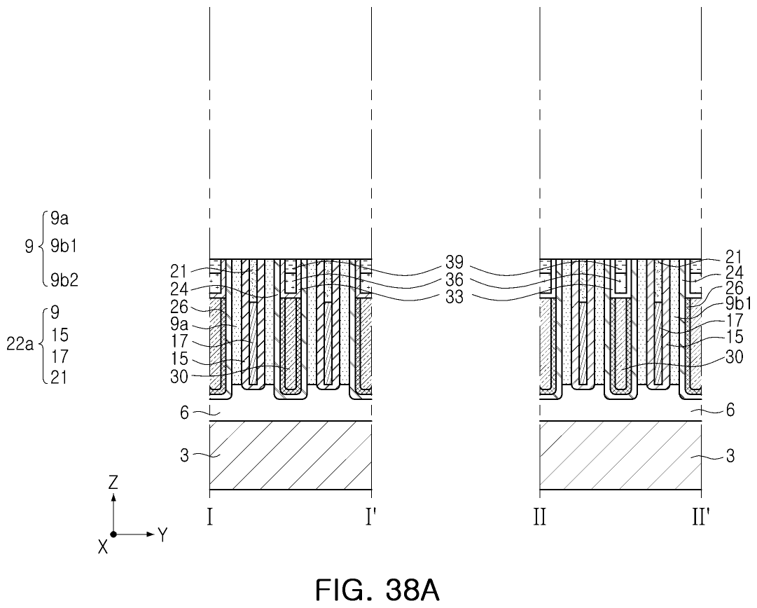

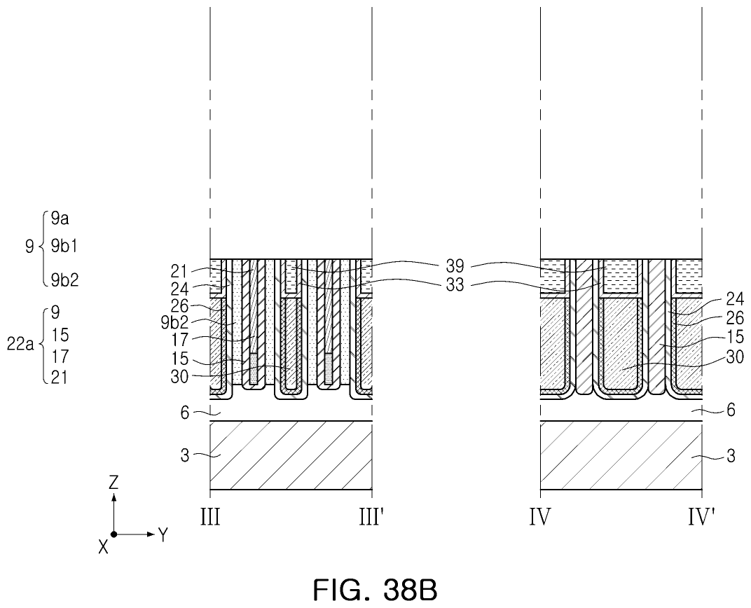

Referring to FIGS. 5A, 5B, 5C, 38A and 38B, the conductive material layer 35 (see FIGS. 37A and 37B) may be partially etched to form first conductive patterns 36.

The first conductive patterns 36 may be formed of doped silicon. However, the example embodiment is not limited thereto, and the first conductive patterns 36 may also be formed of a metallic material including at least one of a metal, a metal nitride, or a metal-semiconductor compound.

With reference to FIGS. 37A and 37B, an insulating material layer covering the first conductive patterns 36 may be formed, and the insulating material layer, the preliminary structures 22, the dielectric liner 32 and the conductive material layer 35 may be planarized. The planarization may be performed until the active patterns 9 of the preliminary structures 22 are exposed. While the preliminary structures 22 are planarized, the upper surfaces of the active patterns 9, an upper surface of the gate dielectric layer 24, an upper surface of the back gate dielectric layer 15 and an upper surface of the first back gate capping pattern 21 may be exposed.

The first conductive patterns 36 may traverse the memory cell array region MCA and may extend into the first and second interface regions IA1 and IA2, and may end within the first and second interface regions IA1 and IA2.

The insulating material layer may be planarized to form first insulating capping patterns 39 formed on the first conductive patterns 36. The first insulating capping patterns 39 may cover the upper surfaces of the first conductive patterns 36 and side surfaces of ends of the first conductive patterns 36.

The preliminary structures 22 may be planarized and may be formed into structures 22a. While the preliminary structures 22 are planarized, the masks 12 may be removed. The dielectric liner 32 may be planarized and may be formed into first buffer dielectric layers 33. Each of the first buffer dielectric layers 33 may cover a lower surface and a side surface of a corresponding first conductive pattern, among the first conductive patterns 36, and may cover a side surface of a corresponding insulating capping pattern, among the first insulating capping patterns 39.

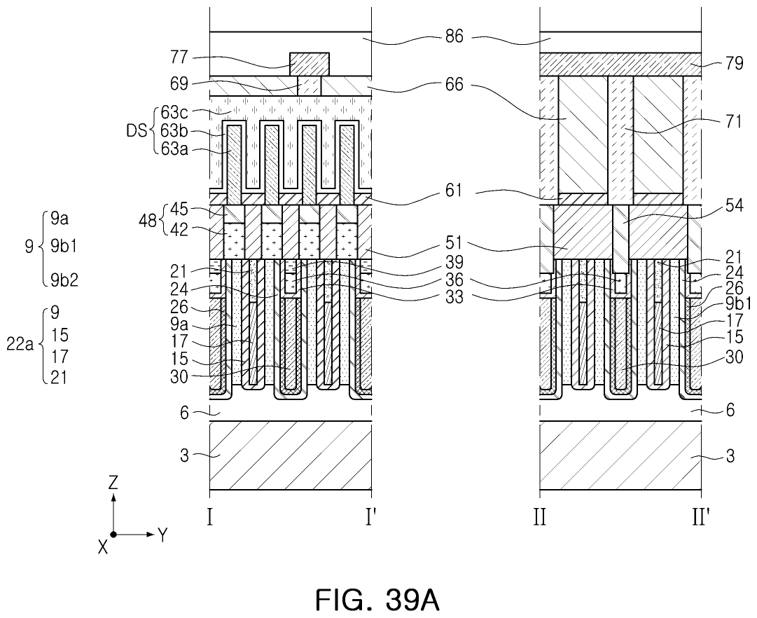

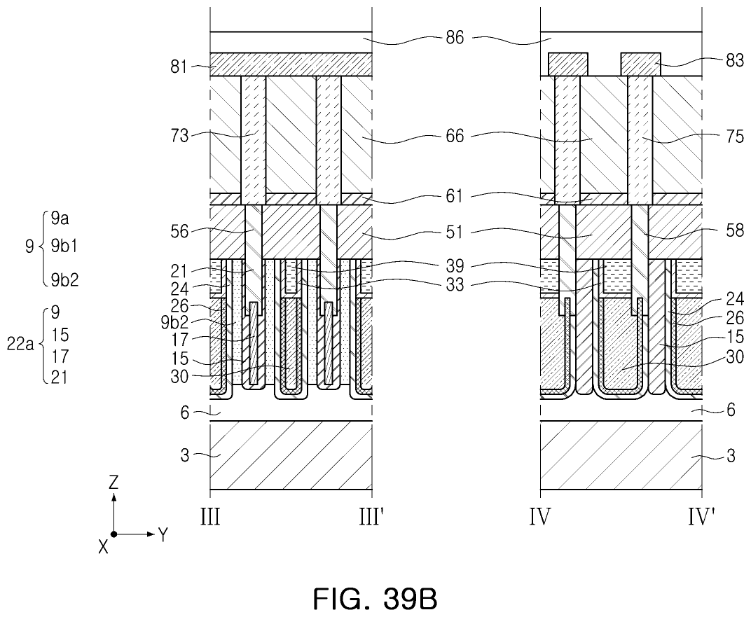

Referring to FIGS. 5A, 5B, 5C, 39A and 39B, contact structures 48 and insulating structures 51 may be formed. The contact structures 48 may be connected to the cell active patterns 9a. Each of the contact structures 48 may include a first material layer 42 and a second material layer 45 on the first material layer 42. The first material layer 42 may include a material such as doped silicon. The second material layer 45 may include at least one of a metal, a metal nitride, or a metal-semiconductor compound. The insulating structure 51 may surround side surfaces of the contact structures 48.

Gate contact plugs 58, back gate contact plugs 56 and first conductive contact plugs 54 may be formed.

The gate contact plugs 58 may extend downwardly by penetrating through the insulating structure 51 and may be connected to the preliminary gate electrode layers 26. The back gate contact plugs 56 may extend downwardly by penetrating through the insulating structure 51 and may be connected to the preliminary back gate electrodes 17. The first conductive contact plugs 54 may extend downwardly by penetrating through the insulating structure 51 and may be connected to the first conductive patterns 36.

An insulating etch stop layer 61 may be formed on the contact structures 48, the gate contact plugs 58, the back gate contact plugs 56, the first conductive contact plugs 54 and the insulating structure 51.

A data storage structure DS may be formed. The data storage structure DS may include first electrodes 63a penetrating through the insulating etch stop layer 61 and connected to the contact structures 48 and extending upwardly, a dielectric layer 63b covering the first electrodes 63a and the etch stop layer 61, and a second electrode 63c covering the dielectric layer 63b.

A first upper insulating layer 66 may be formed on the data storage structure DS and the insulating etch stop layer 61. Upper contact plugs 69, 71, 73 and 75 penetrating through the first upper insulating layer 66 may be formed. The upper contact plugs 69, 71, 73 and 75 may include a first upper contact plug 69 electrically connected to the second electrode 63c, second upper contact plugs 71 electrically connected to the first conductive contact plugs 54, third upper contact plugs 73 electrically connected to the back gate contact plugs 56, and fourth upper contact plugs 75 electrically connected to the gate contact plugs 58.

Upper interconnections 77, 79, 81 and 83 may be formed on the first upper insulating layer 66 and the upper contact plugs 69, 71, 73 and 75. The upper interconnections 77, 79, 81 and 83 may include a first upper interconnection 77 electrically connected to the first upper contact plug 69, a second upper interconnection 79 electrically connected to the second upper contact plugs 71, a third upper interconnection 81 electrically connected to the third upper contact plugs 73, and a fourth upper interconnection 83 electrically connected to the fourth upper contact plugs 75, respectively. A second upper insulating layer 86 may be formed on the first upper insulating layer 66 and the upper interconnections 77, 79, 81 and 83.

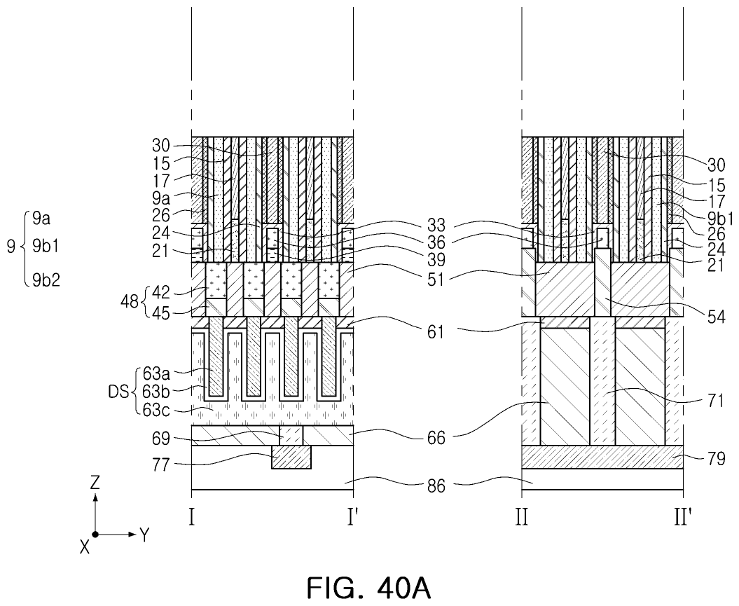

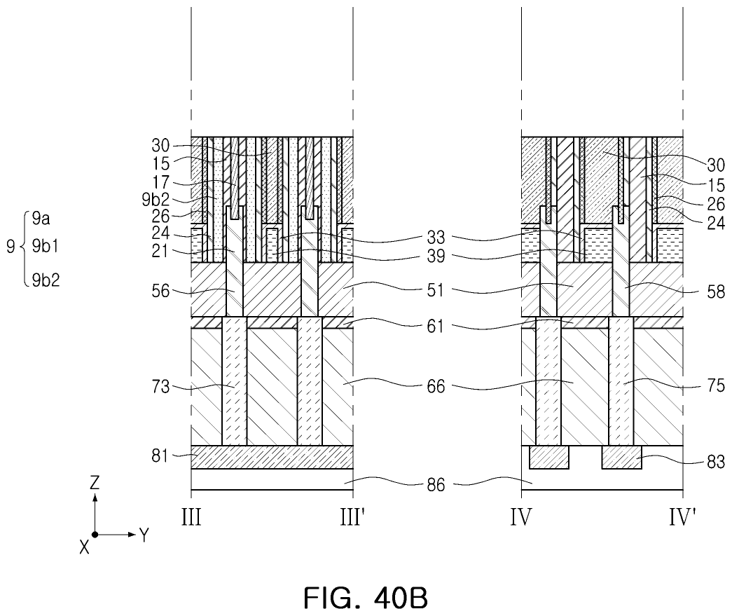

Referring to FIGS. 5A, 5B, 5C, 40A and 40B, following process steps are performed on the surface including the base substrate 3. The base substrate 3 and the sacrificial insulating layer 6 may be removed. The active patterns 9 may be exposed when the sacrificial insulating layer 6 is removed. Then, the upper surfaces of the preliminary back gate electrodes 17 and the preliminary gate electrode layers 26 may be exposed.

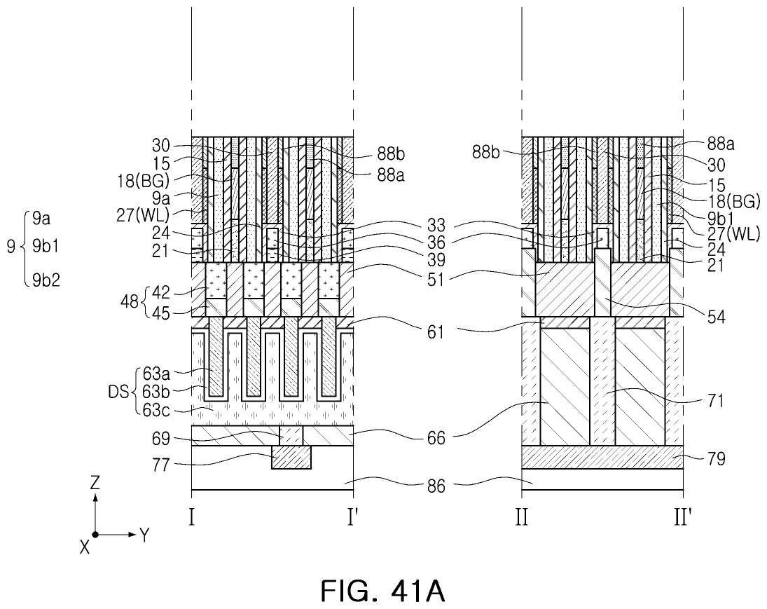

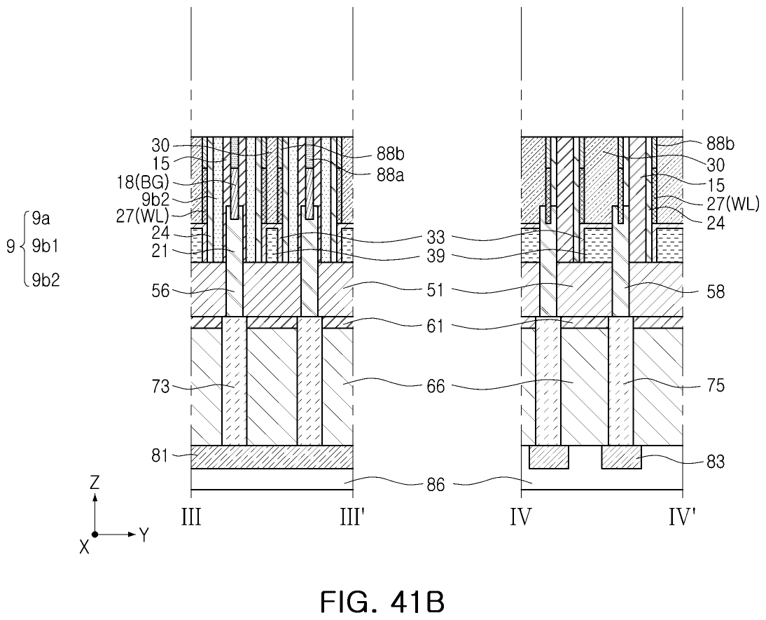

Referring to FIGS. 5A, 5B, 5C, 41A and 41B, the preliminary back gate electrodes 17 and the preliminary gate electrode layers 26 may be partially etched to form back gate electrodes 18 and word lines 27. Insulating capping patterns 88a and 88b may be formed on the back gate electrodes 18 and the word lines 27. The insulating capping patterns 88a and 88b may include insulating gate capping patterns 88b on the word lines 27 and second insulating back gate capping patterns 88a on the back gate electrodes 18.

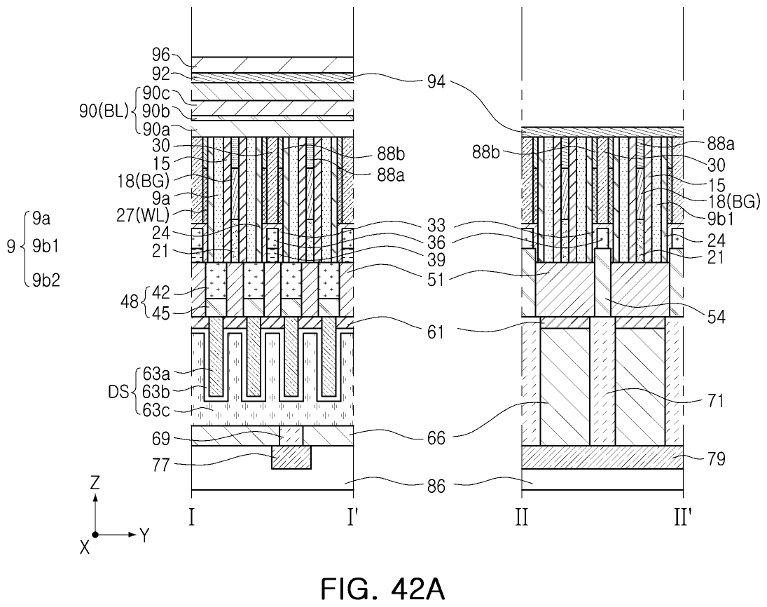

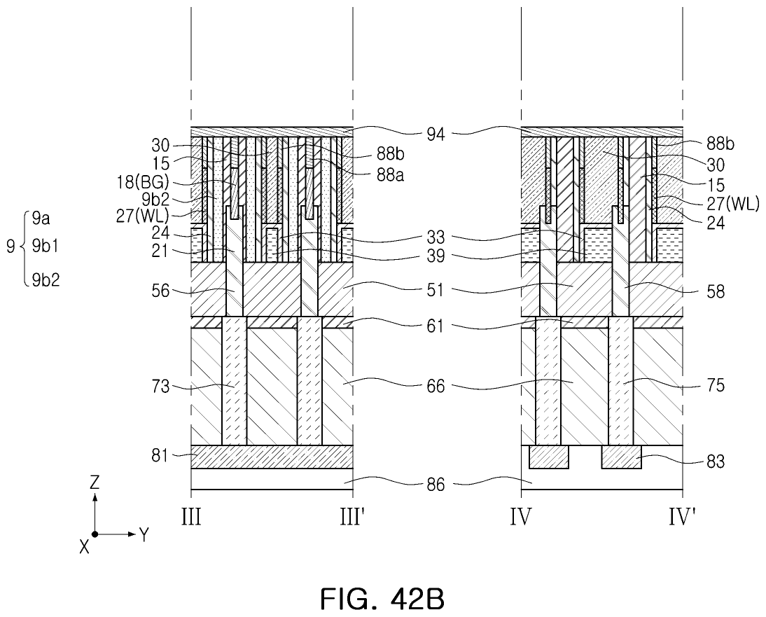

Referring to FIGS. 5A, 5B, 5C, 42A and 42B, bit line structures 90 and 92 may be formed. Each of the bit line structures 90 and 92 may include a bit line 90 and a bit line capping pattern 92 on the bit line 90.

Each of the bit lines 90 may include a first material layer 90a, a second material layer 90b and a third material layer 90c, which are sequentially stacked. The first material layer 70 may include at least one of doped silicon, doped germanium, and doped silicon-germanium. The second material layer 90b may include at least one of a metal-semiconductor compound layer and a metal nitride. The third material layer 90c may include at least one of a metal or a metal nitride.

An insulating liner 94 conformally covering a structure including the bit line structures 90 and 92 may be formed. A bit line shield pattern 96 may be formed on the insulating liner 94. The bit line shield pattern 96 may be formed between the bit line structures 90 and 92 and on upper surfaces of the bit line structures 90 and 92.

Referring again to FIGS. 5A, 5B, 5C, 6A, 6B, 6C and 7, a first lower insulating layer 97 covering the bit line shield pattern 96 and the insulating liner 94 may be formed. A second lower insulating layer 98 covering the first lower insulating layer 97 may be formed.

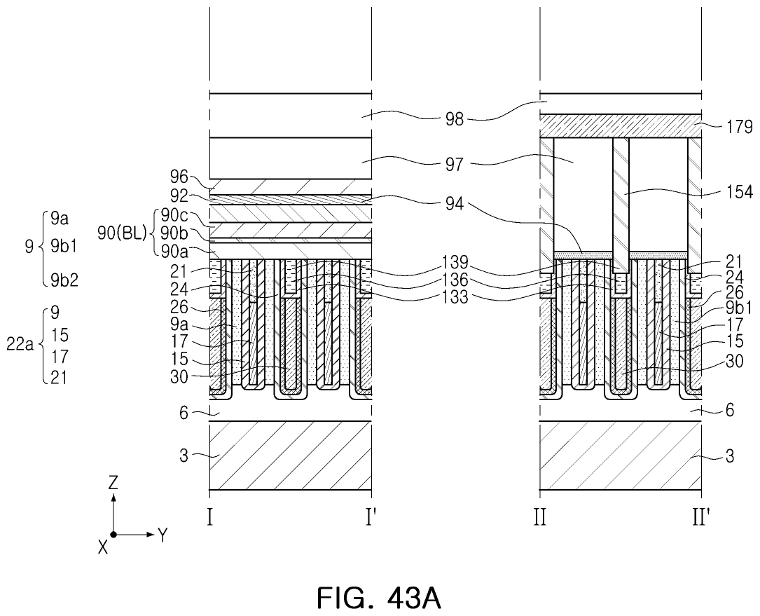

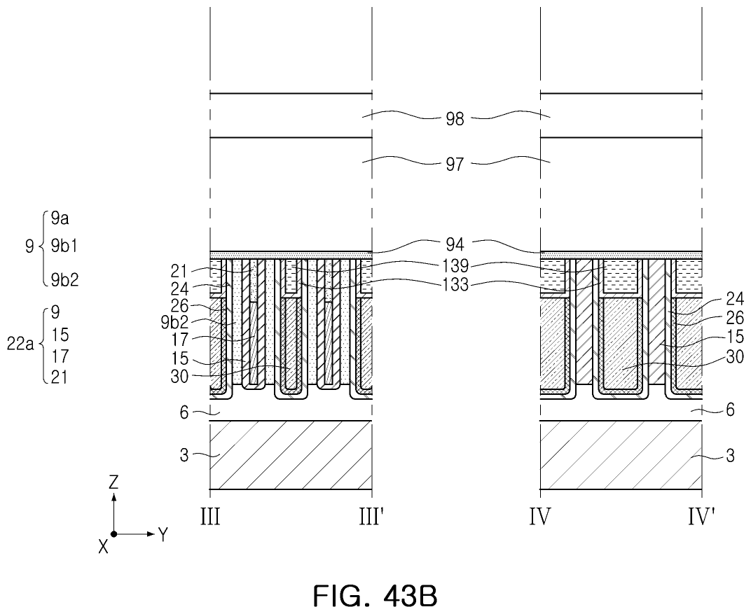

With reference to FIGS. 43A to 46B along with FIGS. 5A, 5B and 5C, an example of a method of forming a semiconductor device according to an example embodiment of the present disclosure will be described. FIGS. 43A to 46B, FIGS. 43A, 44A, 45A and 46A are cross-sectional views illustrating regions taken along lines I-I′ and II-II′ of FIG. 5B, and FIGS. 43B, 44B, 45B and 46B are cross-sectional views illustrating regions taken along lines III-III′ and IV-IV′ of FIG. 5B.

With reference to FIGS. 5A, 5B, 5C, 43A and 43B, the same process as described with reference to FIGS. 35A to 38B may be performed. Accordingly, the same structure as described in FIGS. 38a and 38b may be formed.

In an example embodiment, the first buffer dielectric layers 33 described in FIGS. 38A and 38B may be referred to as second buffer dielectric layers 133, the first conductive patterns 36 may be referred to as second conductive patterns 136, and the first insulating capping patterns 39 may be referred to as second insulating capping patterns 139.

Then, the same process as described in FIGS. 42A and 42B may be performed. Accordingly, the bit line structures 90 and 92, the insulating liner 94 and the bit line shield pattern 96, which are identical to those described in FIGS. 42A and 42B, may be formed.

A first lower insulating layer 97 covering the bit line shield pattern 96 and the insulating liner 94 may be formed. Second conductive contact plugs 154 penetrating through the first lower insulating layer 97, the insulating liner 94 and the second insulating capping patterns 139 and electrically connected to the second conductive patterns 136 may be formed. The lower interconnection 179 electrically connected to the second conductive contact plugs 154 may be formed on the first lower insulating layer 97. A second lower insulating layer 98 covering the first lower insulating layer 97 and the lower interconnection 179 may be formed.

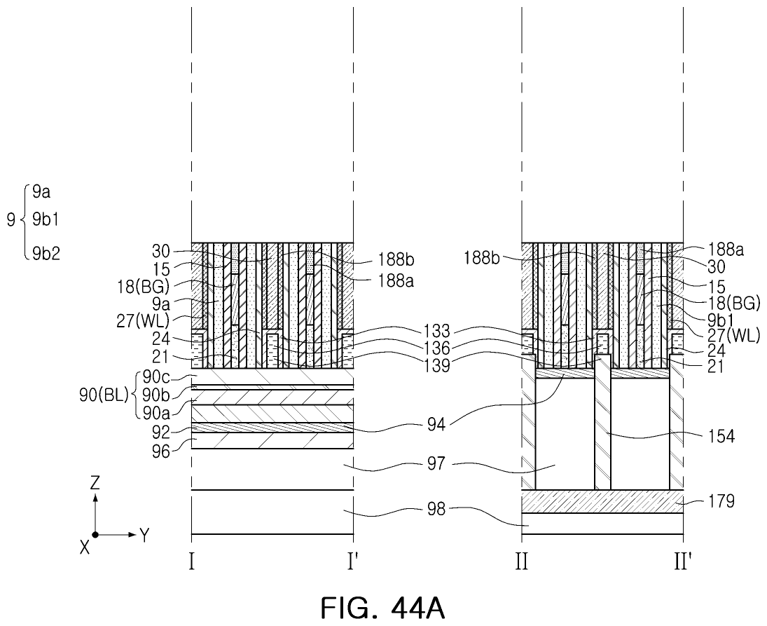

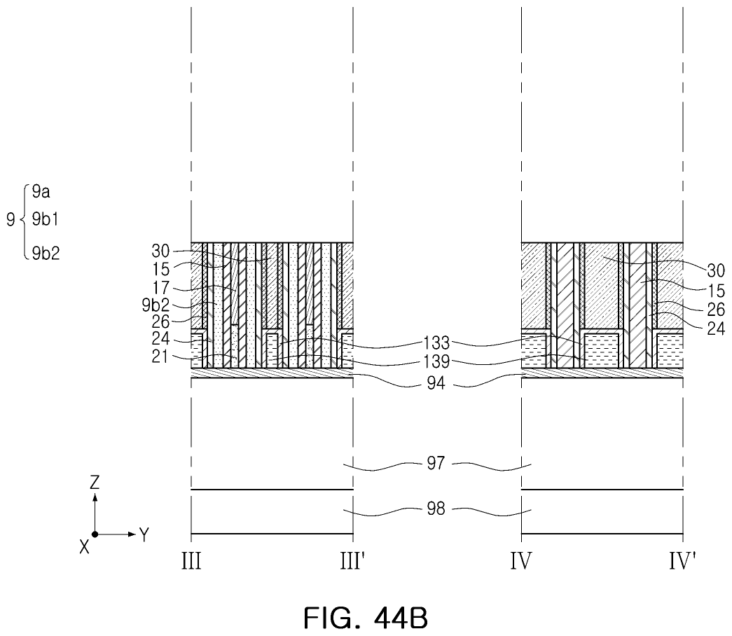

Referring to FIGS. 5A, 5B, 5C, 44A and 44B, after the second lower insulating layer 98 and the base substrate 3 are disposed, following process steps are performed on the surface including the base substrate 3. The base substrate 3 and the sacrificial insulating layer 6 may be removed. As the sacrificial insulating layer 6 is removed, the active patterns 9 may be exposed. Subsequently, upper surfaces of the preliminary back gate electrodes 17 and the preliminary gate electrode layers 26 may be exposed.

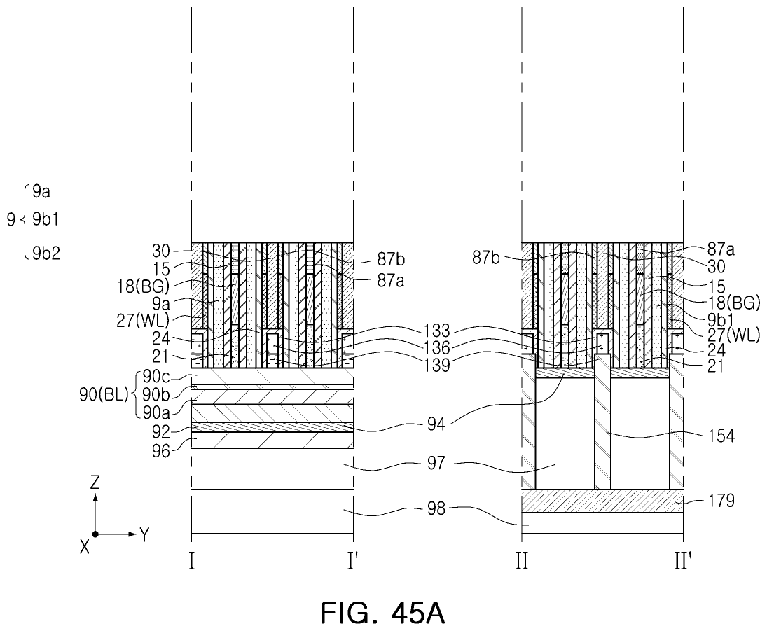

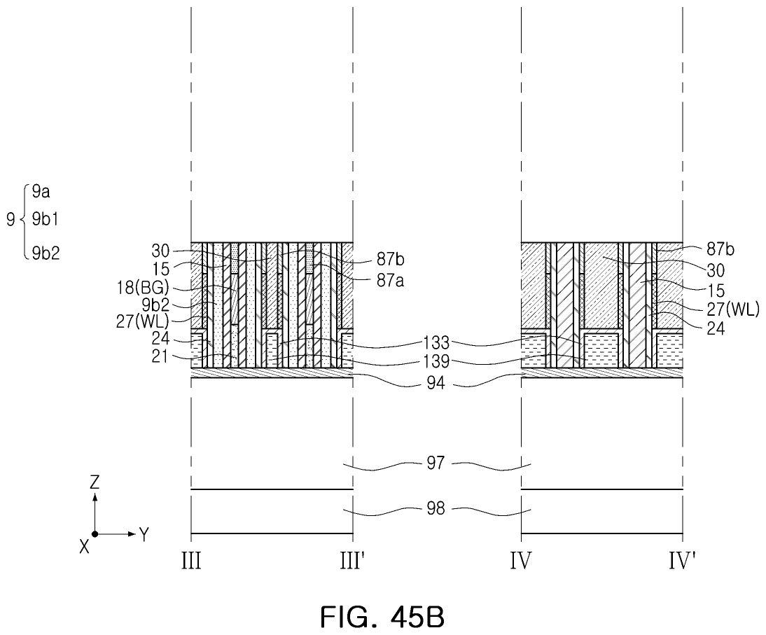

Referring to FIGS. 5A, 5B, 5C, 45A and 45B, the same process as described above in FIGS. 41A and 41B may be performed. For example, the preliminary back gate electrodes 17 and the preliminary gate electrode layers 26 may be partially etched to form back gate electrodes 18 and word lines 27. Insulating capping patterns 87a and 87b may be formed on the back gate electrodes 18 and the word lines 27. The insulating capping patterns 87a and 87b may include insulating gate capping patterns 87b on the word lines 27 and insulating back gate capping patterns 87a on the back gate electrodes 18.

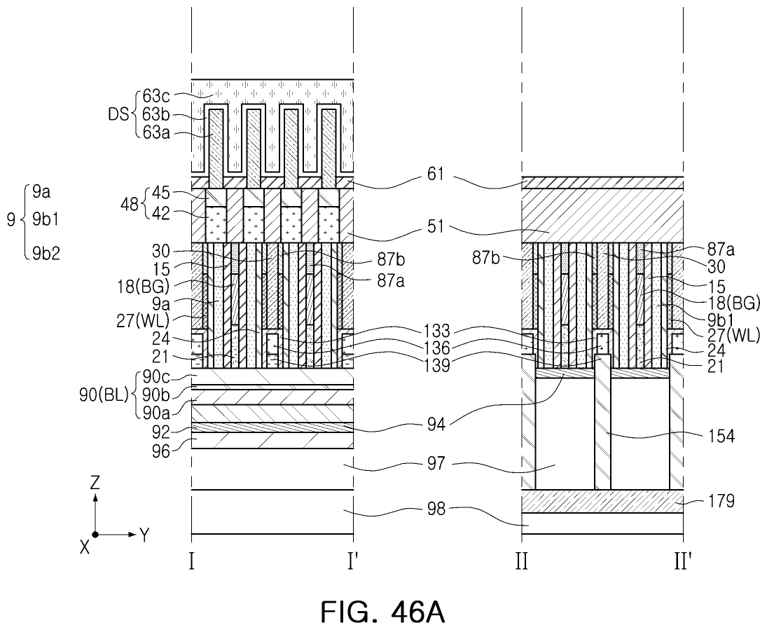

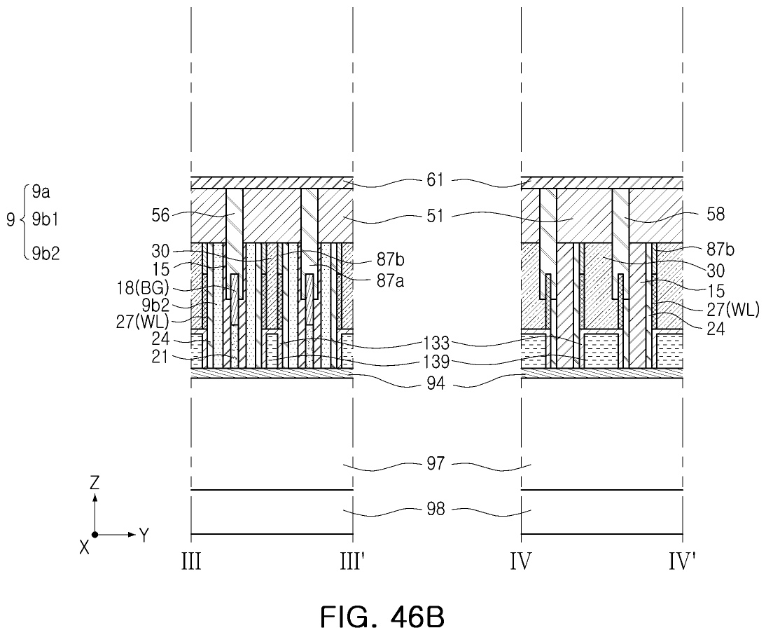

Referring to FIGS. 5A, 5B, 5C, 46A and 46B, then, the contact structures 48, the insulating structure 51, the gate contact plugs 58, the back gate contact plugs 56, the insulating etch stop layer 61, and the data storage structure DS may be formed in the same manner as described in FIGS. 39A and 39B.

Referring to FIGS. 5A, 5B, 5C, 14, 15A, 15B and 16, a first upper insulating layer 66 may be formed on the data storage structure DS and the insulating etch stop layer 61. Upper contact plugs 69, 73 and 75 penetrating through the first upper insulating layer 66 may be formed. The upper contact plugs 69, 73 and 75 may include a first upper contact plug 69 electrically connected to the second electrode 63c, third upper contact plugs 73 electrically connected to the back gate contact plugs 56, and fourth upper contact plugs 75 electrically connected to the gate contact plugs 58.

Upper interconnections 77, 81 and 83 may be formed on the first upper insulating layer 66 and the upper contact plugs 69, 73 and 75. The upper interconnections 77, 81 and 83 may include a first upper interconnection 77 electrically connected to the first upper contact plug 69, a third upper interconnection 81 electrically connected to the third upper contact plugs 73, and a fourth upper interconnection 83 electrically connected to the fourth upper contact plugs 75, respectively. A second upper insulating layer 86 may be formed on the first upper insulating layer 66 and the upper interconnections 77, 81 and 83.

According to example embodiments, a semiconductor device may include a cell transistor configured to reduce leakage current due to Gate-Induced-Drain Leakage (GIDL).

According to example embodiments, a semiconductor device may reduce parasitic capacitance between adjacent cell transistors.

According to example embodiments, at least one conductive pattern is disposed between cell active patterns and is spaced apart from gate electrodes, in which at least a portion of the conductive pattern is disposed at a different level from the gate electrodes.

Since the at least one conductive pattern is configured to reduce parasitic capacitance between adjacent cell transistors, the performance of a semiconductor device including the conductive pattern may be improved.

Since the at least one conductive pattern is configured to reduce signal crosstalk between adjacent cell transistors to suppress noise, the performance of a semiconductor device including the conductive pattern may be improved.

The at least one conductive pattern may reduce leakage current due to gate-induced-drain leakage (GIDL) of a cell transistor adjacent to the conductive pattern, thereby improving the performance of a semiconductor device including the conductive pattern.

According to example embodiments, a back gate electrode may be arranged to face a channel region of the cell transistor. The back gate electrode may suppress or prevent the performance of the cell transistor from being degraded due to a floating body effect.

Advantages and effects of the present application are not limited to the described embodiments and may become more clear while discussing a specific example embodiment of the present disclosure.

Although example embodiments of the present disclosure have been described with reference to the accompanying drawings, it will be understood by those skilled in the art that the present invention may be implemented in other specific forms without changing its technical concepts or essential features. Therefore, it should be understood that the example embodiments described above are exemplary and not limited in all respects.

What is claimed is:

1. A semiconductor device, comprising:
a first cell active pattern and a second cell active pattern that are adjacent to each other;
a first gate electrode and a second gate electrode disposed between the first and second cell active patterns and spaced apart from each other;
a first gate dielectric layer between the first gate electrode and the first cell active pattern;
a second gate dielectric layer between the second gate electrode and the second cell active pattern; and
a first conductive pattern disposed between the first and second cell active patterns and spaced apart from the first and second gate electrodes, at least a portion of the first conductive pattern being disposed at a different level from the first and second gate electrodes.

2. The semiconductor device of claim 1, further comprising:
a buffer dielectric layer including a first portion, a second portion and a third portion,
wherein the first portion covers a first side surface of the first conductive pattern facing the first cell active pattern, the second portion covers a second side surface of the first conductive pattern facing the second cell active pattern, and the third portion covers a third surface of the first conductive pattern adjacent to the first and second gate electrodes and separates the first conductive pattern from the first and second gate electrodes, and wherein the first portion of the buffer dielectric layer is disposed between the first cell active pattern and the first conductive pattern, and the second portion of the buffer dielectric layer is disposed between the second cell active pattern and the first conductive pattern.

3. The semiconductor device of claim 2, wherein
the first gate dielectric layer is disposed between the first portion of the buffer dielectric layer and the first cell active pattern and between the first gate electrode and the first cell active pattern, and the second gate dielectric layer is disposed between the second portion of the buffer dielectric layer and the second cell active pattern and between the second gate electrode and the second cell active pattern.

4. The semiconductor device of claim 1, further comprising:
a first data storage structure vertically on the first cell active pattern and a second data storage structure vertically on the second cell active pattern;
a first contact structure between the first cell active pattern and the first data storage structure;
a second contact structure between the second cell active pattern and the second data storage structure; and
a bit line connected to the first and second cell active patterns and disposed below the first and second cell active patterns.

5. The semiconductor device of claim 4, wherein the first conductive pattern is disposed at a higher level than the first and second gate electrodes.

6. The semiconductor device of claim 5, further comprising:
a second conductive pattern disposed between the first and second cell active patterns, disposed at a different level from the first conductive pattern, and vertically overlapping the first conductive pattern,
wherein at least a portion of the second conductive pattern is disposed at a lower level than the first and second gate electrodes.

7. The semiconductor device of claim 4, wherein the first conductive pattern includes:
an upper conductive portion disposed at a higher level than the first and second gate electrodes; and
an intermediate conductive portion extending downwardly from the upper conductive portion and disposed between the first and second gate electrodes.

8. The semiconductor device of claim 7, wherein
the first conductive pattern further includes a lower conductive portion extending downwardly from the intermediate conductive portion and disposed at a lower level than the first and second gate electrodes, and the upper conductive portion has a width greater than a width of the intermediate conductive portion.

9. The semiconductor device of claim 4, wherein the first conductive pattern is disposed at a lower level than the first and second gate electrodes.

10. The semiconductor device of claim 4, wherein the first conductive pattern includes a lower conductive portion disposed at a lower level than the first and second gate electrodes, and an intermediate conductive portion extending upwardly from the lower conductive portion and disposed between the first and second gate electrodes.

11. The semiconductor device of claim 10, wherein
the first conductive pattern further includes an upper conductive portion extending upwardly from the intermediate conductive portion and disposed at a higher level than the first and second gate electrodes, and the lower conductive portion has a width greater than a width of the intermediate conductive portion.

12. The semiconductor device of claim 1, wherein
each of the first and second cell active patterns includes a first source/drain region, a second source/drain region disposed at a different level from the first source/drain region, and a channel region between the first and second source/drain regions,
the first gate electrode has a side surface facing the channel region of the first cell active pattern,
the second gate electrode has a side surface facing the channel region of the second cell active pattern, and
at least a portion of the first conductive pattern is disposed between the second source/drain region of the first cell active pattern and the second source/drain region of the second cell active pattern.

13. The semiconductor device of claim 1, wherein each of the first and second cell active patterns includes a first source/drain region, a second source/drain region disposed at a different level from the first source/drain region, and a channel region between the first and second source/drain regions, the first gate electrode has a side surface facing the channel region of the first cell active pattern, the second gate electrode has a side surface facing the channel region of the second cell active pattern, and the first conductive pattern includes a portion disposed between the channel region of the first cell active pattern and the channel region of the second cell active pattern.

14. The semiconductor device of claim 1, further comprising:
a third cell active pattern disposed at the same level as the first and second cell active patterns;
a back gate electrode passing between the second cell active pattern and the third cell active pattern;
a first back gate dielectric layer disposed between the second cell active pattern and the back gate electrode; and
a second back gate dielectric layer disposed between the third cell active pattern and the back gate electrode,
wherein the back gate electrode extends in a first horizontal direction, wherein the first cell active pattern, the second cell active pattern and the third cell active pattern are sequentially disposed in a second horizontal direction perpendicular to the first horizontal direction, wherein each of the first, second and third cell active patterns extends in a vertical direction perpendicular to the first and second horizontal directions, and wherein at least a portion of the back gate electrode is disposed at the same level as the first and second gate electrodes.

15. A semiconductor device, comprising:
a memory cell array region and an interface region adjacent to each other in a first horizontal direction;
active patterns including cell active patterns disposed within the memory cell array region and dummy active patterns disposed within the interface region;
gate electrodes traversing the memory cell array region and extending into the interface region; and
conductive patterns traversing the memory cell array region and extending into the interface region,
wherein at least a portion of each of the conductive patterns is disposed at a different level from the gate electrodes, wherein the cell active patterns include a first cell active pattern and a second cell active pattern adjacent to each other in a second horizontal direction perpendicular to the first horizontal direction, wherein the gate electrodes include a first gate electrode and a second gate electrode passing between the first and second cell active patterns and spaced apart from each other, and wherein the conductive patterns include a first conductive pattern passing between the first cell active pattern and the second cell active pattern.

16. The semiconductor device of claim 15, wherein the first gate electrode extends from the memory cell array region into the interface region by a first length, and the first conductive pattern extends from the memory cell array region into the interface region by a second length, in which the first length is greater than the second length.

17. The semiconductor device of claim 15, further comprising:
bit lines connected to the cell active patterns and disposed below the cell active patterns;
data storage structures disposed at a higher level than the cell active patterns; and
contact structures between the cell active patterns and the data storage structures,
wherein each of the first and second cell active patterns includes a first source/drain region, a second source/drain region disposed at a different level from the first source/drain region, and a channel region between the first and second source/drain regions, wherein the first and second gate electrodes are disposed between the channel region of the first cell active pattern and the channel region of the second cell active pattern, and
wherein at least a portion of the first conductive pattern is disposed between the second source/drain region of the first cell active pattern and the second source/drain region of the second cell active pattern.

18. A semiconductor device, comprising:
a memory cell array region and an interface region adjacent to each other in a first horizontal direction;
active patterns including cell active patterns disposed in the memory cell array region and dummy active patterns disposed in the interface region;
gate electrodes traversing the memory cell array region and extending into the interface region;
first conductive patterns traversing the memory cell array region and extending into the interface region;
bit lines extending in a second horizontal direction perpendicular to the first horizontal direction, connected to the cell active patterns, and disposed below the cell active patterns;
data storage structures on the cell active patterns; and
a contact structure between the cell active patterns and the data storage structure,
wherein at least a portion of each of the first conductive patterns is at a different level from the gate electrodes, wherein the cell active patterns include a first cell active pattern and a second cell active pattern adjacent to each other in a second horizontal direction perpendicular to the first horizontal direction, wherein the gate electrodes include a first gate electrode and a second gate electrode passing between the first and second cell active patterns and spaced apart from each other, and wherein one of the first conductive patterns passes between the first cell active pattern and the second cell active pattern.

19. The semiconductor device of claim 18, further comprising:
back gate electrodes traversing the memory cell array region and extending into the interface region,
wherein the cell active patterns further include a third cell active pattern, wherein the first cell active pattern, the second cell active pattern and the third cell active pattern are arranged sequentially in the second horizontal direction, wherein the back gate electrodes include a first back gate electrode disposed between the second cell active pattern and the third cell active pattern, and wherein at least a portion of each of the back gate electrodes is disposed at the same level as the gate electrodes.

20. The semiconductor device of claim 18, further comprising:
second conductive patterns traversing the memory cell array region and extending into the interface region, and disposed at a different level from the first conductive patterns,
wherein at least a portion of each of the second conductive patterns is disposed at a different level from the gate electrodes, and wherein the second conductive patterns vertically overlap the first conductive patterns.
